(19) United States
(12) Patent Application Publication
(10) Pub. No.: US 2021/0183860 A1
(43) Pub. Date: Jun. 17, 2021

(54) MEMORY DEVICE AND ELECTRONIC DEVICE

(71) Applicant: SEMICONDUCTOR ENERGY LABORATORY CO., LTD., ATSUGI-SHI, KANAGAWA-KEN (JP)

(72) Inventors: Shunpei YAMAZAKI, Setagaya, Tokyo (JP); Kiyoshi KATO, Atsugi, Kanagawa (JP); Tatsuya ONUKI, Atsugi, Kanagawa (JP); Takanori MATSUZAKI, Atsugi, Kanagawa (JP)

(73) Assignee: SEMICONDUCTOR ENERGY LABORATORY CO., LTD., ATSUGI-SHI, KANAGAWA-KEN (JP)

(21) Appl. No.: 17/047,143

(22) PCT Filed: Apr. 11, 2019
(86) PCT No.: PCT/IB2019/052977

§ 371 Date: Oct. 13, 2020

(30) Foreign Application Priority Data
Apr. 20, 2018 (JP) 2018-081702
Apr. 27, 2018 (JP) 2018-087077

(51) Int. Cl. H01L 27/105; H01L 27/12; H01L 29/24; H01L 29/786

(52) U.S. Cl. CPC H01L 27/1052; H01L 27/1207; H01L 27/1225; H01L 29/7869; H01L 29/24; H01L 29/78648; H01L 29/78696; H01L 27/1255

(57) ABSTRACT

A novel semiconductor device is provided. A semiconductor device includes a plurality of cell arrays and a plurality of peripheral circuits. The cell array includes a plurality of memory cells. The peripheral circuit includes a first driver circuit, a second driver circuit, a first amplifier circuit, a second amplifier circuit, a third amplifier circuit, and a fourth amplifier circuit. The first driver circuit and the second driver circuit each have a function of supplying a selection signal to the cell array. The first amplifier circuit and the second amplifier circuit each have a function of amplifying a potential input from the cell array. The third amplifier circuit and the fourth amplifier circuit each have a function of amplifying a potential input from the first amplifier circuit or the second amplifier circuit. The first driver circuit, the second driver circuit, the first amplifier circuit, the second amplifier circuit, the third amplifier circuit, and the fourth amplifier circuit have a region overlapping with the cell array. A transistor included in the memory cell includes a metal oxide in a channel formation region.

### TECHNICAL FIELD

One embodiment of the present invention relates to a semiconductor device.

Note that one embodiment of the present invention is not limited to the above technical field. Examples of the technical field of one embodiment of the present invention disclosed in this specification and the like include a semiconductor device, an imaging device, a display device, a light-emitting apparatus, a power storage device, a memory device, a display system, an electronic device, a lighting device, an input device, an input/output device, a driving method thereof, and a manufacturing method thereof.

The semiconductor device in this specification and the like means every device which can function by utilizing semiconductor characteristics. A transistor, a semiconductor circuit, an arithmetic device, a memory device, and the like are each an embodiment of the semiconductor device. In addition, a display device, an imaging device, an electro-optical device, a power generation device (including a thin film solar cell, an organic thin film solar cell, and the like), and an electronic device may include a semiconductor device.

### BACKGROUND ART

A DRAM (Dynamic Random Access Memory) is widely used as a memory incorporated in various kinds of electronic devices. A DRAM has been miniaturized in accordance with a scaling law like other semiconductor integrated circuits. Patent Document 1 discloses a manufacturing method of a transistor suitable for miniaturization of a DRAM.

Patent Document 2 discloses an example in which a transistor using an oxide semiconductor is used for a DRAM. The transistor using an oxide semiconductor has an extremely low leakage current in an off state (off-state current), and thus enables fabrication of a low-power-consumption memory having long refresh intervals.

### PRIOR ART DOCUMENTS

### Patent Documents

### [Patent Document 1] Japanese Published Patent Application No. 2016-127193

### [Patent Document 2] Japanese Published Patent Application No. 2017-28237

### SUMMARY OF THE INVENTION

### Problems to be Solved by the Invention

An object of one embodiment of the present invention is to provide a novel semiconductor device. Another object of one embodiment of the present invention is to provide a semiconductor device with a small circuit area. Another object of one embodiment of the present invention is to provide a semiconductor device with low power consumption. Another object of one embodiment of the present invention is to provide a semiconductor device capable of high-speed operation.

One embodiment of the present invention does not have to achieve all the above objects and only needs to achieve at least one of the objects. The descriptions of the above objects do not preclude the existence of other objects. Objects other than these objects will be apparent from the descriptions of the specification, the claims, the drawings, and the like, and objects other than these objects can be derived from the descriptions of the specification, the claims, the drawings, and the like.

### Means for Solving the Problems

One embodiment of the present invention is a memory device including a first memory cell including a first transistor; the first transistor includes a metal oxide in a semiconductor layer; a refresh interval of the first memory cell is longer than or equal to 10 minutes; and the operation speed of the first memory cell is higher than or equal to that of a second memory cell including a transistor including silicon in a semiconductor layer.

Another embodiment of the present invention is a memory device including a first memory cell including a first transistor; the first transistor includes a metal oxide in a semiconductor layer; a refresh interval of the first memory cell is longer than or equal to one hour; and the operation speed of the first memory cell is higher than or equal to that of a second memory cell including a transistor including silicon in a semiconductor layer.

At an operation temperature of higher than or equal to 20° C. and lower than or equal to 200° C., the first memory cell can operate at a higher operation speed than the second memory cell. Alternatively, at an operation temperature of higher than or equal to 20° C. and lower than or equal to 200° C., the first memory cell may operate at an operation speed five or more times higher than that of the second memory cell.

The channel length of the first transistor is preferably greater than or equal to 5 nm and less than or equal to 100 nm, further preferably greater than or equal to 5 nm and less than or equal to 30 nm.

Another embodiment of the present invention is a memory device including a peripheral circuit and a cell array; the peripheral circuit includes a region overlapping with the cell array; the peripheral circuit has a function of controlling the cell array; the cell array includes a memory cell; the memory cell includes a transistor and a capacitor; the transistor includes a metal oxide in a semiconductor layer; and the memory device has a function of operating at a refresh interval of longer than or equal to 10 minutes and shorter than or equal to one hour in an environment of higher than or equal to 20° C. and lower than or equal to 85° C.

Note that the refresh interval can be longer than or equal to 10 minutes and shorter than or equal to 10 hours in an environment of higher than or equal to 20° C. and lower than or equal to 85° C.

The peripheral circuit has a function of writing data to the memory cell when the transistor is in an on state; the memory cell has a function of retaining the data when the transistor is in an off state; and the peripheral circuit has a function of reading out the data retained in the memory cell when the transistor is in an on state.

The metal oxide preferably contains one or both of In (indium) and Zn (zinc).

An electronic device of one embodiment of the present invention is an electronic device including the above memory device.

### Effect of the Invention

One embodiment of the present invention can provide a novel semiconductor device.

Another embodiment of the present invention can provide a semiconductor device with a small circuit area. Another embodiment of the present invention can provide a semiconductor device with low power consumption. Another embodiment of the present invention can provide a semiconductor device capable of high-speed operation.

Note that the descriptions of the effects do not disturb the existence of other effects. One embodiment of the present invention does not have to have all of these effects. Effects other than these will be apparent from the descriptions of the specification, the claims, the drawings, and the like, and effects other than these can be derived from the descriptions of the specification, the claims, the drawings, and the like.

### BRIEF DESCRIPTION OF THE DRAWINGS

FIG. 1 illustrates a structure example of a semiconductor device.

FIGS. 2(A), 2(B-1), 2(B-2), and 2(B-3) illustrate structure examples of a semiconductor device and a memory cell.

FIGS. 3(A) and 3(B) each illustrate an example of a stacked-layer structure of a semiconductor device.

FIG. 4 illustrates a structure example of a semiconductor device.

FIG. 5 illustrates a structure example of a semiconductor device.

FIG. 6 illustrates a structure example of a semiconductor device.

FIG. 7 illustrates a structure example of a semiconductor device.

FIG. 8 illustrates a structure example of a sense amplifier.

FIG. 9 is a timing chart.

FIG. 10 illustrates a structure example of a computer.

FIGS. 11(A), 11(B), and 11(C) illustrate a structure example of a semiconductor device.

FIG. 12 illustrates a structure example of a semiconductor device.

FIG. 13 illustrates a structure example of a semiconductor device.

FIGS. 14(A), 14(B), and 14(C) illustrate a structure example of a transistor.

FIGS. 15(A), 15(B), and 15(C) illustrate a structure example of a transistor.

FIGS. 16(A), 16(B), and 16(C) illustrate a structure example of a transistor.

FIGS. 17(A), 17(B), and 17(C) illustrate a structure example of a transistor.

FIGS. 18(A), 18(B), and 18(C) illustrate a structure example of a transistor.

FIG. 19 shows a product image.

FIGS. 20(A) and 20(B) illustrate structure examples of electronic devices.

FIG. 21 illustrates structure examples of electronic devices.

FIGS. 22(A), 22(B), and 22(C) illustrate structure examples of electronic devices.

FIGS. 23(A), 23(B), and 23(C) illustrate structure examples of electronic devices.

FIGS. 24(A) and 24(B) show Id-Vg characteristics of transistors.

FIG. 25 shows a relation between memory cell temperature and retention time.

FIG. 26 shows Hall mobility and carrier concentration of a CAAC-IGZO film.

FIGS. 27(A) and 27(B) are cross-sectional TEM images of a transistor.

FIGS. 28(A) and 28(B) show Id-Vg characteristics and field-effect mobility of a transistor.

FIGS. 29(A) and 29(B) show Icut and on/off ratio of a transistor.

FIG. 30 shows retention time and writing time of a memory cell.

### MODE FOR CARRYING OUT THE INVENTION

Embodiments of the present invention will be described in detail below with reference to the drawings. Note that the present invention is not limited to the descriptions in the following embodiments and it is easily understood by those skilled in the art that the modes and details can be variously changed without departing from the scope and spirit of the present invention. Therefore, the present invention should not be interpreted as being limited to the descriptions of the embodiments below.

In this specification and the like, a metal oxide means an oxide of metal in a broad sense. Metal oxides are classified into an oxide insulator, an oxide conductor (including a transparent oxide conductor), an oxide semiconductor (also referred to as OS), and the like. For example, in the case where a metal oxide is used in a channel formation region of a transistor, the metal oxide is called an oxide semiconductor in some cases. That is to say, in the case where a metal oxide has at least one of an amplifying function, a rectifying function, and a switching function, the metal oxide can also be called a metal oxide semiconductor. A transistor including a metal oxide in a channel formation region is also referred to as an OS transistor below.

In this specification and the like, metal oxides containing nitrogen are also collectively referred to as a metal oxide in some cases. A metal oxide containing nitrogen may be referred to as a metal oxynitride. The details of a metal oxide will be described later.

In the case where there is an explicit description, X and Y are connected, in this specification and the like, the case where X and Y are electrically connected, the case where X and Y are functionally connected, and the case where X and Y are directly connected are disclosed in this specification and the like. Accordingly, without being limited to a predetermined connection relation, for example, a connection relation shown in drawings or texts, a connection relation other than one shown in drawings or texts is regarded as being disclosed in the drawings or the texts. Here, X and Y each denote an object (e.g., a device, an element, a circuit, a wiring, an electrode, a terminal, a conductive film, or a layer).

An example of the case where X and Y are directly connected is the case where an element that allows electrical connection between X and Y (e.g., a switch, a transistor, a capacitor, an inductor, a resistor, a diode, a display element, a light-emitting device, or a load) is not connected between X and Y, and is the case where X and Y are connected without an element that allows electrical connection between X and Y (e.g., a switch, a transistor, a capacitor, an inductor, a resistor, a diode, a display element, a light-emitting device, or a load) placed therebetween.

In an example of the case where X and Y are electrically connected, at least one element that allows electrical connection between X and Y (e.g., a switch, a transistor, a capacitor, an inductor, a resistor, a diode, a display element, a light-emitting device, or a load) can be connected between X and Y. Note that a switch has a function of being controlled to be turned on or off. That is, a switch has a function of being turned on or off to control whether or not current flows. Alternatively, the switch has a function of selecting and changing a current path. Note that the case where X and Y are electrically connected includes the case where X and Y are directly connected.

An example of the case where X and Y are functionally connected is the case where one or more circuits that allow functional connection between X and Y (for example, a logic circuit (an inverter, a NAND circuit, a NOR circuit, or the like), a signal converter circuit (a DA converter circuit, an AD converter circuit, a gamma correction circuit, or the like), a potential level converter circuit (a power supply circuit (for example, a step-up circuit, a step-down circuit, or the like), a level shifter circuit for changing the potential level of a signal, or the like), a voltage source, a current source, a switching circuit, an amplifier circuit (a circuit capable of increasing signal amplitude, the amount of current, or the like, an operational amplifier, a differential amplifier circuit, a source follower circuit, a buffer circuit, or the like), a signal generator circuit, a memory circuit, a control circuit, or the like) can be connected between X and Y. Note that even if another circuit is sandwiched between X and Y, for example, X and Y are regarded as being functionally connected when a signal output from X is transmitted to Y. Note that the case where X and Y are functionally connected includes the case where X and Y are directly connected and the case where X and Y are electrically connected.

Note that in the case where there is an explicit description, X and Y are electrically connected, the case where X and Y are electrically connected (i.e., the case where X and Y are connected with another element or another circuit provided therebetween), the case where X and Y are functionally connected (i.e., the case where X and Y are functionally connected with another circuit provided therebetween), and the case where X and Y are directly connected (i.e., the case where X and Y are connected without another element or another circuit provided therebetween) are disclosed in this specification and the like. That is, in the case where there is an explicit description, being electrically connected, the same contents as the case where there is only an explicit description, being connected, are disclosed in this specification and the like.

In this specification and the like, expressions “one of a source and a drain” (or a first electrode or a first terminal) and “the other of the source and the drain” (or a second electrode or a second terminal) are used in description of the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation. In this specification and the like, two terminals except a gate are sometimes referred to as a first terminal and a second terminal or as a third terminal and a fourth terminal. Note that in this specification and the like, a channel formation region refers to a region where a channel is formed; this region is formed by application of a potential to the gate, so that current can flow between the source and the drain.

Furthermore, functions of a source and a drain might be switched when a transistor of opposite polarity is employed or a direction of current flow is changed in circuit operation, for example. Thus, the terms of source and drain are interchangeable for use in this specification and the like.

In this specification and the like, in the case where a transistor has two or more gates, these gates are referred to as a first gate and a second gate or as a front gate and a back gate in some cases. In particular, the term “front gate” can be replaced by the simple term “gate”. In addition, the term “back gate” can be replaced by the simple term “gate”.

In addition, in this specification and the like, the term such as an “electrode” or a “wiring” does not limit a function of the component. For example, an “electrode” is used as part of a “wiring” in some cases, and vice versa. Furthermore, the term “electrode” or “wiring” can also mean a formation of a plurality of “electrodes” and “wirings” formed in an integrated manner.

In this specification and the like, voltage and potential can be interchanged with each other as appropriate. The voltage refers to a potential difference from a reference potential. When the reference potential is a ground potential, for example, the voltage can be replaced by the potential. The ground potential does not necessarily mean 0 V. Potentials are relative values, and the potential applied to a wiring or the like is changed depending on the reference potential, in some cases.

In this specification and the like, the terms “wiring”, “signal line”, “power supply line”, and the like can be interchanged with each other depending on circumstances or conditions. For example, the term “wiring” can be changed into the term “signal line” in some cases. In addition, the term “wiring” can be changed into the term such as “power supply line” in some cases. Inversely, the term such as “signal line” or “power supply line” can be changed into the term “wiring” in some cases. The term such as “power supply line” can be changed into the term such as “signal line” in some cases. Conversely, the term such as “signal line” can be changed into the term such as “power supply line” in some cases. The term “potential” that is applied to a wiring can be changed into the term “signal” or the like depending on circumstances or conditions. Conversely, the term “signal” or the like can be changed into the term “potential” in some cases.

Even when a diagram shows that independent components are electrically connected to each other, one component has functions of a plurality of components in some cases. For example, when part of a wiring also functions as an electrode, one conductive film has a function of the wiring and a function of the electrode. Thus, electrical connection in this specification includes in its category such a case where one conductive film has functions of a plurality of components.

### Embodiment 1

In this embodiment, structure examples of a semiconductor device of embodiments of the present invention will be described.

### <Semiconductor Device>

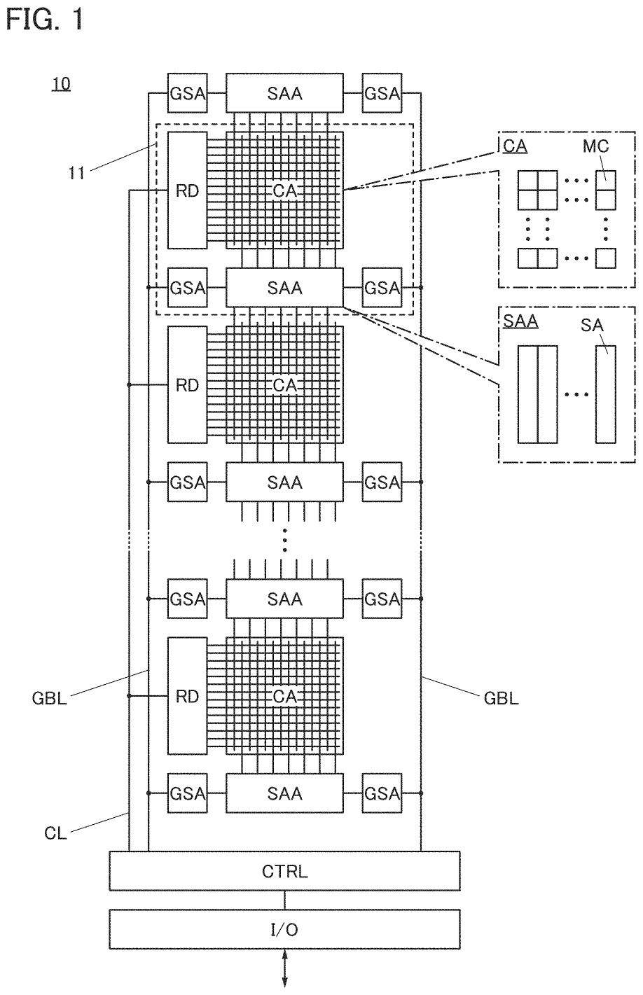

FIG. 1 illustrates a structure example of a semiconductor device 10 of one embodiment of the present invention. The semiconductor device 10 has a function of a memory device. Thus, the semiconductor device 10 can also be referred to as a memory device.

The semiconductor device 10 includes cell arrays CA, driver circuits RD, sense amplifier arrays SAA, global sense amplifiers GSA, a control circuit CTRL, and an input/output circuit I/O. In FIG. 1, a region composed of the cell array CA, the driver circuit RD, the sense amplifier array SAA, and two global sense amplifiers GSA is referred to as a block 11. The semiconductor device 10 includes a plurality of blocks 11.

The cell array CA is composed of a plurality of memory cells MC arranged in a matrix. The memory cell MC is a memory circuit having a function of storing data. Data stored in the memory cell MC may be 1-bit data (binary data) or data of two or more bits (multilevel data). Furthermore, the data may be analog data.

The driver circuit RD is a row decoder having a function of selecting the memory cells MC in a predetermined row. Specifically, the driver circuit RD has a function of supplying a signal for selecting the memory cell MC to/from which data is to be written or read out (hereinafter also referred to as a selection signal).

The sense amplifier array SAA is an amplifier circuit having a function of amplifying an input signal and outputting the amplified signal to the cell array CA or the global sense amplifier GSA. Specifically, the sense amplifier array SAA has a function of amplifying a potential corresponding to data to be written to the cell array CA (hereinafter this potential is also referred to as a write potential) and outputting the potential to the cell array CA, and a function of amplifying a potential corresponding to data read out from the cell array CA (hereinafter this potential is also referred to as a read potential) and outputting the potential to the global sense amplifier GSA. The sense amplifier array SAA has a function of selecting data to be output to the global sense amplifier GSA.

The sense amplifier array SAA can be composed of a plurality of sense amplifiers SA. A specific structure example of the sense amplifier SA will be described later.

The global sense amplifier GSA is an amplifier circuit having a function of amplifying an input signal and outputting the amplified signal to the sense amplifier array SAA or the control circuit CTRL. Specifically, the global sense amplifier GSA has a function of amplifying a write potential input through a wiring GBL from the control circuit CTRL and outputting the amplified potential to the sense amplifier array SAA. The global sense amplifier GSA has a function of amplifying a read potential input from the sense amplifier array SAA and outputting the amplified potential to the control circuit CTRL through the wiring GBL. The global sense amplifier GSA has a function of selecting data to be output to the wiring GBL.

The global sense amplifier GSA can be composed of a plurality of sense amplifiers SA, like the sense amplifier array SAA, for example.

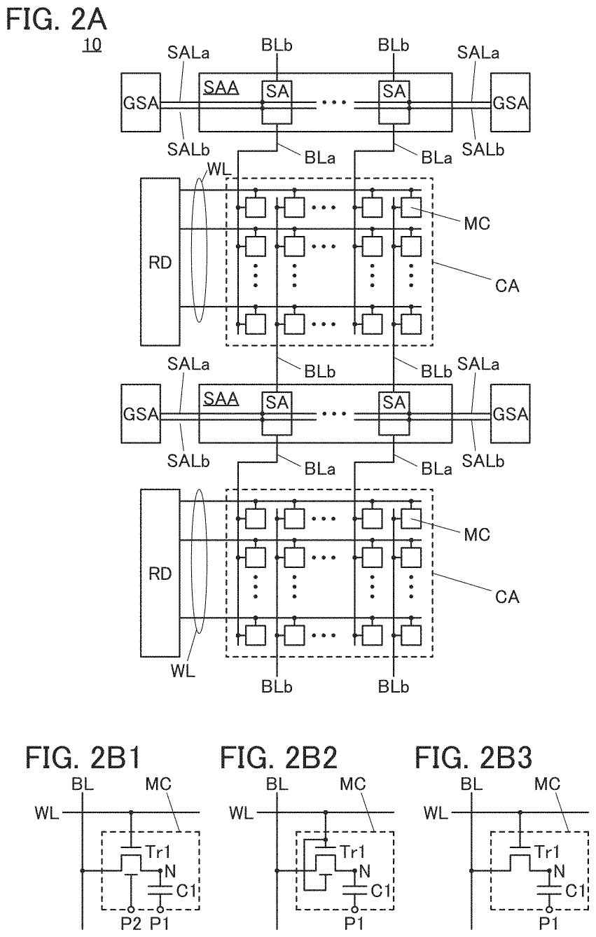

FIG. 2(A) illustrates a specific example of connection relation between the cell arrays CA, the driver circuits RD, the sense amplifier arrays SAA, and the global sense amplifiers GSA. The memory cells MC are connected to wirings WL and wirings BL. A selection signal is supplied from the driver circuit RD to the memory cell MC through the wiring WL. A write potential is supplied from the sense amplifier array SAA to the memory cell MC through the wiring BL. A read potential is supplied from the memory cell MC to the sense amplifier array SAA through the wiring BL.

The plurality of sense amplifiers SA included in the sense amplifier array SAA are each connected to a pair of wirings BL. FIG. 2(A) illustrates a structure example in which the wirings BL (wirings BLa) connected to the memory cells MC in odd-numbered columns included in one of the cell arrays CA and the wirings BL (wirings BLb) connected to the memory cells MC in even-numbered columns included in the other cell array CA are connected to the same sense amplifier SA. The potential difference between the wiring BLa and the wiring BLb is amplified by the sense amplifier SA. The amplified read potential is output to the global sense amplifier GSA through wirings SALa and SALb. Furthermore, in data writing, the potential difference between the wiring SALa and the wiring SALb is amplified by the sense amplifier SA, and the amplified potential is output as a write potential to the wirings BLa and BLb.

FIG. 2(A) illustrates an example where the sense amplifier array SAA is connected to two global sense amplifiers GSA. In this case, half of the sense amplifiers SA included in the sense amplifier array SSA are connected to one of the global sense amplifiers GSA, and the rest of the sense amplifiers SA are connected to the other global sense amplifier GSA.

The sense amplifiers SA each have a function of selecting whether to output a potential to the wirings SALa and SALb. Thus, a potential to be output from the sense amplifier array SAA to the global sense amplifier GSA can be selected.

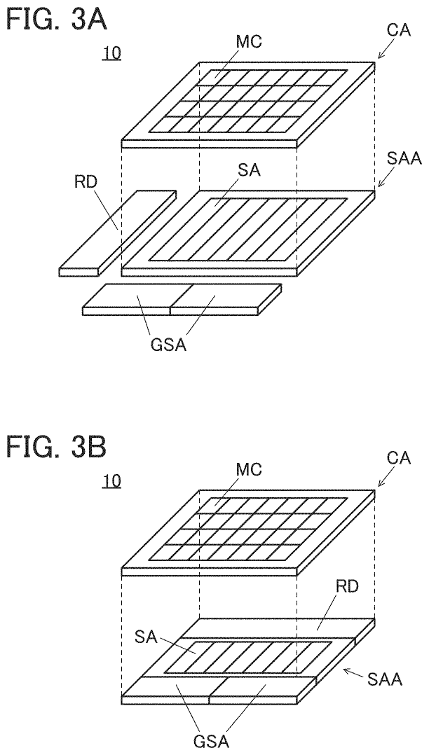

FIG. 2(B-1) to FIG. 2(B-3) illustrate specific structure examples of the memory cell MC. The memory cell MC illustrated in FIG. 2(B-1) includes a transistor Tr1 and a capacitor C1. A gate of the transistor Tr1 is connected to the wiring WL, one of a source and a drain thereof is connected to one electrode of the capacitor C1, and the other of the source and the drain thereof is connected to the wiring BL. The other electrode of the capacitor C1 is connected to a terminal P1. A node that is connected to the one of the source and the drain of the transistor Tr1 and the one electrode of the capacitor C1 is referred to as a node N.

A predetermined potential is supplied to the node N from the wiring BL through the transistor Tr1. When the transistor Tr1 is off, the node N is in a floating state and thus the potential of the node N is retained. This enables storage of data in the memory cell MC. Note that the on/off state of the transistor Tr1 can be controlled by a potential (selection signal) supplied to the wiring WL.

The transistor Tr1 includes a back gate connected to a terminal P2. The threshold voltage of the transistor Tr1 can be controlled by controlling the potential of the terminal P2. For example, a fixed potential (e.g., a negative constant potential) or a potential varying depending on the operation of the memory cell MC may be used as the potential to be supplied to the terminal P2.

Here, an OS transistor is preferably used as the transistor Tr1. A metal oxide has a wider band gap and a lower carrier density than other semiconductors such as silicon; thus, the off-state current of an OS transistor is extremely low. Note that off-state current refers to current that flows between a source and a drain when a transistor is off Therefore, when an OS transistor is used as the transistor Tr1, a potential can be retained at the node N for a long period, and operation in which another writing is performed at predetermined intervals (refresh operation) becomes unnecessary or the frequency of refresh operations can be extremely low. Thus, the power consumption of the semiconductor device 10 can be reduced.

In addition, an OS transistor has a higher withstand voltage than a transistor including silicon (single crystal silicon or the like) in its channel formation region (hereinafter, such a transistor is also referred to as a Si transistor). Therefore, when the transistor Tr1 is an OS transistor, the range of potentials retained at the node N can be widened.

As a metal oxide, a Zn oxide, a Zn—Sn oxide, a Ga—Sn oxide, an In—Ga oxide, an In—Zn oxide, an In-M-Zn oxide (M is Ti, Ga, Y, Zr, La, Ce, Nd, Sn, or Hf), or the like can be used, for example. In addition, an oxide containing indium and zinc may contain one or more kinds of elements selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like. The case where an n-channel OS transistor is used as the transistor Tr1 is specifically described here.

As illustrated in FIG. 2(B-2), the back gate of the transistor Tr1 may be connected to a front gate. This can increase the on-state current of the transistor Tr1. The transistor Tr1 does not need to include a back gate as illustrated in FIG. 2(B-3).

The control circuit CTRL illustrated in FIG. 1 has a function of overseeing the whole operation of the semiconductor device 10 and controlling data reading and data writing.

Specifically, the control circuit CTRL has a function of generating a variety of control signals for data reading and data writing by processing a signal input from the outside. For example, the control circuit CTRL generates a signal for controlling the operation of the driver circuit RD, and the signal is supplied to the driver circuit RD through a wiring CL.

The input/output circuit I/O has a function of receiving data from the outside and transmitting data to the outside. The input/output circuit I/O is connected to the control circuit CTRL.

In order to increase the operation speed of the semiconductor device 10, parasitic capacitance added to the wiring BL is preferably reduced. In order to reduce parasitic capacitance, it is preferable that the number of memory cells MC connected to one wiring BL be small and the number of intersection portions of the wirings BL and the wirings WL be small. Thus, a plurality of cell arrays CA are preferably provided as illustrated in FIG. 1 to reduce the number of memory cells MC included in one cell array CA. However, with the increase in the number of the cell arrays CA, the number of the sense amplifier arrays SAA also increases. Therefore, if the cell arrays CA are each divided to increase the operation speed, an increase in the number of the sense amplifier arrays SAA might increase the circuit area.

An OS transistor can be stacked above another element (e.g., a transistor). Thus, the use of an OS transistor in the memory cell MC allows the cell array CA to be stacked above the sense amplifier array SAA as illustrated in FIG. 3(A). This can reduce or preclude an increase in the circuit area even in the case where the number of the sense amplifier arrays SAA is increased. Thus, while an increase in area is inhibited, the parasitic capacitance of the wiring BL can be reduced, and the operation speed of the semiconductor device 10 can be increased.

Furthermore, a circuit other than the sense amplifier array SAA can also be provided at a position overlapping with the cell array CA. For example, as illustrated in FIG. 3(B), the driver circuit RD and the global sense amplifiers GSA in addition to the sense amplifier array SAA may be positioned so as to overlap with the cell array CA. This can further reduce the circuit area of the semiconductor device 10.

In the case where a circuit other than the sense amplifier array SAA is positioned at a position overlapping with the cell array CA, the circuit area of the sense amplifier array SAA is preferably as small as possible. For example, the number of the memory cells MC connected to one sense amplifier SA is doubled and the number of the sense amplifiers SA is reduced by half, whereby the area of the sense amplifier array SAA can be reduced by half.

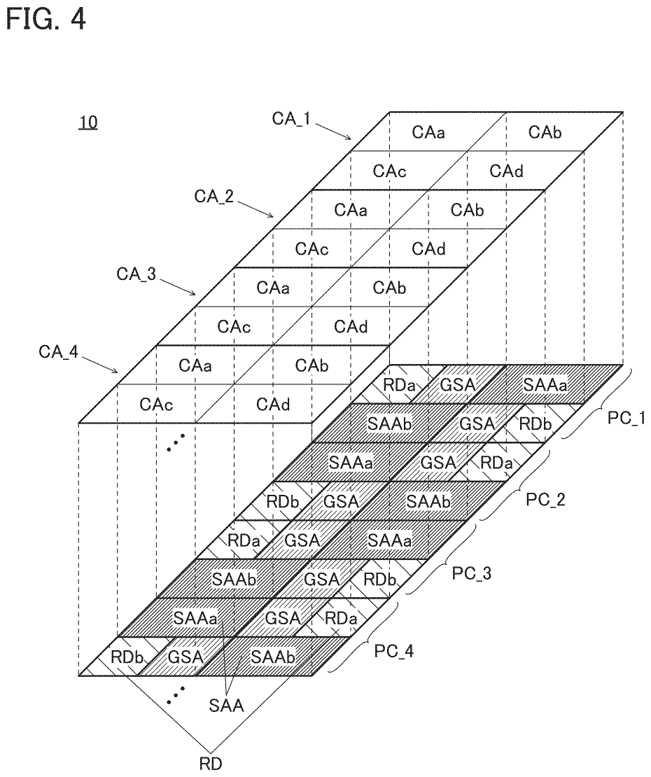

FIG. 4 illustrates a specific example of the stacked-layer structure illustrated in FIG. 3(B). In FIG. 4, the driver circuits RD, the sense amplifier arrays SAA, and the global sense amplifiers GSA are positioned so as to overlap with the cell arrays CA. Note that peripheral circuits PC correspond to circuits other than the cell arrays CA, specifically, circuits each composed of the driver circuits RD, the sense amplifier arrays SAA, and the global sense amplifiers GSA. FIG. 4 illustrates four cell arrays CA (CA_1 to CA_4), and four peripheral circuits PC (PC_1 to PC_4) arranged in a region overlapping with the cell arrays CA_1 to CA_4, as a typical example.

In the peripheral circuit PC, the driver circuit RD is divided into driver circuits RDa and RDb, and the sense amplifier array SAA is divided into sense amplifier arrays SAAa and SAAb. That is, a circuit composed of the driver circuits RDa and RDb corresponds to the driver circuit RD in FIG. 1. A circuit composed of the sense amplifier arrays SAAa and SAAb corresponds to the sense amplifier array SAA in FIG. 1.

The driver circuits RDa and RDb, the sense amplifier arrays SAAa and SAAb, and the global sense amplifiers GSA are arranged as illustrated in FIG. 4. Specifically, the driver circuit RDa is adjacent to the driver circuit RDb, the sense amplifier array SAAb, and the global sense amplifier GSA. The driver circuit RDb is adjacent to the driver circuit RDa, the sense amplifier array SAAa, and the global sense amplifier GSA. The sense amplifier array SAAa is adjacent to the driver circuit RDb, the sense amplifier array SAAb, and two global sense amplifiers GSA. The sense amplifier array SAAb is adjacent to the driver circuit RDa, the sense amplifier array SAAa, and two global sense amplifiers GSA. The global sense amplifier GSA is adjacent to the driver circuit RDa or the driver circuit RDb, the sense amplifier array SAAa, the sense amplifier array SAAb, and another global sense amplifier GSA.

As illustrated in FIG. 4, the driver circuits RDa and RDb, the sense amplifier arrays SAAa and SAAb, and two global sense amplifiers GSA are arranged so as to each include a region overlapping with the cell array CA. Specifically, when the cell array CA is divided into four sub arrays CAa to CAd, the driver circuit RDa and the global sense amplifier GSA, the driver circuit RDb and the global sense amplifier GSA, the sense amplifier array SAAa, and the sense amplifier array SAAb each include a region overlapping with any of the sub arrays CAa to CAd. For example, when the cell array CA_1 and the peripheral circuit PC_1 are focused on, the sub array CAa includes a region overlapping with the driver circuit RDa and the global sense amplifier GSA, the sub array CAb includes a region overlapping with the sense amplifier array SAAa, the sub array CAc includes a region overlapping with the sense amplifier array SAAb, and the sub array CAd includes a region overlapping with the driver circuit RDb and the global sense amplifier GSA.

When the peripheral circuit PC is provided in the above manner, the driver circuits RD and the global sense amplifiers GSA as well as the sense amplifier arrays SAA can be provided so as to overlap with the cell array CA. Consequently, the circuit area of the semiconductor device 10 can be reduced.

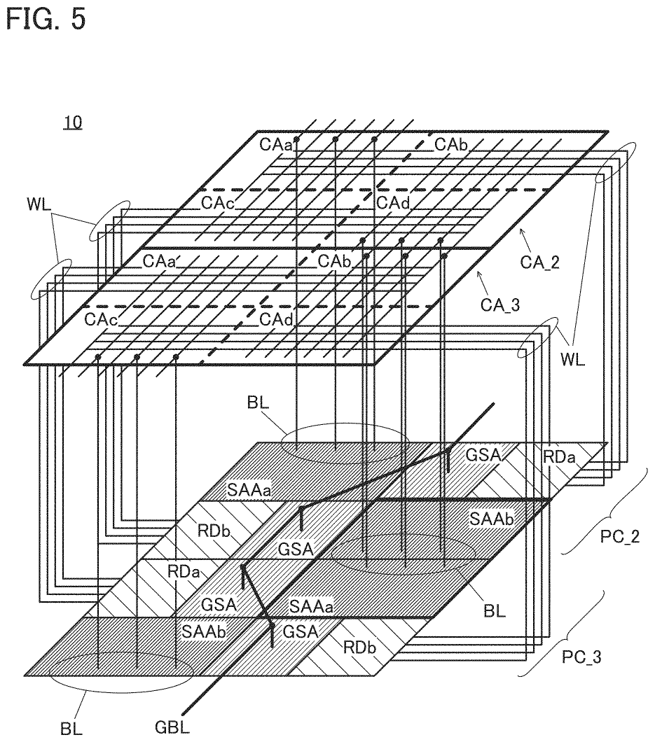

FIG. 5 illustrates an example of a connection structure of the cell arrays CA and the peripheral circuits PC. Here, as a typical example, the cell arrays CA_2 and CA_3 and the peripheral circuits PC_2 and PC_3 in FIG. 4 are illustrated. The driver circuits RDa and RDb are connected to the cell arrays CA through the wirings WL. The sense amplifier arrays SAAa and SAAb are connected to the cell arrays CA through the wirings BL. The global sense amplifiers GSA are connected to the wiring GBL provided in a layer between the peripheral circuits PC and the cell arrays CA. Although not illustrated in FIG. 5, the memory cells MC are provided at intersection portions of the wirings WL and the wirings BL in the cell arrays CA (see FIG. 2).

The driver circuit RDa is connected to the memory cells MC included in the sub arrays CAa and CAb through the wirings WL. The driver circuit RDb is connected to the memory cells MC included in the sub arrays CAc and CAd through the wirings WL. The driver circuit RDa has a function of supplying a selection signal to the sub arrays CAa and CAb, and the driver circuit RDb has a function of supplying a selection signal to the sub arrays CAc and CAd. In this manner, the driver circuit RDa and the driver circuit RDb are used to select the memory cell MC in one cell array CA.

The sense amplifier arrays SAAa and SAAb are connected to two respective cell arrays CA adjacent to each other, through the wirings BL. For example, the sense amplifier arrays SAAa and SAAb (the sense amplifier array SAAb of the peripheral circuit PC_2 and the sense amplifier array SAAa of the peripheral circuit PC_3) are connected to two respective cell arrays CA (CA_2 and CA_3) in FIG. 5. The sense amplifier array SAAa and the sense amplifier array SAAb have a function of amplifying the potential difference between the wiring BL connected to the cell array CA_2 and the wiring BL connected to the cell array CA_3.

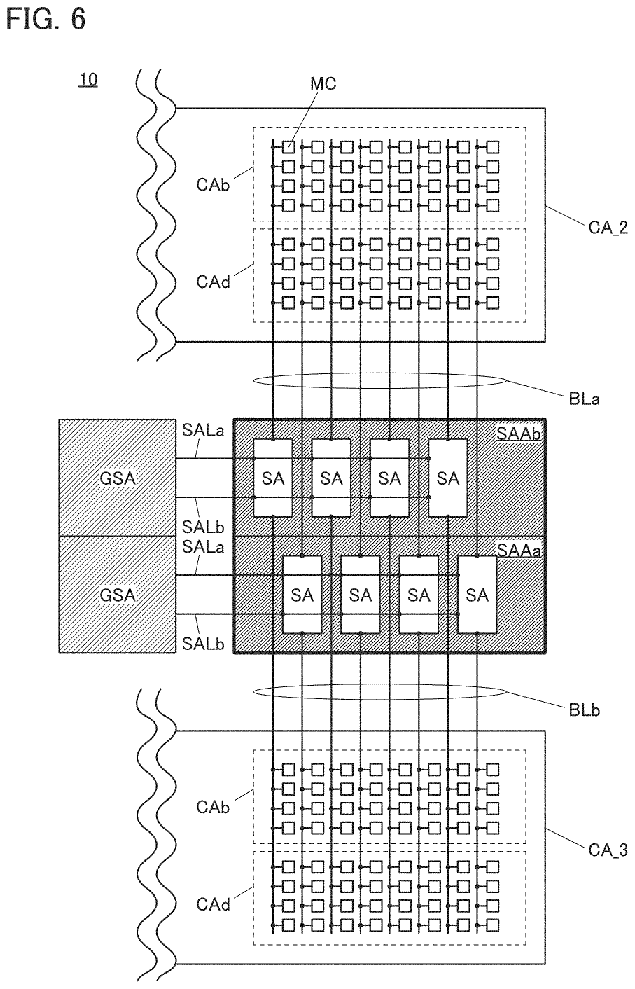

FIG. 6 illustrates an example of the connection relation between the sense amplifier arrays SAAa and SAAb provided adjacent to each other and the cell arrays CA_2 and CA_3.

In FIG. 6, the wirings BL connected to the cell array CA_2 are referred to as the wirings BLa, and the wirings BL connected to the cell array CA_3 are referred to as the wirings BLb.

The sense amplifier arrays SAAa and SAAb each include a plurality of sense amplifiers SA. The sense amplifiers SA are each connected to the global sense amplifier GSA through the wirings SALa and SALb.

The sense amplifiers SA included in the sense amplifier array SAAb are connected to the wirings BLa in odd-numbered columns and the wirings BLb in odd-numbered columns. The sense amplifiers SA included in the sense amplifier array SAAa are connected to the wirings BLa in even-numbered columns and the wirings BLb in even-numbered columns. The sense amplifiers SA each have a function of amplifying the potential difference between the wiring BLa and the wiring BLb and outputting the amplified potential difference to the wiring SALa and the wiring SALb. In this manner, the sense amplifier arrays SAAa and SAAb can amplify data read out from the sub arrays CAb and CAd of the cell array CA_2 and data read out from the sub arrays CAb and CAd of the cell array CA_3.

Note that the connection relation between the sense amplifiers SA and the wirings BL is not limited to the above. That is, any connection relation can be employed as long as the sense amplifier arrays SAAa and SAAb can amplify data read out from the sub arrays CAb and CAd of the cell array CA_2 and data read out from the sub arrays CAb and CAd of the cell array CA_3. For example, the sense amplifier array SAAb may amplify data read out from the sub arrays CAb and CAd of the cell array CA_2, and the sense amplifier array SAAa may amplify data read out from the sub arrays CAb and CAd of the cell array CA_3.

The data amplified by the sense amplifier arrays SAAa and SAAb are selectively input to adjacent global sense amplifiers GSA. Note that in FIG. 4 and FIG. 5, each of the sense amplifier arrays SAAa and SAAb is adjacent to two global sense amplifiers GSA, and the outputs of the sense amplifier arrays SAAa and SAAb are input to either of the global sense amplifiers GSA. The data amplified by the global sense amplifier GSA is output to the wiring GBL.

The wiring GBL is provided so as to overlap with the cell arrays CA and the peripheral circuits PC, whereby the circuit area can be reduced. However, as illustrated in FIG. 5, a large number of wirings (e.g., the wirings WL and the wirings BL) are provided between the cell arrays CA and the peripheral circuits PC. Therefore, the wiring GBL needs to be positioned so as not to contact with these wirings. Here, employing the arrangement of the peripheral circuits PC of one embodiment of the present invention allows formation of a path of the wiring GBL that enables it to cross the plurality of peripheral circuits PC while avoiding being in contact with a wiring group of the wirings WL and a wiring group of the wirings BL.

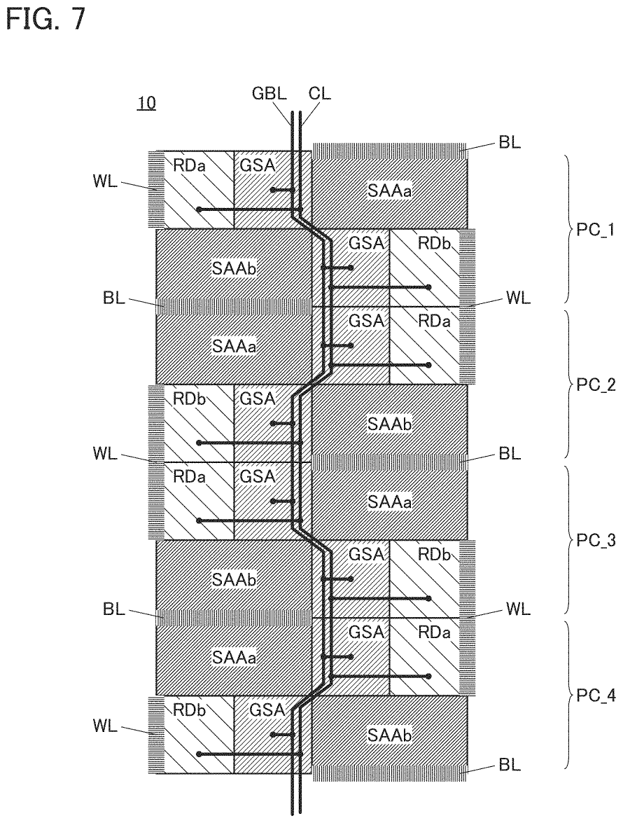

FIG. 7 shows a top view of the peripheral circuits PC_1 to PC_4. In the case where circuits included in the peripheral circuits PC_1 to PC_4 are arranged in the above-described manner, the wiring GBL connected to the plurality of global sense amplifiers GSA can be formed so as to cross the plurality of peripheral circuits PC while avoiding being in contact with the wirings WL and the wirings BL, as illustrated in FIG. 7.

In addition, a wiring other than the wiring GBL, for example, the wiring CL (see FIG. 1) for connecting the control circuit CTRL and the driver circuits RD can be positioned in the same path as the wiring GBL. FIG. 7 illustrates a structure in which the wiring CL is also provided so as to cross the peripheral circuits PC. This allows the wiring CL to be positioned in a region overlapping with the peripheral circuits PC and the cell arrays CA, further reducing the circuit area.

Employing the arrangement of the peripheral circuits PC of one embodiment of the present invention in the above manner allows the cell arrays CA to be positioned so as to overlap with the driver circuits RD, the sense amplifier arrays SAA, and the global sense amplifiers GSA. Furthermore, the wiring GBL and the wiring CL can be positioned so as to overlap with the cell arrays CA and the peripheral circuits PC. Consequently, the circuit area of the semiconductor device 10 can be reduced.

### <Sense Amplifier>

Next, a structure example and an operation example of the sense amplifier SA will be described. Here, as an example, the sense amplifier SA connected to the memory cells MC, i.e., the sense amplifier SA used in the sense amplifier array SAA will be described. The sense amplifier SA described below can also be used as the global sense amplifier GSA.

### [Structure Example]

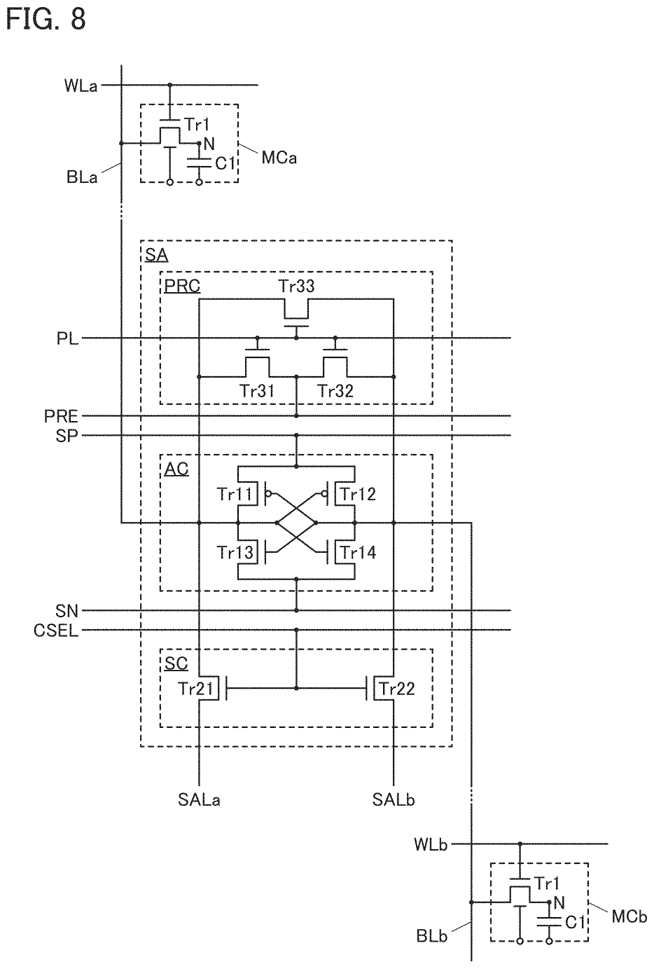

FIG. 8 illustrates a circuit structure example of the sense amplifier SA. Here, a memory cell MCa connected to the wiring WLa and the wiring BLa, a memory cell MCb connected to the wiring WLb and the wiring BLb, and the sense amplifier SA connected to the memory cells MCa and MCb are illustrated as an example. For the memory cells MCa and MCb, the structure illustrated in FIG. 2(B-1) is used. The sense amplifier SA includes an amplifier circuit AC, a switch circuit SC, and a precharge circuit PRC.

The amplifier circuit AC includes a p-channel transistor Tr11, a p-channel transistor Tr12, an n-channel transistor Tr13, and an n-channel transistor Tr14. One of a source and a drain of the transistor Tr11 is connected to a wiring SP, and the other of the source and the drain thereof is connected to a gate of the transistor Tr12, a gate of the transistor Tr14, and the wiring BLa. One of a source and a drain of the transistor Tr13 is connected to the gate of the transistor Tr12, the gate of the transistor Tr14, and the wiring BLa, and the other of the source and the drain thereof is connected to a wiring SN. One of a source and a drain of the transistor Tr12 is connected to the wiring SP, and the other of the source and the drain thereof is connected to a gate of the transistor Tr11, a gate of the transistor Tr13, and the wiring BLb. One of a source and a drain of the transistor Tr14 is connected to the gate of the transistor Tr11, the gate of the transistor Tr13, and the wiring BLb, and the other of the source and the drain thereof is connected to the wiring SN. The amplifier circuit AC has a function of amplifying the potentials of the wirings BLa and BLb. The sense amplifier SA including the amplifier circuit AC functions as a latch sense amplifier.

The switch circuit SC includes an n-channel transistor Tr21 and an n-channel transistor Tr22. Note that the transistor Tr21 and the transistor Tr22 may be p-channel transistors. One of a source and a drain of the transistor Tr21 is connected to the wiring BLa, and the other of the source and the drain thereof is connected to the wiring SALa. One of a source and a drain of the transistor Tr22 is connected to the wiring BLb, and the other of the source and the drain thereof is connected to the wiring SALb. A gate of the transistor Tr21 and a gate of the transistor Tr22 are connected to a wiring CSEL.

The switch circuit SC has a function of controlling electrical continuity between the wiring BLa and the wiring SALa and electrical continuity between the wiring BLb and the wiring SALb on the basis of a potential supplied to the wiring CSEL. That is, whether a potential is output to the wiring SALa and the wiring SALb can be selected by the switch circuit SC.

The precharge circuit PRC includes n-channel transistors Tr31 to Tr33. Note that the transistors Tr31 to Tr33 may be p-channel transistors. One of a source and a drain of the transistor Tr31 is connected to the wiring BLa, and the other of the source and the drain thereof is connected to a wiring PRE. One of a source and a drain of the transistor Tr32 is connected to the wiring BLb, and the other of the source and the drain thereof is connected to the wiring PRE. One of a source and a drain of the transistor Tr33 is connected to the wiring BLa, and the other of the source and the drain thereof is connected to the wiring BLb. A gate of the transistor Tr31, a gate of the transistor Tr32, and a gate of the transistor Tr33 are connected to a wiring PL. The precharge circuit PRC has a function of initializing the potentials of the wiring BLa and the wiring BLb.

The wiring SP, the wiring SN, the wiring CSEL, the wiring PRE, and the wiring PL have a function of transmitting a signal for controlling the operation of the sense amplifier SA. These wirings are connected to the driver circuit RD illustrated in FIG. 1, and the sense amplifier SA operates in response to a control signal input from the driver circuit RD.

### [Operation Example]

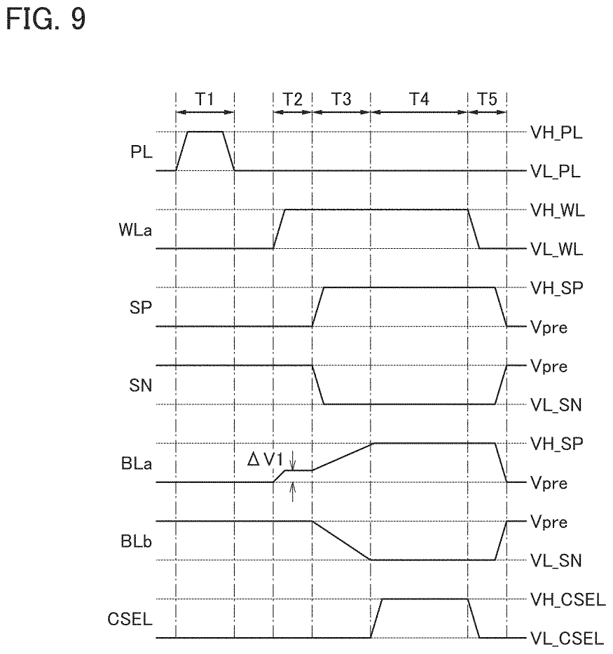

Next, an operation example of the sense amplifier SA when data is read out from the memory cell MCa will be described with reference to a timing chart shown in FIG. 9.

First, in a period T1, the precharge circuit PRC is operated, and the potentials of the wiring BLa and the wiring BLb are initialized. Specifically, the potential of the wiring PL is set to a high level (VH_PL) to turn on the transistors Tr31 to Tr33. Thus, a potential Vpre of the wiring PRE is supplied to the wiring BLa and the wiring BLb. The potential Vpre can be set to (VH_SP+VL_SN)/2, for example. After that, the potential of the wiring PL is set to a low level (VL_PL) to turn off the transistors Tr31 to Tr33.

Note that the potential of the wiring CSEL is at a low level (VL_CSEL) in the period T1, and the transistors Tr21 and Tr22 in the switch circuit SC are off. In addition, the potential of the wiring WLa is at a low level (VL_WL), and the transistor Tr1 included in the memory cell MCa is off. Similarly, although not illustrated in FIG. 9, the potential of the wiring WLb is at a low level (VL_WL), and the transistor Tr1 included in the memory cell MCb is off. In addition, the potentials of the wiring SP and the wiring SN are the potential Vpre, and the sense amplifier SA is in a halting state.

Next, the wiring WLa is selected in a period T2. Specifically, the potential of the wiring WLa is set to a high level (VH_WL) to turn on the transistor Tr1 included in the memory cell MCa. This establishes electrical continuity between the wiring BLa and the capacitor C1 through the transistor Tr1 in the memory cell MCa, and the potential of the wiring BLa is changed in accordance with the amount of charge that is retained in the capacitor C1.

FIG. 9 illustrates the case where data “1” is stored in the memory cell MCa and the amount of charge accumulated in the capacitor C1 is large, as an example. Specifically, in the case where the amount of charge accumulated in the capacitor C1 is large, the release of charge from the capacitor C1 to the wiring BLa increases the potential of the wiring BLa from the potential Vpre by ΔV1. On the other hand, in the case where data “0” is stored in the memory cell MCa and the amount of charge accumulated in the capacitor C1 is small, charge flows from the wiring BLa to the capacitor C1, decreasing the potential of the wiring BLa by ΔV2.

The potential of the wiring CSEL is at a low level (VL_CSEL) in the period T2, and the transistors Tr21 and Tr22 in the switch circuit SC are off. In addition, the potentials of the wiring SP and the wiring SN are the potential Vpre, and the sense amplifier SA remains in a halting state.

Then, in a period T3, the potential of the wiring SP is set to a high level (VH_SP) and the potential of the wiring SN is set to a low level (VL_SN) to bring the amplifier circuit AC into an operating state. The amplifier circuit AC has a function of amplifying the potential difference between the wiring BLa and the wiring BLb (ΔV1 in FIG. 9). Bringing the amplifier circuit AC into an operating state makes the potential of the wiring BLa closer to the potential of the wiring SP (VH_SP) from Vpre+ΔV1. In addition, the potential of the wiring BLb gets closer to the potential of the wiring SN (VL_SN) from Vpre.

Note that in the case where the potential of the wiring BLa is Vpre−ΔV2 in the initial stage of the period T3, bringing the amplifier circuit AC into an operating state makes the potential of the wiring BLa closer to the potential of the wiring SN (VL_SN) from Vpre−ΔV2. In addition, the potential of the wiring BLb gets closer to the potential of the wiring SP (VH_SP) from the potential Vpre.

The potential of the wiring PL is at a low level (VL_PL) in the period T3, and the transistors Tr31 to Tr33 in the precharge circuit PRC are off. The potential of the wiring CSEL is at a low level (VL_CSEL), and the transistors Tr21 and Tr22 in the switch circuit SC are off. The potential of the wiring WLa is at a high level (VH_WL), and the transistor Tr1 included in the memory cell MCa is on. Consequently, charge corresponding to the potential of the wiring BLa (VH_SP) is accumulated in the capacitor C1 in the memory cell MCa.

Next, in a period T4, the potential of the wiring CSEL is controlled to turn on the switch circuit SC. Specifically, setting the potential of the wiring CSEL to a high level (VH_CSEL) turns on the transistors Tr21 and Tr22. Accordingly, the potential of the wiring BLa is supplied to the wiring SALa, and the potential of the wiring BLb is supplied to the wiring SALb.

Note that the potential of the wiring PL is at a low level (VL_PL) in the period T4, and the transistors Tr31 to Tr33 in the precharge circuit PRC are off. The potential of the wiring WLa is at a high level (VH_WL), and the transistor Tr1 included in the memory cell MCa is on. The potential of the wiring SP is at a high level (VH_SP), the potential of the wiring SN is at a low level (VL_SN), and the amplifier circuit AC is in an operating state. Consequently, charge corresponding to the potential of the wiring BLa (VH_SP) is accumulated in the capacitor C1 in the memory cell MCa.

Next, in a period T5, the potential of the wiring CSEL is controlled to turn off the switch circuit SC. Specifically, the potential of the wiring CSEL is set to a low level (VL_CSEL) to turn off the transistors Tr21 and Tr22.

In addition, the wiring WLa is unselected in the period T5. Specifically, the potential of the wiring WLa is set to a low level (VL_WL) to turn off the transistor Tr1 included in the memory cell MCa. Thus, charge corresponding to the potential of the wiring BLa (VH_SP) is retained in the capacitor C1 included in the memory cell MCa. Accordingly, data is retained in the memory cell MCa even after the data is read out.

Note that in the period T5, even when the switch circuit SC is turned off, the potential difference between the wiring BLa and the wiring BLb is held by the amplifier circuit AC as long as the sense amplifier SA is in an operating state. Therefore, the sense amplifier SA has a function of temporarily retaining data that has been read out from the memory cell MCa.

Through the operations described above, data is read out from the memory cell MCa. Data in the memory cell MCb can be read out similarly.

Data can be written to the memory cell MCa on the principle similar to that described above. Specifically, first, the transistors Tr31 to Tr33 included in the precharge circuit PRC are temporarily turned on to initialize the potentials of the wiring BLa and the wiring BLb, in a manner similar to that in the case where data is read out.

Then, the wiring WLa that is connected to the memory cell MCa to which data is to be written is selected, and the transistor Tr1 included in the memory cell MCa is turned on. This establishes electrical continuity between the wiring BLa and the capacitor C1 through the transistor Tr1, in the memory cell MCa.

Then, the potential of the wiring SP is set to a high level (VH_SP) and the potential of the wiring SN is set to a low level (VL_SN), to bring the amplifier circuit AC into an operating state.

Then, the potential of the wiring CSEL is controlled to turn on the switch circuit SC. This establishes electrical continuity between the wiring BLa and the wiring SALa and electrical continuity between the wiring BLb and the wiring SALb. Then, a write potential is supplied to the wiring SALa, whereby the write potential is supplied to the wiring BLa through the switch circuit SC. Through these operations, charge is accumulated in the capacitor C1 included in the memory cell MCa according to the potential of the wiring BLa, and data is written to the memory cell MCa.

Note that after the potential of the wiring SALa is supplied to the wiring BLa, the potential difference between the wiring BLa and the wiring BLb is retained by the amplifier circuit AC as long as the sense amplifier SA is in an operating state, even when the transistors Tr21 and Tr22 are turned off in the switch circuit SC. Thus, the timing of switching the transistors Tr21 and Tr22 from an on state to an off state can be either before or after the wiring WLa is selected.

The use of a plurality of sense amplifiers SA described above enables formation of the sense amplifier array SAA or the global sense amplifier GSA.

As described in this embodiment, in one embodiment of the present invention, the driver circuit RD, the sense amplifier array SAA, and the global sense amplifier GSA can be provided so as to overlap with the cell arrays CA, resulting in a reduction in the circuit area of the semiconductor device 10. Employing the arrangement of the peripheral circuits PC of one embodiment of the present invention allows wirings crossing the plurality of peripheral circuits PC, such as the wiring GBL and the wiring CL, to be provided so as to overlap with a layer between the cell arrays CA and the peripheral circuits PC, and the circuit area of the semiconductor device 10 can be further reduced.

This embodiment can be combined with the descriptions of the other embodiments as appropriate.

### Embodiment 2

In this embodiment, a structure example of a computer using the semiconductor device described in the above embodiment will be described.

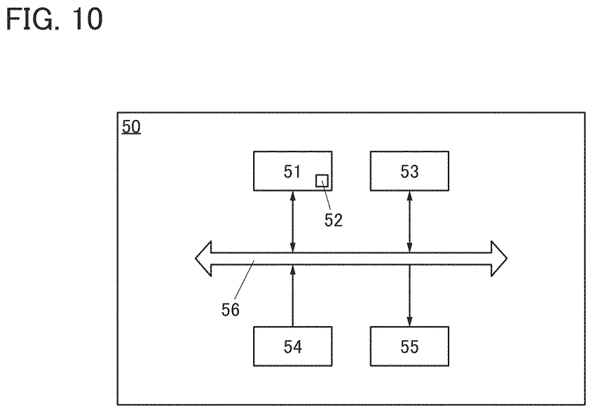

The semiconductor device 10 described above can be used for a computer. FIG. 10 illustrates a structure example of a computer 50. The computer 50 includes a processing unit 51, a memory unit 53, an input unit 54, and an output unit 55. The processing unit 51, the memory unit 53, the input unit 54, and the output unit 55 are connected to a transmission path 56, and data transmission and reception between them can be performed through the transmission path 56.

The processing unit 51 has a function of performing an arithmetic operation using data supplied from the memory unit 53, the input unit 54, or the like. The results of the arithmetic operation by the processing unit 51 are supplied to the memory unit 53, the output unit 55, or the like. The processing unit 51 can perform a variety of kinds of data processing and program control by executing a program stored in the memory unit 53.

The processing unit 51 can be composed of, for example, a central processing unit (CPU). The processing unit 51 can also be formed using a microprocessor such as a DSP

(Digital Signal Processor) or a GPU (Graphics Processing Unit). The microprocessor may be composed of a PLD (Programmable Logic Device) such as an FPGA (Field Programmable Gate Array) or an FPAA (Field Programmable Analog Array).

The processing unit 51 may include the memory unit 52. The memory unit 52 has a function of a cache memory. Part of data stored in the memory unit 53 is stored in the memory unit 52.

The memory unit 53 has a function of storing data used for an arithmetic operation by the processing unit 51, a program executed by the processing unit 51, or the like. That is, the memory unit 53 has a function of a main memory device of the computer 50.

The input unit 54 has a function of supplying data input from the outside of the computer 50 to the processing unit 51, the memory unit 53, or the like. The output unit 55 has a function of outputting data stored in the memory unit 53, or the like, as a result of processing by the processing unit 51, to the outside of the computer 50.

The semiconductor device 10 described in the above embodiment can be used for the memory unit 52 or the memory unit 53. In other words, the semiconductor device 10 can be used as a cache memory or a main memory device of the computer 50. Accordingly, the computer 50 having low power consumption and the small circuit area can be constructed.

Although the example in which the semiconductor device 10 is incorporated in a computer is described here, an application example of the semiconductor device 10 is not limited thereto. For example, when the semiconductor device 10 is used for an image processing circuit of a display device, a frame memory or the like can be constructed.

This embodiment can be combined with the descriptions of the other embodiments and examples as appropriate.

### Embodiment 3

Next, structures of a transistor and a capacitor included in a memory cell of the semiconductor device of one embodiment of the present invention will be described.

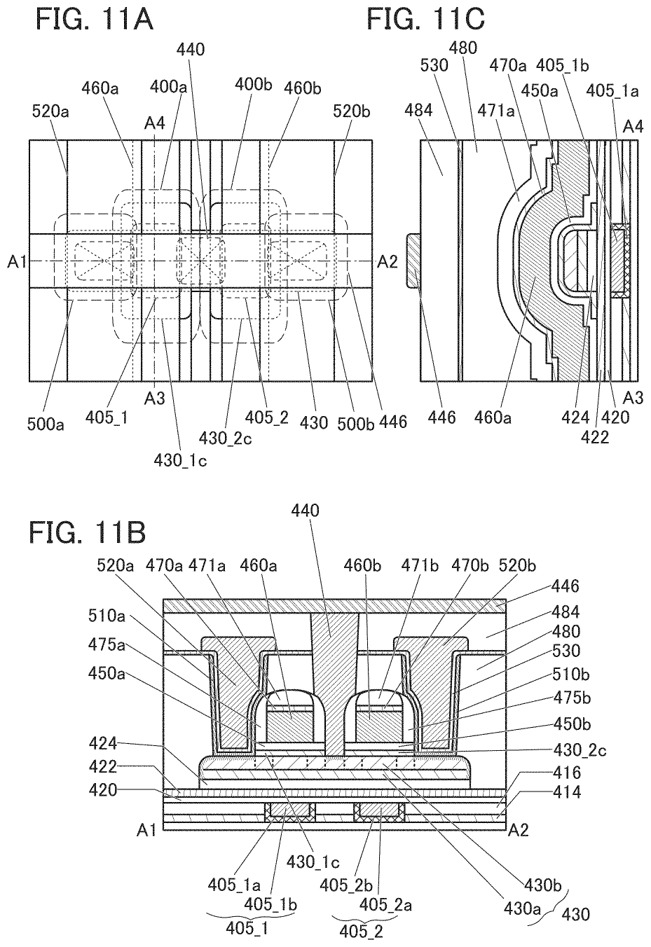

FIG. 11(A) shows a top view of a transistor 400a, a transistor 400b, a capacitor 500a, and a capacitor 500b when two memory cells share one bit line (wiring BL). The transistor 400a and the capacitor 500a are included in a first memory cell, and the transistor 400b and the capacitor 500b are included in a second memory cell.

FIG. 11(B) corresponds to a cross-sectional view along dashed-dotted line A1-A2 in FIG. 11(A), and FIG. 11(C) corresponds to a cross-sectional view along dashed-dotted line A3-A4 in FIG. 11(A). For simplification of the drawing, some components are not illustrated in the top view shown in FIG. 11(A).

As illustrated in FIG. 11, the transistor 400a includes a conductor 405_1 (a conductor 405_1a and a conductor 405_1b) positioned over an insulating surface so as to be embedded in an insulator 414 and an insulator 416; an insulator 420 positioned over the conductor 405_1 and the insulator 416; an insulator 422 positioned over the insulator 420; an insulator 424 positioned over the insulator 422; an oxide 430 (an oxide 430a and an oxide 430b) positioned over the insulator 424; an oxide 430_1c positioned over the oxide 430; an insulator 450a positioned over the oxide 430_1c; a conductor 460a positioned over the insulator 450a; an insulator 470a positioned over the conductor 460a; an insulator 471a positioned over the insulator 470a; and an insulator 475a positioned in contact with at least a side surface of the conductor 460a.

As illustrated in FIG. 11, the transistor 400b includes a conductor 405_2 (a conductor 405_2a and a conductor 405_2b) positioned over an insulating surface so as to be embedded in the insulator 414 and the insulator 416; the insulator 420 positioned over the conductor 405_2 and the insulator 416; the insulator 422 positioned over the insulator 420; the insulator 424 positioned over the insulator 422; the oxide 430 (the oxide 430a and the oxide 430b) positioned over the insulator 424; an oxide 430_2c positioned over the oxide 430; an insulator 450b positioned over the oxide 430_2c; a conductor 460b positioned over the insulator 450b; an insulator 470b positioned over the conductor 460b; an insulator 471b positioned over the insulator 470b; and an insulator 475b positioned in contact with at least a side surface of the conductor 460b.

Although FIG. 11 illustrates the structure where the transistor 400a and the transistor 400b include the oxide 430a and the oxide 430b that are stacked, the transistor 400a and the transistor 400b may have a structure with a single layer of only the oxide 430b. Alternatively, the transistor 400a and the transistor 400b may have a structure including three or more oxides that are stacked.

Although FIG. 11 illustrates the structure where the conductor 460a is a single layer and the conductor 460b is a single layer, for example, the conductor 460a may have a stacked-layer structure of two or more conductors, and the conductor 460b may have a stacked-layer structure of two or more conductors.

Note that the transistor 400b includes components corresponding to the components included in the transistor 400a. Thus, in drawings, the corresponding components in the transistor 400a and the transistor 400b are basically denoted by the same three-digit reference numerals. In addition, unless otherwise specified, the description of the transistor 400a can be referred to for the transistor 400b below.

As in the description of the transistor 400a, the capacitor 500b includes components corresponding to the components included in the capacitor 500a. Thus, in drawings, the corresponding components in the capacitor 500a and the capacitor 500b are basically denoted by the same three-digit reference numerals. Thus, unless otherwise specified, the description of the capacitor 500a can be referred to for the capacitor 500b below.

For example, the conductor 405_1, the oxide 430_1c, the insulator 450a, the conductor 460a, the insulator 470a, the insulator 471a, and the insulator 475a of the transistor 400a correspond to the conductor 405_2, the oxide 430_2c, the insulator 450b, the conductor 460b, the insulator 470b, the insulator 471b, and the insulator 475b of the transistor 400b, respectively.

As illustrated in FIG. 11, the oxide 430 is shared by the transistor 400a and the transistor 400b, whereby the distance between the conductor 460a functioning as a first gate electrode of the transistor 400a and the conductor 460b functioning as a first gate electrode of the transistor 400b can be substantially equal to the minimum feature size, resulting in a reduction in the area occupied by the transistors in each memory cell.

A conductor 440 has a function of a plug, a function of one of a source electrode and a drain electrode of the transistor 400a, and also a function of one of a source electrode and a drain electrode of the transistor 400b. With the above structure, in one embodiment of the present invention, the distance between the transistor 400a and the transistor 400b adjacent to each other can be small. Thus, the semiconductor device including the transistor 400a, the transistor 400b, the capacitor 500a, and the capacitor 500b can be highly integrated. A conductor 446 is electrically connected to the conductor 440 and has a function of a wiring.

Furthermore, an insulator 480 is preferably provided so as to cover the transistor 400a and the transistor 400b in FIG. 11. The concentration of impurities such as water or hydrogen in the film of the insulator 480 is preferably lowered.

Openings in the insulator 480 are formed such that part of the insulator 475a of the transistor 400a and part of the insulator 475b of the transistor 400b overlap with part of the openings in the insulator 480. Therefore, when the openings in the insulator 480 are formed, a side surface of the insulator 475a of the transistor 400a and a side surface of the insulator 475b of the transistor 400b are partly exposed in regions to be the openings in the insulator 480. With the above structure, the positions and the shapes of the openings are determined in a self-aligned manner by the shape of the insulator 480, and the shape of the insulator 475a or the shape of the insulator 475b. Consequently, the distance between the opening and the gate electrode can be designed to be small, so that the semiconductor device can be highly integrated.

Furthermore, the conductor 440 is formed in the opening including a region overlapping with the insulator 475a and a region overlapping with the insulator 475b among the openings in the insulator 480. The oxide 430 is positioned on at least part of a bottom portion of the opening, and the conductor 440 is electrically connected to the oxide 430 in the opening.

Note that the conductor 440 may be formed so as to overlap with aluminum oxide after the aluminum oxide is formed so as to overlap with an inner wall of the opening in the insulator 480. The formation of aluminum oxide can inhibit the passage of oxygen from the outside and oxidation of the conductor 440. Furthermore, impurities such as water or hydrogen can be prevented from being diffused from the conductor 440 to the outside. The aluminum oxide can be formed by depositing aluminum oxide by an ALD method or the like such that the aluminum oxide overlaps with the inner wall of the opening in the insulator 480 and then performing anisotropic etching.

In one embodiment of the present invention, the other of the source region and the drain region of the transistor 400a and the capacitor 500a are provided so as to overlap with each other. Similarly, the other of the source region and the drain region of the transistor 400b and the capacitor 500b are provided so as to overlap with each other. It is particularly preferable that the capacitor 500a and the capacitor 500b have a structure where the side surface area is larger than the bottom surface area (hereinafter, such a structure is also referred to as a cylinder capacitor). Thus, the capacitance per projected area of the capacitor 500a and the capacitor 500b can be large.

In one embodiment of the present invention, one electrode of the capacitor 500a is provided in contact with the other of the source region and the drain region of the transistor 400a. Similarly, one electrode of the capacitor 500b is provided in contact with the other of the source region and the drain region of the transistor 400b. With the structure, steps for making a contact between the capacitor 500a and the transistor 400a and steps for making a contact between the capacitor 500b and the transistor 400b can be reduced in number. Accordingly, the number of steps and the manufacturing cost can be reduced.

Note that the insulator 475a and the insulator 475b are formed in a self-aligned manner by anisotropic etching treatment. The transistor 400a is provided with the insulator 475a, whereby parasitic capacitance formed between the conductor 460a and the capacitor 500a or the conductor 440 can be reduced. Similarly, the transistor 400b is provided with the insulator 475b, whereby parasitic capacitance formed between the conductor 460b and the capacitor 500b or the conductor 440 can be reduced. For example, silicon oxide, silicon oxynitride, silicon nitride oxide, and silicon nitride can be used as the insulator 475a and the insulator 475b. When the parasitic capacitance is reduced, high-speed operation of the transistor 400a and the transistor 400b can be achieved.

As the oxide 430, an oxide semiconductor typified by a metal oxide such as an In-M-Zn oxide (the element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is used, for example. As the oxide 430, an In—Ga oxide or an In—Zn oxide may be used.

The transistor 400a and the transistor 400b using an oxide semiconductor in their channel formation regions have an extremely low leakage current in an off state; thus, a semiconductor device with low power consumption can be provided. An oxide semiconductor can be deposited by a sputtering method or the like, and thus can be used for the transistor 400a and the transistor 400b included in a highly integrated semiconductor device.

A region of the oxide 430 overlapping with neither the conductor 460a nor the conductor 460b may have a lower resistivity than a region overlapping with the conductor 460a or the conductor 460b. With the above structure, contact resistance between the region having a low resistivity and the conductor 440 can be reduced, and the on-state current of the transistor 400a and the transistor 400b can be increased. In addition, the contact resistance between the region having a low resistivity and the one electrode of the capacitor 500a or the one electrode of the capacitor 500b can be reduced, so that the on-state current of the transistor 400a and the transistor 400b can be increased.

In the oxide 430, the boundaries between the regions are difficult to clearly determine in some cases. The concentration of a metal element and impurity elements such as hydrogen and nitrogen, which are detected in each region, may be not only gradually changed between the regions, but also continuously changed (also referred to as gradation) in each region. That is, the region closer to the channel formation region preferably has a lower concentration of a metal element and impurity elements such as hydrogen and nitrogen.

The channel lengths of the transistor 400a and the transistor 400b are determined by the widths of the conductor 460a and the insulator 475a and the widths of the conductor 460b and the insulator 475b. When the widths of the conductor 460a and the conductor 460b are each a minimum feature size, the transistor 400a and the transistor 400b can be miniaturized.

Note that a potential that is applied to the conductor 405_1 having a function of a second gate electrode may be equal to a potential that is applied to the conductor 460a having a function of a first gate electrode. When the potential that is applied to the conductor 405_1 is equal to the potential that is applied to the conductor 460a, the conductor 405_1 may be provided such that, in the channel width direction, the length of the conductor 405_1 is larger than that of a region of the oxide 430 overlapping with the conductor 460a. Specifically, the conductor 405_1 preferably extends beyond an end portion of the oxide 430 overlapping with the conductor 460a that intersects with the channel width direction. In other words, the conductor 405_1 and the conductor 460a preferably overlap with each other with an insulator therebetween outside the side surface of the oxide 430 in the channel width direction.

With the above structure, when a potential is applied to the conductor 460a and the conductor 405_1, the region of the oxide 430 overlapping with the conductor 460a can be electrically surrounded by an electric field generated from the conductor 460a and an electric field generated from the conductor 405_1. In this specification, a transistor structure in which a channel formation region is electrically surrounded by electric fields of a first gate electrode and a second gate electrode is referred to as a surrounded channel (S-channel) structure.

In the conductor 405_1, the conductor 405_1a is formed in contact with an inner wall of an opening in the insulator 414 and the insulator 416, and the conductor 405_1b is formed more inward than the conductor 405_1a. Here, the top surface of the conductor 405_1a can be substantially level with the top surface of the insulator 416. In addition, the top surface of the conductor 405_2a can be substantially level with the top surface of the insulator 416. Although the structure is illustrated in which the conductor 405_1a and the conductor 405_1b are stacked in the transistor 400a, the present invention is not limited thereto. For example, a structure in which only one of the conductor 405_1a and the conductor 405_1b is provided may be employed.

Here, it is preferable to use a conductive material that has a function of inhibiting the passage of impurities such as water or hydrogen (that is less likely to allow the passage of such impurities) for the conductor 405_1a. For example, tantalum, tantalum nitride, ruthenium, ruthenium oxide, or the like is preferably used, and a single layer or stacked layers are used. Accordingly, diffusion of impurities such as hydrogen and water from a layer below the insulator 414 into an upper layer through the conductor 405_1 and conductor 405_2 can be inhibited. Note that it is preferable that the conductor 405_1a have a function of inhibiting the passage of either of impurities such as a hydrogen atom, a hydrogen molecule, a water molecule, a nitrogen atom, a nitrogen molecule, a nitrogen oxide molecule (e.g., N₂O, NO, and NO₂), or a copper atom, or oxygen (e.g., at least one of an oxygen atom, an oxygen molecule, and the like). Furthermore, hereinafter, the same applies to the case of describing a conductive material that has a function of inhibiting the passage of impurities. When the conductor 405_1a has a function of inhibiting the passage of oxygen, the conductivity of the conductor 405_1b can be prevented from being lowered because of oxidation.

For the conductor 405_1b, a conductive material whose main component is tungsten, copper, or aluminum is preferably used. Although not illustrated, the conductor 405_1b may have a stacked-layer structure and may be, for example, stacked layers of titanium or titanium nitride and the above-described conductive material.

The insulator 414 and the insulator 422 can function as barrier insulating films that prevent impurities such as water or hydrogen from entering the transistor from a lower layer. For the insulator 414 and the insulator 422, an insulating material having a function of inhibiting the passage of impurities such as water or hydrogen is preferably used. For example, it is preferable that silicon nitride or the like be used for the insulator 414 and aluminum oxide, hafnium oxide, an oxide containing silicon and hafnium (hafnium silicate), an oxide containing aluminum and hafnium (hafnium aluminate), or the like be used for the insulator 422. This can inhibit diffusion of impurities such as hydrogen and water to a layer above the insulator 414 and the insulator 422. Note that it is preferable that the insulator 414 and the insulator 422 have a function of inhibiting the passage of at least one of impurities such as a hydrogen atom, a hydrogen molecule, a water molecule, a nitrogen atom, a nitrogen molecule, a nitrogen oxide molecule (e.g., N₂O, NO, and NO₂), and a copper atom. Furthermore, hereinafter, the same applies to the case of describing an insulating material that has a function of inhibiting the passage of impurities.

Furthermore, for the insulator 414 and the insulator 422, an insulating material having a function of inhibiting the passage of oxygen (e.g., oxygen atoms or oxygen molecules) is preferably used. This can inhibit downward diffusion of oxygen contained in the insulator 424 or the like.

Moreover, the concentration of impurities such as water, hydrogen, or nitrogen oxide in the insulator 422 is preferably lowered. The amount of hydrogen released from the insulator 422, which is converted into hydrogen molecules per unit area of the insulator 422, is less than or equal to 2×10¹⁵ molecules/cm², preferably less than or equal to 1×10¹⁵ molecules/cm², further preferably less than or equal to 5×10¹⁴ molecules/cm² in thermal desorption spectroscopy (TDS) within the surface temperature range of the insulator 422 of 50° C. to 500° C., for example.

The insulator 422 is preferably formed using an insulator from which oxygen is released by heating.

The insulator 450a can function as a first gate insulating film of the transistor 400a, and the insulator 420, the insulator 422, and the insulator 424 can function as second gate insulating films of the transistor 400a. Although a structure in which the insulator 420, the insulator 422, and the insulator 424 are stacked in the transistor 400a is illustrated, the present invention is not limited thereto. For example, a structure in which any two of the insulator 420, the insulator 422, and the insulator 424 are stacked may be employed, or a structure in which any one of them is used may be employed.

It is preferred to use a metal oxide functioning as an oxide semiconductor (hereinafter, also referred to as an oxide semiconductor) for the oxide 430. A metal oxide whose energy gap is greater than or equal to 2 eV, preferably greater than or equal to 2.5 eV, is preferably used as the metal oxide. With the use of a metal oxide having such a wide energy gap, the off-state current of the transistor can be reduced.

The oxide semiconductor preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxide semiconductor is an In-M-Zn oxide that contains indium, the element M, and zinc is considered. The element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, magnesium, and the like. Note that a plurality of the above-described elements may be used in combination as the element M.

Here, when a metal element such as aluminum, ruthenium, titanium, tantalum, chromium, or tungsten is added to the oxide semiconductor in addition to the constituent element of the oxide semiconductor, the oxide semiconductor becomes a metal compound to have reduced resistance in some cases. Note that aluminum, titanium, tantalum, tungsten, or the like is preferably used. To add the metal element to the oxide semiconductor, for example, a metal film containing the metal element, a nitride film containing the metal element, or an oxide film containing the metal element is preferably provided over the oxide semiconductor. By providing such a film, some oxygen in the interface between the film and the oxide semiconductor or in the oxide semiconductor positioned in the vicinity of the interface is absorbed by the film or the like and an oxygen vacancy is formed, so that the resistance of the oxide semiconductor in the vicinity of the interface is reduced in some cases.

The periphery of an oxygen vacancy formed in the vicinity of the interface has a distortion. When the above film is formed by a sputtering method with a sputtering gas containing a rare gas, the rare gas might enter the oxide semiconductor during the formation of the film. When the rare gas enters the oxide semiconductor, a distortion or a structural disorder is caused in the vicinity of the interface and around the rare gas. The rare gas is, for example, He or Ar. Owing to its larger atomic radius, Ar is preferable to He. When Ar enters the oxide semiconductor, a distortion or a structural disorder is appropriately caused. In a region where such a distortion or a structural disorder is caused, the number of metal atoms bonded to a small number of oxygen probably increases. When the number of metal atoms bonded to a small number of oxygen increases, the resistance in the vicinity of the interface and around the rare gas is reduced in some cases.

In the case where a crystalline oxide semiconductor is used as the oxide semiconductor, a region where the distortion or the structural disorder is caused has a broken crystallinity and seems like an amorphous oxide semiconductor in some cases.

After the metal film, the nitride film containing the metal element, or the oxide film containing the metal element is provided over the oxide semiconductor, heat treatment is preferably performed in an atmosphere containing nitrogen. By the heat treatment in the atmosphere containing nitrogen, the metal element is diffused from the metal film into the oxide semiconductor; thus, the metal element can be added to the oxide semiconductor.

In the case where hydrogen in the oxide semiconductor diffuses to a low-resistance region of the oxide semiconductor and enters an oxygen vacancy in the low-resistance region, the hydrogen is brought into a relatively stable state. It is known that hydrogen in the oxygen vacancy in the oxide semiconductor is released from the oxygen vacancy by heat treatment at 250° C. or higher, is diffused into a low-resistance region of the oxide semiconductor, enters an oxygen vacancy in the low-resistance region, and is brought into a relatively stable state. Thus, by the heat treatment, the resistance of the low-resistance region of the oxide semiconductor tends to be further reduced, and the oxide semiconductor whose resistance is not reduced tends to be highly purified (a reduction in the amount of impurities such as water or hydrogen) and tends to be increased in resistance.

The carrier density of the oxide semiconductor is increased when an impurity element such as hydrogen or nitrogen exists. Hydrogen in the oxide semiconductor reacts with oxygen, which is bonded to a metal atom, to be water, and thus forms an oxygen vacancy in some cases. Entry of hydrogen into the oxygen vacancy increases carrier density. Furthermore, in some cases, bonding of part of hydrogen to oxygen bonded to a metal atom causes generation of an electron serving as a carrier. That is, the resistance of an oxide semiconductor containing nitrogen or hydrogen is reduced.

Thus, selective addition of a metal element and an impurity element such as hydrogen and nitrogen to the oxide semiconductor allows a high-resistance region and a low-resistance region to be formed in the oxide semiconductor. In other words, when the resistance of the oxide 430 is selectively reduced, a region functioning as a semiconductor having a low carrier density and a low-resistance region functioning as a source region or a drain region can be provided in the oxide 430 processed into an island shape.

The atomic ratio of the element M to constituent elements in a metal oxide used as the oxide 430a is preferably greater than the atomic ratio of the element M to constituent elements in a metal oxide used as the oxide 430b. Moreover, the atomic ratio of the element M to In in the metal oxide used as the oxide 430a is preferably greater than the atomic ratio of the element M to In in the metal oxide used as the oxide 430b. Furthermore, the atomic ratio of In to the element M in the metal oxide used as the oxide 430b is preferably greater than the atomic ratio of In to the element M in the metal oxide used as the oxide 430a.

When the above metal oxide is used as the oxide 430a, it is preferable that the energy of the conduction band minimum of the oxide 430a be higher than the energy of the conduction band minimum of the region of the oxide 430b where the energy of conduction band minimum is low. In other words, the electron affinity of the oxide 430a is preferably smaller than the electron affinity of the region of the oxide 430b where the energy of the conduction band minimum is low.

Here, the energy level of the conduction band minimum gently changes in the oxide 430a and the oxide 430b. In other words, a continuous change or continuous connection occurs. This can be obtained by decreasing the density of defect states in a mixed layer formed at the interface between the oxide 430a and the oxide 430b.

Specifically, when the oxide 430a and the oxide 430b contain a common element (as a main component) in addition to oxygen, a mixed layer with a low density of defect states can be formed. For example, in the case where the oxide 430b is an In—Ga—Zn oxide, an In—Ga—Zn oxide, a Ga—Zn oxide, gallium oxide, or the like is used as the oxide 430a.

At this time, a narrow-gap portion formed in the oxide 430b functions as a main carrier path. Since the density of defect states at the interface between the oxide 430a and the oxide 430b can be decreased, the influence of interface scattering on carrier conduction can be small and a high on-state current can be obtained.

Furthermore, as shown in FIG. 11(B), a side surface of a structure body composed of the conductor 460a, the insulator 470a, and the insulator 471a is preferably substantially perpendicular to the insulator 422. However, the semiconductor device described in this embodiment is not limited thereto. For example, a structure may be employed in which an angle formed by the side surface and the top surface of the structure body composed of the conductor 460a, the insulator 470a, and the insulator 471a is an acute angle. In that case, the angle formed by the side surface of the structure body and the top surface of the insulator 422 is preferably larger.

The insulator 475a is provided in contact with at least the side surfaces of the conductor 460a and the insulator 470a. The insulator 475a is formed by depositing the insulator to be the insulator 475a and then performing anisotropic etching. By the etching, the insulator 475a is formed in contact with the side surfaces of the conductor 460a and the insulator 470a.

The capacitor 500a includes a conductor 510a, an insulator 530, and a conductor 520a over the insulator 530. The capacitor 500b includes a conductor 510b, the insulator 530, and a conductor 520b over the insulator 530. An insulator 484 is formed over the conductor 520a and the conductor 520b, and the conductor 440 is formed in the opening in the insulator 480, the insulator 530, and the insulator 484.

The capacitor 500a has a structure in which the conductor 510a functioning as a lower electrode and the conductor 520a functioning as an upper electrode face each other with the insulator 530 functioning as a dielectric interposed therebetween, along the bottom surface and the side surface of the opening in the insulator 480. The above structure allows the electrostatic capacitance per unit area to be high, which enables further miniaturization and higher integration of a semiconductor device. The electrostatic capacitance value of the capacitor 500a can be set as appropriate with the thickness of the insulator 480. Therefore, a semiconductor device with high design flexibility can be provided.

In particular, with the deeper opening in the insulator 480, the capacitor 500a can have increased electrostatic capacitance without an increase in its projected area. Thus, the capacitor 500a is preferably a cylinder capacitor (the side surface area is larger than the bottom surface area).

An insulator having a high permittivity is preferably used as the insulator 530. For example, an insulator containing an oxide of one or both of aluminum and hafnium can be used. Aluminum oxide, hafnium oxide, an oxide containing aluminum and hafnium (hafnium aluminate), or the like is preferably used as the insulator containing an oxide of one or both of aluminum and hafnium.

The insulator 530 may have a stacked-layer structure; for example, two or more layers selected from silicon oxide, silicon oxynitride, silicon nitride oxide, silicon nitride, aluminum oxide, hafnium oxide, an oxide containing aluminum and hafnium (hafnium aluminate), and the like may be used for the stacked-layer structure. For example, it is preferable that hafnium oxide, aluminum oxide, and hafnium oxide be deposited in this order by an ALD method to form a stacked-layer structure. Hafnium oxide and aluminum oxide each have a thickness of greater than or equal to 0.5 nm and less than or equal to 5 nm. With such a stacked-layer structure, the capacitor 500a can have a large capacitance value and a low leakage current.

Note that the conductor 510a or the conductor 520a may have a stacked-layer structure. For example, the conductor 510a or the conductor 520a may have a stacked-layer structure of a conductive material containing titanium, titanium nitride, tantalum, or tantalum nitride as its main component and a conductive material containing tungsten, copper, or aluminum as its main component. The conductor 510a or the conductor 520a may have either a single-layer structure or a stacked-layer structure of three or more layers.

### <Substrate>

As a substrate where the transistors are formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like, and a compound semiconductor substrate of silicon carbide, silicon germanium, gallium arsenide, indium phosphide, zinc oxide, or gallium oxide. In addition, a semiconductor substrate in which an insulator region is included in the above semiconductor substrate, e.g., an SOI (Silicon On Insulator) substrate and the like are given. Examples of the conductor substrate include a graphite substrate, a metal substrate, an alloy substrate, and a conductive resin substrate. Alternatively, a substrate including a metal nitride, a substrate including a metal oxide, and the like are given. Furthermore, a substrate in which an insulator substrate is provided with a conductor or a semiconductor, a substrate in which a semiconductor substrate is provided with a conductor or an insulator, a substrate in which a conductor substrate is provided with a semiconductor or an insulator, and the like are given. These substrates provided with elements may be used. Examples of the elements provided for the substrates include a capacitor, a resistor, a switching element, a light-emitting device, and a memory element.

A flexible substrate may be used as the substrate. Note that as a method for providing a transistor over a flexible substrate, there is also a method in which the transistor is manufactured over a non-flexible substrate and then the transistor is separated and transferred to a flexible substrate. In that case, a separation layer is preferably provided between the non-flexible substrate and the transistor. As the substrate, a sheet, a film, a foil, or the like in which a fiber is weaved may be used. In addition, the substrate may have elasticity. The substrate may have a property of returning to its original shape when bending or pulling is stopped, or may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. Moreover, when the substrate has a small thickness, even in the case of using glass or the like, the substrate may have elasticity or a property of returning to its original shape when bending or pulling is stopped. Thus, an impact applied to a semiconductor device over the substrate, which is caused by dropping or the like, can be reduced, for example. That is, a durable semiconductor device can be provided.

For the flexible substrate, metal, an alloy, a resin, glass, or fiber thereof can be used, for example. The flexible substrate preferably has a lower coefficient of linear expansion because deformation due to an environment is inhibited. For the flexible substrate, a material whose coefficient of linear expansion is lower than or equal to 1×10⁻³/K, lower than or equal to 5×10⁻⁵/K, or lower than or equal to 1×10⁻⁵/K can be used, for example. Examples of the resin include polyester, polyolefin, polyamide (e.g., nylon or aramid), polyimide, polycarbonate, and acrylic. In particular, aramid is preferable for the flexible substrate because of its low coefficient of linear expansion.

### <Insulator>

Examples of an insulator include an oxide, a nitride, an oxynitride, a nitride oxide, a metal oxide, a metal oxynitride, and a metal nitride oxide, each of which has an insulating property.

When a transistor is surrounded by an insulator having a function of inhibiting the passage of oxygen and impurities such as hydrogen, the transistor can have stable electrical characteristics. For example, an insulator having a function of inhibiting the passage of oxygen and impurities such as hydrogen can be used as the insulator 414, the insulator 422, the insulator 470a, and the insulator 470b.

As the insulator having a function of inhibiting the passage of oxygen and impurities such as hydrogen, for example, a single layer or stacked layers of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used.

For the insulator 414, the insulator 422, the insulator 470a, and the insulator 470b, for example, a metal oxide such as aluminum oxide, magnesium oxide, gallium oxide, germanium oxide, yttrium oxide, zirconium oxide, lanthanum oxide, neodymium oxide, hafnium oxide, an oxide containing silicon and hafnium, an oxide containing aluminum and hafnium, or tantalum oxide; silicon nitride oxide; or silicon nitride may be used. Note that the insulator 414, the insulator 422, the insulator 470a, and the insulator 470b preferably contain aluminum oxide, hafnium oxide, and the like.

As the insulator 471a, the insulator 471b, the insulator 475a, and the insulator 475b, for example, a single layer or stacked layers of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. For example, the insulator 471a, the insulator 471b, the insulator 475a, and the insulator 475b preferably contain silicon oxide, silicon oxynitride, or silicon nitride.

The insulator 420, the insulator 424, the insulator 450a, the insulator 450b, and the insulator 530 preferably contain an insulator with a high dielectric constant. For example, the insulator 420, the insulator 424, the insulator 450a, the insulator 450b, and the insulator 530 preferably contain gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like.

Alternatively, the insulator 420, the insulator 424, the insulator 450a, the insulator 450b, and the insulator 530 preferably have a stacked-layer structure of silicon oxide or silicon oxynitride and an insulator with a high dielectric constant. When silicon oxide and silicon oxynitride, which are thermally stable, are combined with an insulator with a high dielectric constant, the stacked-layer structure can have thermal stability and a high dielectric constant. For example, when a structure is employed in which aluminum oxide, gallium oxide, or hafnium oxide in the insulator 450a and the insulator 450b is in contact with the oxide 430, silicon contained in silicon oxide or silicon oxynitride can be inhibited from entering the oxide 430.

Furthermore, for example, when a structure is employed in which silicon oxide or silicon oxynitride in the insulator 450a and the insulator 450b is in contact with the oxide 430, trap centers are formed at the interface between aluminum oxide, gallium oxide, or hafnium oxide and silicon oxide or silicon oxynitride, in some cases. The trap centers can shift the threshold voltage of the transistor in the positive direction by trapping electrons in some cases.

The insulator 416, the insulator 480, the insulator 484, the insulator 475a, and the insulator 475b preferably contain an insulator with a low dielectric constant. For example, the insulator 416, the insulator 480, the insulator 484, the insulator 475a, and the insulator 475b preferably contain silicon oxide, silicon oxynitride, silicon nitride oxide, silicon nitride, silicon oxide to which fluorine is added, silicon oxide to which carbon is added, silicon oxide to which carbon and nitrogen are added, silicon oxide having pores, a resin, or the like. Alternatively, the insulator 416, the insulator 480, the insulator 484, the insulator 475a, and the insulator 475b preferably have a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or silicon oxide having pores. When silicon oxide and silicon oxynitride, which are thermally stable, are combined with a resin, the stacked-layer structure can have thermal stability and a low dielectric constant. Examples of the resin include polyester, polyolefin, polyamide (e.g., nylon or aramid), polyimide, polycarbonate, and acrylic.

### <Conductor>

For the conductor 405_1, the conductor 4052, the conductor 460a, the conductor 460b, the conductor 440, the conductor 510a, the conductor 510b, the conductor 520a, and the conductor 520b, a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor with high electrical conductivity, typified by polycrystalline silicon containing an impurity element such as phosphorus, or silicide such as nickel silicide may be used.

In particular, a conductive material containing oxygen and a metal element contained in a metal oxide that can be used for the oxide 430 may be used for the conductor 460a and the conductor 460b. A conductive material containing the above metal element and nitrogen may be used. For example, a conductive material containing nitrogen, such as titanium nitride or tantalum nitride, may be used. An indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon is added may be used. An indium gallium zinc oxide containing nitrogen may be used. With the use of such a material, hydrogen contained in the oxide 430 can be captured in some cases. Alternatively, hydrogen entering from an external insulator or the like can be captured in some cases.

Furthermore, a stack of a plurality of conductive layers formed with the above materials may be used. For example, a stacked-layer structure combining a material containing the above-described metal element and a conductive material containing oxygen may be employed. A stacked-layer structure combining a material containing the above-described metal element and a conductive material containing nitrogen may be employed. A stacked-layer structure combining a material containing the above-described metal element, a conductive material containing oxygen, and a conductive material containing nitrogen may be employed.

Note that in the case where an oxide is used for the channel formation region of the transistor, a stacked-layer structure combining a material containing the above-described metal element and a conductive material containing oxygen is preferably used for the gate electrode. In that case, the conductive material containing oxygen is preferably provided on the channel formation region side. When the conductive material containing oxygen is provided on the channel formation region side, oxygen left from the conductive material is easily supplied to the channel formation region.

### [Composition of Metal Oxide]

The composition of a CAC (Cloud-Aligned Composite)-OS that can be used for the transistor disclosed in one embodiment of the present invention will be described below.

Note that in this specification and the like, CAAC (c-axis aligned crystalline) or CAC (Cloud-Aligned Composite) might be stated. Note that CAAC refers to an example of a crystal structure, and CAC refers to an example of a function or a material composition.

A CAC-OS or a CAC-metal oxide has a conducting function in a part of the material and an insulating function in another part of the material and has a function of a semiconductor as a whole. In the case where the CAC-OS or the CAC-metal oxide is used in an active layer of a transistor, the conducting function is a function of allowing electrons (or holes) serving as carriers to flow, and the insulating function is a function of not allowing electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

Furthermore, the CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, the conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide is composed of components having different bandgaps. For example, the CAC-OS or the CAC-metal oxide is composed of a component having a wide gap due to the insulating regions and a component having a narrow gap due to the conductive regions. In the case of the structure, when carriers flow, carriers mainly flow in the component having a narrow gap. Furthermore, the component having a narrow gap complements the component having a wide gap, and carriers flow also in the component having a wide gap in conjunction with the component having a narrow gap. Therefore, in the case where the above-described CAC-OS or CAC-metal oxide is used in the channel formation region of the transistor, high current driving capability in an on state of the transistor, that is, a high on-state current, and high field-effect mobility can be obtained.

In other words, the CAC-OS or the CAC-metal oxide can also be referred to as a matrix composite or a metal matrix composite.

### [Structure of Metal Oxide]

Oxide semiconductors can be classified into single crystal oxide semiconductors and the others, non-single-crystal oxide semiconductors. Examples of the non-single-crystal oxide semiconductors include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment and a crystal structure with distortion in which a plurality of nanocrystals are connected in the a-b plane direction. Note that the distortion refers to a portion where the direction of a lattice arrangement changes between a region with a regular lattice arrangement and another region with a regular lattice arrangement in a region where the plurality of nanocrystals are connected.

A nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) cannot be observed even in the vicinity of distortion in the CAAC-OS. That is, it is found that formation of a crystal grain boundary is inhibited by the lattice arrangement distortion. This is probably because the CAAC-OS can tolerate distortion owing to non-dense arrangement of oxygen atoms in the a-b plane direction, an interatomic bond length changed by metal element substitution, and the like.

The CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other; when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is an oxide semiconductor with high crystallinity. On the other hand, a clear crystal grain boundary cannot be observed in the CAAC-OS; thus, it can be said that a reduction in electron mobility due to the crystal grain boundary is less likely to occur. Furthermore, entry of impurities, formation of defects, or the like might decrease the crystallinity of an oxide semiconductor, which means that the CAAC-OS is an oxide semiconductor having small amounts of impurities and defects (e.g., oxygen vacancies). Thus, an oxide semiconductor including a CAAC-OS is physically stable. Therefore, the oxide semiconductor including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

The a-like OS is an oxide semiconductor having a structure between those of the nc-OS and the amorphous oxide semiconductor. The a-like OS contains a void or a low-density region. That is, the a-like OS has low crystallinity as compared with the nc-OS and the CAAC-OS.

An oxide semiconductor has various structures with different properties. Two or more kinds of the amorphous oxide semiconductor, the polycrystalline oxide semiconductor, the a-like OS, the nc-OS, and the CAAC-OS may be included in an oxide semiconductor of one embodiment of the present invention.

### [Transistor Including Oxide Semiconductor]

Next, the case where the above oxide semiconductor is used for a transistor will be described.

Note that when the above oxide semiconductor is used for a transistor, a transistor with high field-effect mobility can be achieved. In addition, a transistor with high reliability can be achieved.

An oxide semiconductor with a low carrier density is preferably used for a transistor. In the case where the carrier density of an oxide semiconductor is lowered, the impurity concentration in the oxide semiconductor is lowered to lower the density of defect states. In this specification and the like, a state with a low impurity concentration and a low density of defect states is referred to as a highly purified intrinsic or substantially highly purified intrinsic state. For example, the carrier density of the oxide semiconductor is lower than 8×10¹¹/cm³, preferably lower than 1×10¹¹/cm³, more preferably lower than 1×10¹⁰/cm³, and greater than or equal to 1×10⁻⁹/cm³.

In addition, a highly purified intrinsic or substantially highly purified intrinsic oxide semiconductor has a low density of defect states and accordingly has a low density of trap states in some cases.

Furthermore, charges trapped by the trap states in the oxide semiconductor take a long time to disappear and may behave like fixed charges. Thus, a transistor whose channel formation region is formed in an oxide semiconductor with a high density of trap states has unstable electrical characteristics in some cases.

Thus, in order to stabilize electrical characteristics of the transistor, reducing the impurity concentration in the oxide semiconductor is effective. Furthermore, in order to reduce the impurity concentration in the oxide semiconductor, it is preferred that the impurity concentration in an adjacent film be also reduced. Examples of impurities include hydrogen, nitrogen, an alkali metal, an alkaline earth metal, iron, nickel, and silicon.

### [Impurity]

Here, the influence of each impurity in the oxide semiconductor will be described.

When silicon or carbon, which is one of the Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are set lower than or equal to 2×10¹⁸ atoms/cm³, preferably lower than or equal to 2×10¹⁷ atoms/cm³.

Furthermore, when the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Accordingly, it is preferred to reduce the concentration of an alkali metal or an alkaline earth metal in the oxide semiconductor. Specifically, the concentration of an alkali metal or an alkaline earth metal in the oxide semiconductor obtained by SIMS is set lower than or equal to 1×10¹⁸ atoms/cm³, preferably lower than or equal to 2×10¹⁶ atoms/cm³.

Furthermore, when containing nitrogen, the oxide semiconductor easily becomes n-type by generation of electrons serving as carriers and an increase of carrier density. As a result, a transistor using an oxide semiconductor containing nitrogen as a semiconductor is likely to have normally-on characteristics. For this reason, nitrogen in the oxide semiconductor is preferably reduced as much as possible; the nitrogen concentration in the oxide semiconductor obtained by SIMS is set, for example, lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Furthermore, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor obtained by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurities is used for a channel formation region of a transistor, stable electrical characteristics can be given.

This embodiment can be implemented in combination with the other embodiments and examples as appropriate.

### Embodiment 4

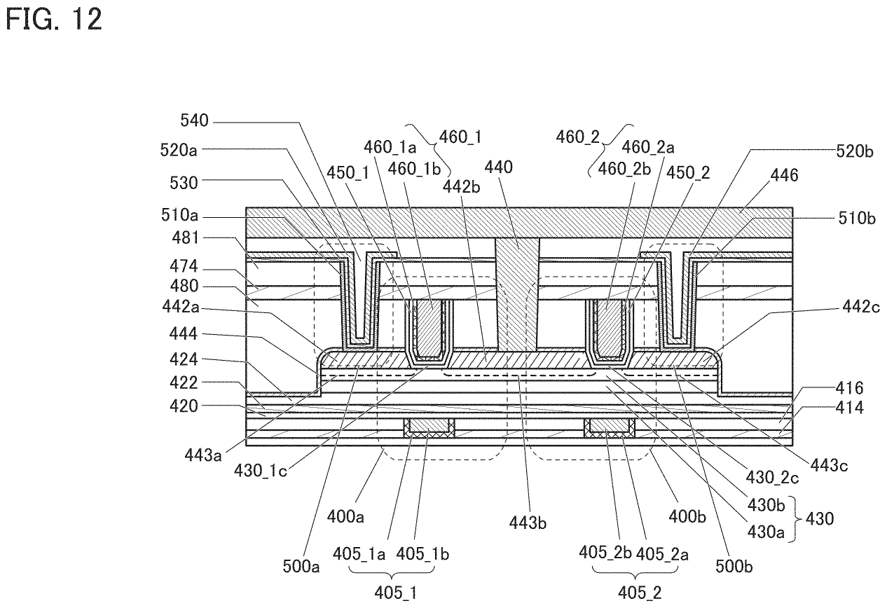

FIG. 12 illustrates another structure example of the transistor 400a, the transistor 400b, the capacitor 500a, and the capacitor 500b when two memory cells share one bit line. In the cross-sectional view shown in FIG. 12, the transistor 400a and the capacitor 500a are included in a first memory cell, and the transistor 400b and the capacitor 500b are included in a second memory cell.

As illustrated in FIG. 12, the transistor 400a includes the conductor 405_1 (the conductor 405_1a and the conductor 405_1b) positioned over an insulating surface so as to be embedded in the insulator 414 and the insulator 416; the insulator 420 positioned over the conductor 405_1 and the insulator 416; the insulator 422 positioned over the insulator 420; the insulator 424 positioned over the insulator 422; the oxide 430 (the oxide 430a and the oxide 430b) positioned over the insulator 424; a conductor 442a and a conductor 442b positioned over the oxide 430; the oxide 430_1c positioned between the conductor 442a and the conductor 442b and over the oxide 430; an insulator 450_1 positioned over the oxide 430_1c; and a conductor 460_1 (a conductor 460_1a and a conductor 460_1b) positioned over the insulator 450_1.

As illustrated in FIG. 12, the transistor 400b includes the conductor 405_2 (the conductor 405_2a and the conductor 405_2b) positioned over an insulating surface so as to be embedded in the insulator 414 and the insulator 416; the insulator 420 positioned over the conductor 405_2 and the insulator 416; the insulator 422 positioned over the insulator 420; the insulator 424 positioned over the insulator 422; the oxide 430 (the oxide 430a and the oxide 430b) positioned over the insulator 424; a conductor 442c and the conductor 442b positioned over the oxide 430; the oxide 430_2c positioned between the conductor 442c and the conductor 442b and over the oxide 430; an insulator 450_2 positioned over the oxide 430_2c; and a conductor 460_2 (a conductor 460_2a and a conductor 460_2b) positioned over the insulator 450_2.

Although FIG. 12 illustrates the structure in which the transistor 400a and the transistor 400b include the oxide 430a and the oxide 430b that are stacked, the transistor 400a and the transistor 400b may have a structure including a single layer of only the oxide 430b. Alternatively, the transistor 400a and the transistor 400b may have a structure including three or more oxide layers stacked.

Although FIG. 12 illustrates a structure in which the conductor 460_1a and the conductor 460_1b are each a single layer and the conductor 460_2a and the conductor 460_2b are each a single layer, these conductors may each have a structure in which two or more conductor layers are stacked, for example.

Note that the transistor 400b includes components corresponding to the components included in the transistor 400a. Thus, in drawings, the corresponding components in the transistor 400a and the transistor 400b are basically denoted by the same three-digit reference numerals. In addition, unless otherwise specified, the description of the transistor 400a can be referred to for the transistor 400b below.

As in the description of the transistor 400a, the capacitor 500b includes components corresponding to the components included in the capacitor 500a. Thus, in drawings, the corresponding components in the capacitor 500a and the capacitor 500b are basically denoted by the same three-digit reference numerals. Thus, unless otherwise specified, the description of the capacitor 500a can be referred to for the capacitor 500b below.

As illustrated in FIG. 12, the oxide 430 is shared by the transistor 400a and the transistor 400b, whereby the distance between the conductor 460_1 functioning as a first gate electrode of the transistor 400a and the conductor 460_2 functioning as a first gate electrode of the transistor 400b can be substantially equal to the minimum feature size, resulting in a reduction in the area occupied by the transistors in each memory cell. Note that the conductor 405_1 functions as the second gate electrode of the transistor 400a. The conductor 405_2 functions as a second gate electrode of the transistor 400b.

The conductor 442b has a function of one of a source electrode and a drain electrode of the transistor 400a and also a function of one of a source electrode and a drain electrode of the transistor 400b. The conductor 440 has a function of a plug and is electrically connected to the conductor 442b. With the above structure, in one embodiment of the present invention, the distance between the transistor 400a and the transistor 400b adjacent to each other can be small. Thus, the semiconductor device including the transistor 400a, the transistor 400b, the capacitor 500a, and the capacitor 500b can be highly integrated. The conductor 446 is electrically connected to the conductor 440 and has a function of a wiring.

Although an insulator 444 is provided so as to cover the oxide 430, the conductor 442a, the conductor 442b, and the conductor 442c of the transistor 400a and the transistor 400b in FIG. 12, a structure without the insulator 444 may be employed in one embodiment of the present invention. When the insulator 444 is provided so as to cover the conductor 442a, the conductor 442b, and the conductor 442c, surfaces of the conductor 442a, the conductor 442b, and the conductor 442c can be prevented from being oxidized.

The insulator 480 is positioned over the insulator 444. The concentration of impurities such as water or hydrogen in the film of the insulator 480 is preferably lowered. In a depressed portion formed by the insulator 480, the insulator 444, the conductor 442a, the conductor 442b, and the oxide 430, the oxide 430_1c is positioned along the inner wall of the depressed portion, the insulator 450_1 is positioned so as to overlap with the oxide 430_1c, the conductor 460_1a is positioned so as to overlap with the insulator 450_1, and the conductor 460_1b is positioned so as to overlap with the conductor 460_1a. Similarly, in a depressed portion formed by the insulator 480, the conductor 442b, the conductor 442c, and the oxide 430, the oxide 430_2c is positioned along the inner wall of the depressed portion, the insulator 450_2 is positioned so as to overlap with the oxide 430_2c, the conductor 460_2a is positioned so as to overlap with the insulator 450_2, and the conductor 460_2b is positioned so as to overlap with the conductor 460_2a.

In one embodiment of the present invention, an insulator 474 is positioned over the insulator 480, the oxide 430_1c, the oxide 430_2c, the insulator 4501, the insulator 4502, the conductor 460_1, and the conductor 460_2, and an insulator 481 is positioned over the insulator 474.

The insulator 474 and the insulator 481 can function as barrier insulating films that prevent impurities such as water or hydrogen from entering the transistors from an upper layer. For the insulator 474 and the insulator 481, an insulating material having a function of inhibiting the passage of impurities such as water or hydrogen is preferably used. For example, it is preferable that aluminum oxide, hafnium oxide, an oxide containing silicon and hafnium (hafnium silicate), an oxide containing aluminum and hafnium (hafnium aluminate), or the like be used for the insulator 474, and silicon nitride or the like be used for the insulator 481. This can inhibit diffusion of impurities such as hydrogen and water to a layer below the insulator 474 and the insulator 481. Note that it is preferable that the insulator 474 and the insulator 481 have a function of inhibiting the passage of at least one of impurities such as a hydrogen atom, a hydrogen molecule, a water molecule, a nitrogen atom, a nitrogen molecule, a nitrogen oxide molecule (e.g., N₂O, NO, and NO₂), and a copper atom. Furthermore, hereinafter, the same applies to the case of describing an insulating material that has a function of inhibiting the passage of impurities.

For the insulator 474 and the insulator 481, an insulating material having a function of inhibiting the passage of oxygen (e.g., oxygen atoms or oxygen molecules) is preferably used. This can inhibit upward diffusion of oxygen contained in the insulator 481 or the like.

In one embodiment of the present invention, the other of the source region and the drain region of the transistor 400a and the capacitor 500a are provided so as to overlap with each other. Similarly, the other of the source region and the drain region of the transistor 400b and the capacitor 500b are provided so as to overlap with each other. It is particularly preferable that the capacitor 500a and the capacitor 500b have a structure where the side surface area is larger than the bottom surface area (hereinafter, such a structure is also referred to as a cylinder capacitor). Thus, the capacitance per projected area of the capacitor 500a and the capacitor 500b can be large.

In one embodiment of the present invention, one electrode of the capacitor 500a is provided in contact with the other of the source region and the drain region of the transistor 400a. Similarly, one electrode of the capacitor 500b is provided in contact with the other of the source region and the drain region of the transistor 400b. With the structure, steps for making a contact between the capacitor 500a and the transistor 400a and steps for making a contact between the capacitor 500b and the transistor 400b can be reduced in number. Accordingly, the number of steps and the manufacturing cost can be reduced.

The transistor 400a and the transistor 400b using an oxide semiconductor in their channel formation regions have an extremely low leakage current in an off state; thus, a semiconductor device with low power consumption can be provided. An oxide semiconductor can be deposited by a sputtering method or the like, and thus can be used for the transistor 400a and the transistor 400b included in a highly integrated semiconductor device.

In some cases, a low-resistance region having lower resistance than the channel formation region is formed in a region of the oxide 430 that overlaps with the conductor 442a, more specifically, a region 443a in the vicinity of the surface of the oxide 430 that is in contact with the conductor 442a. Similarly, in some cases, a low-resistance region having lower resistance than the channel formation region is formed in a region of the oxide 430 that overlaps with the conductor 442b, more specifically, a region 443b in the vicinity of the surface of the oxide 430 that is in contact with the conductor 442b. Similarly, in some cases, a low-resistance region having lower resistance than the channel formation region is formed in a region of the oxide 430 that overlaps with the conductor 442c, more specifically, a region 443c in the vicinity of the surface of the oxide 430 that is in contact with the conductor 442c. With the above regions, the contact resistance between the oxide 430 and each of the conductor 442a, the conductor 442b, and the conductor 442c can be reduced, and the on-state current of the transistor 400a and the transistor 400b can be increased.

The capacitor 500a includes the conductor 510a, the insulator 530, the conductor 520a over the insulator 530. The capacitor 500b includes the conductor 510b, the insulator 530, and the conductor 520b over the insulator 530. The capacitor 500a has a structure where the conductor 510a functioning as a lower electrode and the conductor 520a functioning as an upper electrode face each other with the insulator 530 functioning as a dielectric therebetween, along the bottom surface and the side surface of the opening in the insulator 444, the insulator 480, the insulator 474, and the insulator 481. The above structure allows the electrostatic capacitance per unit area to be high, which enables further miniaturization and higher integration of a semiconductor device. The electrostatic capacitance value of the capacitor 500a can be set as appropriate with the thickness of the insulator 480. Therefore, a semiconductor device with high design flexibility can be provided.

In particular, with the deeper opening in the insulator 480, the capacitor 500a can have increased electrostatic capacitance without an increase in its projected area. Thus, the capacitor 500a is preferably a cylinder capacitor (the side surface area is larger than the bottom surface area).

FIG. 12 illustrates an example where the conductor 520a and the conductor 520b have depressed portions and the insulator 540 over the capacitor 500a and the capacitor 500b is positioned inside the depressed portions.

An insulator having a high permittivity is preferably used as the insulator 530. For example, an insulator containing an oxide of one or both of aluminum and hafnium can be used. Aluminum oxide, hafnium oxide, an oxide containing aluminum and hafnium (hafnium aluminate), or the like is preferably used as the insulator containing an oxide of one or both of aluminum and hafnium.

The insulator 530 may have a stacked-layer structure; for example, two or more layers selected from silicon oxide, silicon oxynitride, silicon nitride oxide, silicon nitride, aluminum oxide, hafnium oxide, an oxide containing aluminum and hafnium (hafnium aluminate), and the like may be used for the stacked-layer structure. For example, it is preferable that hafnium oxide, aluminum oxide, and hafnium oxide be deposited in this order by an ALD method to form a stacked-layer structure. Hafnium oxide and aluminum oxide each have a thickness of greater than or equal to 0.5 nm and less than or equal to 5 nm. With such a stacked-layer structure, the capacitor 500a and the capacitor 500b can each have a large capacitance value and a low leakage current.

Note that the conductor 510a or the conductor 520a may have a stacked-layer structure. For example, the conductor 510a or the conductor 520a may have a stacked-layer structure of a conductive material containing titanium, titanium nitride, tantalum, or tantalum nitride as its main component and a conductive material containing tungsten, copper, or aluminum as its main component. The conductor 510a or the conductor 520a may have either a single-layer structure or a stacked-layer structure of three or more layers.

The conductor 440 is formed in the opening in the insulator 444, the insulator 480, the insulator 474, the insulator 481, and the insulator 540. The conductor 442b is positioned on at least part of a bottom portion of the opening, and the conductor 440 is electrically connected to the conductor 442b in the opening.

This embodiment can be implemented in combination with the other embodiments as appropriate.

### Embodiment 5

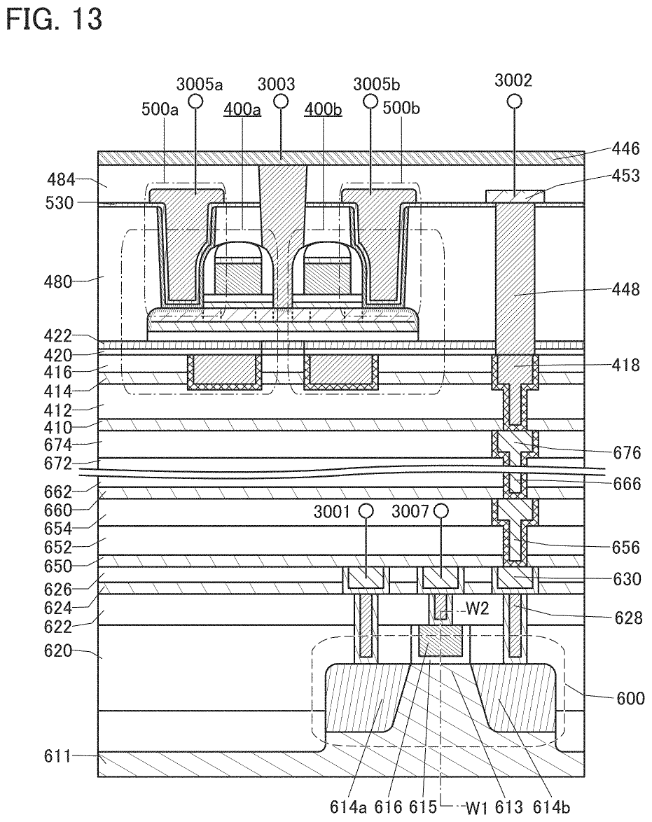

In this embodiment, one embodiment of a semiconductor device will be described with reference to FIG. 13. A semiconductor device illustrated in FIG. 13 includes the transistor 400a, the capacitor 500a, the transistor 400b, and the capacitor 500b illustrated in FIG. 11 above a transistor 600. FIG. 13 is a cross-sectional view of the transistor 400a, the transistor 400b, and the transistor 600 in the channel length direction. The description of the transistor 400a, the capacitor 500a, the transistor 400b, and the capacitor 500b in Embodiment 4 can be referred to for the structures of the transistor 400a, the capacitor 500a, the transistor 400b, and the capacitor 500b illustrated in FIG. 13.

A wiring 3001 is electrically connected to one of a source and a drain of the transistor 600, a wiring 3002 is electrically connected to the other of the source and the drain of the transistor 600, and a wiring 3007 is electrically connected to a gate of the transistor 600. A wiring 3003 is electrically connected to one of the source and the drain of the transistor 400a and one of the source and the drain of the transistor 400b. A wiring 3005a is electrically connected to one electrode of the capacitor 500a, and a wiring 3005b is electrically connected to one electrode of the capacitor 500b.

The transistor 400a, the transistor 400b, the capacitor 500a, and the capacitor 500b are provided above the transistor 600. The transistor 600 is provided on a substrate 611 and includes a conductor 616, an insulator 615, a semiconductor region 613 that is a part of the substrate 611, and a low-resistance region 614a and a low-resistance region 614b functioning as a source region and a drain region. The transistor 600 is either a p-channel transistor or an n-channel transistor.

A channel formation region of the semiconductor region 613, a region in the vicinity thereof, the low-resistance region 614a and the low-resistance region 614b functioning as the source region and the drain region, and the like preferably contain a semiconductor such as a silicon-based semiconductor, further preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and thereby changing the lattice spacing is used. Alternatively, the transistor 600 may be an HEMT (High Electron Mobility Transistor) by using GaAs and GaAlAs, or the like.

Note that the transistor 600 illustrated in FIG. 13 is an example and the structure is not limited thereto; a transistor appropriate for a circuit structure or a driving method is used.

An insulator 620, an insulator 622, an insulator 624, and an insulator 626 are provided to be stacked in this order to cover the transistor 600.

For the insulator 620, the insulator 622, the insulator 624, and the insulator 626, silicon oxide, silicon oxynitride, silicon nitride oxide, silicon nitride, aluminum oxide, aluminum oxynitride, aluminum nitride oxide, aluminum nitride, or the like is used, for example.

The insulator 622 may have a function of a planarization film for eliminating a level difference caused by the transistor 600 or the like provided below the insulator 622. For example, a top surface of the insulator 622 may be planarized by planarization treatment using a chemical mechanical polishing (CMP) method or the like to improve planarity.

For the insulator 624, it is preferred to use a film having a barrier property that prevents diffusion of hydrogen and impurities from the substrate 611, the transistor 600, or the like into a region where the transistor 400a and the transistor 400b are provided.

As an example of the film having a barrier property against hydrogen, silicon nitride formed by a CVD method can be used. Here, the diffusion of hydrogen into a semiconductor element including an oxide semiconductor, such as the transistor 400a or the transistor 400b, degrades the characteristics of the semiconductor element in some cases. Therefore, a film that inhibits diffusion of hydrogen is preferably used between the transistor 600 and the transistor 400a and the transistor 400b. The film that inhibits diffusion of hydrogen is specifically a film from which a small amount of hydrogen is released.

The amount of released hydrogen can be analyzed by thermal desorption spectroscopy (TDS), for example. The amount of hydrogen released from the insulator 624 that is converted into hydrogen atoms per area of the insulator 624 is less than or equal to 10×10¹⁵ atoms/cm², preferably less than or equal to 5×10¹⁵ atoms/cm² in the TDS analysis in a film-surface temperature ranging from 50° C. to 500° C., for example.

Note that the insulator 626 preferably has a lower permittivity than the insulator 624. For example, the dielectric constant of the insulator 626 is preferably lower than 4, further preferably lower than 3. For example, the dielectric constant of the insulator 626 is preferably 0.7 times or less, further preferably 0.6 times or less the dielectric constant of the insulator 624. When a material with a low permittivity is used for an interlayer film, the parasitic capacitance generated between wirings can be reduced.

The conductor 628, the conductor 630, and the like that are electrically connected to the transistor 600 are embedded in the insulator 620, the insulator 622, the insulator 624, and the insulator 626. Note that the conductor 628 and the conductor 630 have functions of plugs or wirings. In addition, a plurality of conductors having functions of plugs or wirings are collectively denoted by the same reference numeral in some cases. Furthermore, in this specification and the like, a wiring and a plug electrically connected to the wiring may be a single component. That is, there are cases where part of a conductor functions as a wiring and part of the conductor functions as a plug.

As a material for each of the plugs and wirings (the conductor 628, the conductor 630, and the like), a single layer or stacked layers of a conductive material such as a metal material, an alloy material, a metal nitride material, or a metal oxide material can be used. It is preferred to use a high-melting-point material that has both heat resistance and conductivity, such as tungsten or molybdenum; it is particularly preferred to use tungsten. Alternatively, it is preferred to form each of the plugs and wirings using a low-resistance conductive material such as aluminum or copper. The use of a low-resistance conductive material can reduce wiring resistance.

A wiring layer may be provided over the insulator 626 and the conductor 630. For example, in FIG. 13, an insulator 650, an insulator 652, and an insulator 654 are provided to be stacked in this order. Furthermore, a conductor 656 is formed in the insulator 650, the insulator 652, and the insulator 654. The conductor 656 has a function of a plug or a wiring. Note that the conductor 656 can be provided using a material similar to those for the conductor 628 and the conductor 630.

Note that for example, an insulator having a barrier property against hydrogen is preferably used for the insulator 650, as in the case of the insulator 624. Furthermore, the conductor 656 preferably includes a conductor having a barrier property against hydrogen. Specifically, the conductor having a barrier property against hydrogen is formed in an opening included in the insulator 650 having a barrier property against hydrogen. In such a structure, the transistor 600 can be separated from the transistor 400a and the transistor 400b by the barrier layer, so that diffusion of hydrogen from the transistor 600 into the transistor 400a and the transistor 400b can be inhibited.

Note that for the conductor having a barrier property against hydrogen, tantalum nitride is preferably used, for example. In addition, by stacking tantalum nitride and tungsten, which has high conductivity, the diffusion of hydrogen from the transistor 600 can be inhibited while the conductivity of a wiring is kept. In that case, it is preferred to have a structure in which tantalum nitride having a barrier property against hydrogen is in contact with the insulator 650 having a barrier property against hydrogen.

In the above, the wiring layer including the conductor 656 is described; however, the semiconductor device of this embodiment is not limited thereto. The wiring layer including the conductor 656 may be a single layer or a stack of a plurality of layers.

Furthermore, a wiring layer may be provided over the insulator 654 and the conductor 656. For example, a wiring layer including an insulator 660, an insulator 662, and a conductor 666 and a wiring layer including an insulator 672, an insulator 674, and a conductor 676 are provided by being stacked in this order in FIG. 13. Furthermore, a plurality of wiring layers may be provided between the wiring layer including the insulator 660, the insulator 662, and the conductor 666 and the wiring layer including the insulator 672, the insulator 674, and the conductor 676. Note that the conductor 666 and the conductor 676 have a function of a plug or a wiring. The insulator 660, the insulator 662, the insulator 672, and the insulator 674 can each be formed using a material similar to that for the above-described insulator.

The insulator 410 and the insulator 412 are provided to be stacked in this order over the insulator 674. A material having a barrier property against oxygen and hydrogen is preferably used for either the insulator 410 or the insulator 412.

For the insulator 410, for example, it is preferred to use a film having a barrier property that prevents diffusion of hydrogen and impurities from the substrate 611, a region where the transistor 600 is provided, or the like into the region where the transistor 400a and the transistor 400b are provided. Therefore, a material similar to that for the insulator 624 can be used.

As an example of the film having a barrier property against hydrogen, silicon nitride formed by a CVD method can be used. Here, the diffusion of hydrogen into a semiconductor element including an oxide semiconductor, such as the transistor 400a or the transistor 400b, degrades the characteristics of the semiconductor element in some cases. Therefore, a film that inhibits diffusion of hydrogen is preferably used between the transistor 600 and the transistor 400a and the transistor 400b. The film that inhibits diffusion of hydrogen is specifically a film from which a small amount of hydrogen is released.

As the film having a barrier property against hydrogen used for the insulator 410, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of a change in electrical characteristics of the transistor. Accordingly, aluminum oxide can prevent entry of impurities such as hydrogen and moisture into the transistor 400a and the transistor 400b in a manufacturing process of the transistor and after the manufacturing process. In addition, release of oxygen from the oxide included in the transistor 400a and the transistor 400b can be inhibited. Therefore, aluminum oxide is suitably used for a protective film for the transistor 400a and the transistor 400b.

For the insulator 412, for example, a material similar to that for the insulator 620 can be used. When a material with a relatively low permittivity is used for an interlayer film, the parasitic capacitance between wirings can be reduced. For example, a silicon oxide film, a silicon oxynitride film, or the like can be used for the insulator 412.

Moreover, a conductor 418, and conductors and the like included in the transistor 400a and the transistor 400b are embedded in the insulator 410, the insulator 412, the insulator 414, and the insulator 416. Note that the conductor 418 has a function of a plug or a wiring that is electrically connected to the transistor 600 or the transistor 400a and the transistor 400b. The conductor 418 can be provided using a material similar to those for the conductor 628 and the conductor 630.

In particular, the conductor 418 in a region in contact with the insulator 410 and the insulator 414 is preferably a conductor having a barrier property against oxygen, hydrogen, and water. In such a structure, the transistor 600 can be separated from the transistor 400a and the transistor 400b by a layer having a barrier property against oxygen, hydrogen, and water; thus, the diffusion of hydrogen from the transistor 600 into the transistor 400a and the transistor 400b can be inhibited.

The transistor 400a, the transistor 400b, the capacitor 500a, and the capacitor 500b are provided above the insulator 412. Note that the structures of the transistor 400a, the transistor 400b, the capacitor 500a, and the capacitor 500b described in the above embodiment can be used as those of the transistor 400a, the transistor 400b, the capacitor 500a, and the capacitor 500b. Note that the transistor 400a, the transistor 400b, the capacitor 500a, and the capacitor 500b illustrated in FIG. 13 are just examples and the structures are not limited thereto; an appropriate transistor and an appropriate capacitor are used in accordance with a circuit structure or a driving method.

Furthermore, a conductor 448 is provided in contact with the conductor 418, so that the conductor 453 which is connected to the transistor 600 can be extracted above the transistor 400a and the transistor 400b. Although the wiring 3002 is extracted above the transistor 400a and the transistor 400b in FIG. 13, this is not necessarily employed; a structure may be employed in which the wiring 3001, the wiring 3007, and the like are extracted above the transistor 400a and the transistor 400b.

The above is the description of the structure example. With the use of the structure, a change in electrical characteristics can be reduced and reliability can be improved in a semiconductor device using a transistor including an oxide semiconductor. Alternatively, a transistor including an oxide semiconductor with a high on-state current can be provided. Alternatively, a transistor including an oxide semiconductor with a low off-state current can be provided. Alternatively, a semiconductor device with low power consumption can be provided.

This embodiment can be implemented in combination with the other embodiments and examples as appropriate.

### Embodiment 6

In this embodiment, a structure example of a transistor that can be used in the memory device and the like described in the above embodiment will be described.

### <Transistor Structure Example 1>

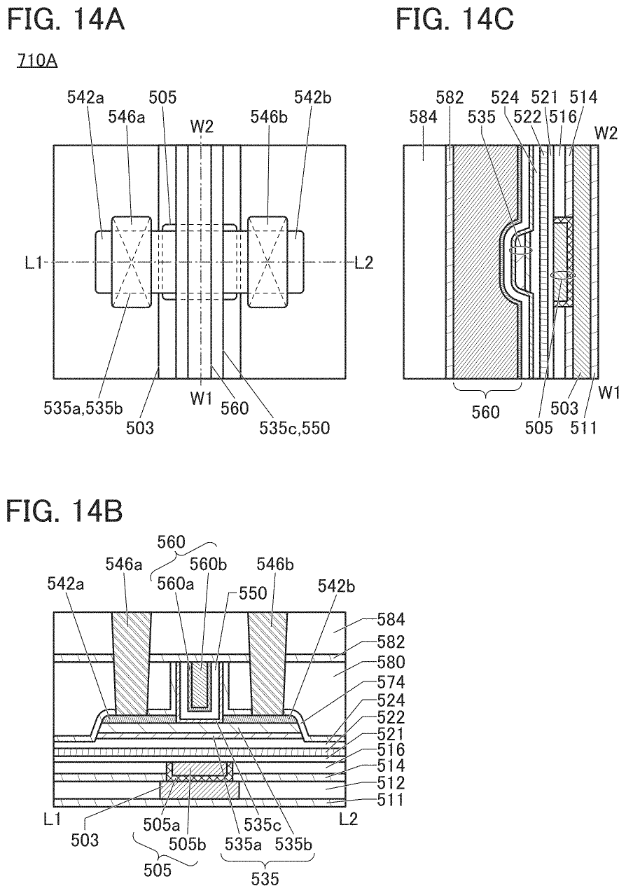

A structure example of a transistor 710A is described with reference to FIG. 14(A), FIG. 14(B), and FIG. 14(C). FIG. 14(A) is a top view of the transistor 710A. FIG. 14(B) is a cross-sectional view of a portion indicated by dashed-dotted line L1-L2 in FIG. 14(A). FIG. 14(C) is a cross-sectional view of a portion indicated by dashed-dotted line W1-W2 in FIG. 14(A). For clarity of the diagram, some components are not illustrated in the top view of FIG. 14(A).

FIG. 14(A), FIG. 14(B), and FIG. 14(C) illustrate the transistor 710A and an insulating layer 511, an insulating layer 512, an insulating layer 514, an insulating layer 516, an insulating layer 580, an insulating layer 582, and an insulating layer 584 that function as interlayer films. In addition, a conductive layer 546 (a conductive layer 546a and a conductive layer 546b) that is electrically connected to the transistor 710A and functions as a contact plug, and a conductive layer 503 functioning as a wiring are illustrated.

The transistor 710A includes a conductive layer 560 (a conductive layer 560a and a conductive layer 560b) functioning as a first gate electrode; a conductive layer 505 (a conductive layer 505a and a conductive layer 505b) functioning as a second gate electrode; an insulating layer 550 functioning as a first gate insulating film; an insulating layer 521, an insulating layer 522, and an insulating layer 524 that function as a second gate insulating layer; an oxide 535 (an oxide 535a, an oxide 535b, and an oxide 535c) including a region where a channel is formed; a conductive layer 542a functioning as one of a source and a drain; a conductive layer 542b functioning as the other of the source and the drain; and an insulating layer 574.

In the transistor 710A illustrated in FIG. 14, the oxide 535c, the insulating layer 550, and the conductive layer 560 are positioned in an opening provided in the insulating layer 580 with the insulating layer 574 positioned therebetween. Moreover, the oxide 535c, the insulating layer 550, and the conductive layer 560 are positioned between the conductive layer 542a and the conductive layer 542b.

The insulating layer 511 and the insulating layer 512 function as interlayer films.

As the interlayer film, a single layer or stacked layers of an insulating layer such as silicon oxide, silicon oxynitride, silicon nitride oxide, aluminum oxide, hafnium oxide, tantalum oxide, zirconium oxide, lead zirconate titanate (PZT), strontium titanate (SrTiO₃), or (Ba,Sr)TiO₃ (BST) can be used. Alternatively, aluminum oxide, bismuth oxide, germanium oxide, niobium oxide, silicon oxide, titanium oxide, tungsten oxide, yttrium oxide, or zirconium oxide may be added to these insulating layers, for example. Alternatively, these insulating layers may be subjected to nitriding treatment. Silicon oxide, silicon oxynitride, or silicon nitride may be stacked over the insulating layer.

For example, the insulating layer 511 preferably functions as a barrier film that inhibits entry of impurities such as water and hydrogen into the transistor 710A from the substrate side. Accordingly, for the insulating layer 511, it is preferable to use an insulating material that has a function of inhibiting diffusion of impurities such as a hydrogen atom, a hydrogen molecule, a water molecule, and a copper atom (through which the above impurities are less likely to pass). Alternatively, it is preferable to use an insulating material that has a function of inhibiting diffusion of oxygen (e.g., at least one of an oxygen atom, an oxygen molecule, and the like) (through which the above oxygen is less likely to pass). Moreover, aluminum oxide or silicon nitride, for example, may be used for the insulating layer 511. This structure can inhibit diffusion of impurities such as hydrogen and water to the transistor 710A side from the substrate side of the insulating layer 511.

For example, the dielectric constant of the insulating layer 512 is preferably lower than that of the insulating layer 511. When a material with a low dielectric constant is used for the interlayer film, the parasitic capacitance generated between wirings can be reduced.

The conductive layer 503 is formed to be embedded in the insulating layer 512. Here, the level of the top surface of the conductive layer 503 and the level of the top surface of the insulating layer 512 can be substantially the same. Note that although a structure in which the conductive layer 503 is a single layer is illustrated, the present invention is not limited thereto.

For example, the conductive layer 503 may have a multi-layer film structure of two or more layers. Note that for the conductive layer 503, a conductive material that has high conductivity and contains tungsten, copper, or aluminum as its main component is preferably used.

In the transistor 710A, the conductive layer 560 functions as a first gate (also referred to as a “top gate”) electrode. The conductive layer 505 functions as a second gate (also referred to as a “bottom gate”) electrode. In that case, the threshold voltage of the transistor 710A can be controlled by changing a potential applied to the conductive layer 505 not in synchronization with but independently of a potential applied to the conductive layer 560. In particular, the threshold voltage of the transistor 710A can be higher than 0 V and the off-state current can be reduced by applying a negative potential to the conductive layer 505. Thus, drain current at the time when a potential applied to the conductive layer 560 is 0 V can be lower in the case where a negative potential is applied to the conductive layer 505 than in the case where a negative potential is not applied to the conductive layer 505.

For example, when the conductive layer 505 and the conductive layer 560 overlap with each other, in the case where a potential is applied to the conductive layer 560 and the conductive layer 505, an electric field generated from the conductive layer 560 and an electric field generated from the conductive layer 505 are connected and can cover a channel formation region formed in the oxide 535.

That is, the channel formation region can be electrically surrounded by the electric field of the conductive layer 560 having a function of the first gate electrode and the electric field of the conductive layer 505 having a function of the second gate electrode.

Like the insulating layer 511 or the insulating layer 512, the insulating layer 514 and the insulating layer 516 function as interlayer films. For example, the insulating layer 514 preferably functions as a barrier film that inhibits entry of impurities such as water and hydrogen into the transistor 710A from the substrate side. This structure can inhibit diffusion of impurities such as hydrogen and water to the transistor 710A side from the substrate side of the insulating layer 514. Moreover, for example, the insulating layer 516 preferably has a lower dielectric constant than the insulating layer 514. When a material with a low dielectric constant is used for the interlayer film, the parasitic capacitance generated between wirings can be reduced.

In the conductive layer 505 functioning as the second gate, the conductive layer 505a is formed in contact with an inner wall of an opening in the insulating layer 514 and the insulating layer 516, and the conductive layer 505b is formed further inside. Here, the top surfaces of the conductive layer 505a and the conductive layer 505b and the top surface of the insulating layer 516 can be substantially level with each other. Although the transistor 710A having a structure in which the conductive layer 505a and the conductive layer 505b are stacked is illustrated, the present invention is not limited thereto. For example, the conductive layer 505 may have a single-layer structure or a stacked-layer structure of three or more layers.

Here, for the conductive layer 505a, a conductive material that has a function of inhibiting diffusion of impurities such as a hydrogen atom, a hydrogen molecule, a water molecule, and a copper atom (through which the above impurities are less likely to pass) is preferably used. Alternatively, it is preferable to use a conductive material that has a function of inhibiting diffusion of oxygen (e.g., at least one of an oxygen atom, an oxygen molecule, and the like) (through which the above oxygen is less likely to pass). Note that in this specification, a function of inhibiting diffusion of impurities or oxygen means a function of inhibiting diffusion of any one or all of the above impurities and the above oxygen.

For example, when the conductive layer 505a has a function of inhibiting diffusion of oxygen, a reduction in conductivity of the conductive layer 505b due to oxidation can be inhibited.

In the case where the conductive layer 505 doubles as a wiring, for the conductive layer 505b, it is preferable to use a conductive material that has high conductivity and contains tungsten, copper, or aluminum as its main component. In that case, the conductive layer 503 is not necessarily provided. Note that the conductive layer 505b is illustrated as a single layer but may have a stacked-layer structure, for example, a stack of any of the above conductive materials and titanium or titanium nitride.

The insulating layer 521, the insulating layer 522, and the insulating layer 524 function as a second gate insulating layer.

The insulating layer 522 preferably has a barrier property. The insulating layer 522 having a barrier property functions as a layer that inhibits entry of impurities such as hydrogen into the transistor 710A from the surroundings of the transistor 710A.

For the insulating layer 522, a single layer or stacked layers of an insulating layer containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current may arise because of a thinner gate insulating layer. When a high-k material is used for an insulating layer functioning as the gate insulating layer, a gate potential during operation of the transistor can be reduced while the physical thickness is maintained.

For example, it is preferable that the insulating layer 521 be thermally stable. For example, silicon oxide and silicon oxynitride, which have thermal stability, are preferable. In addition, a combination of an insulating layer of a high-k material and silicon oxide or silicon oxynitride allows the insulating layer to have a stacked-layer structure with thermal stability and a high dielectric constant.

Note that the second gate insulating layer is shown to have a three-layer stacked structure in FIG. 14, but may have a single-layer structure or a stacked-layer structure of two or more layers. In that case, without limitation to a stacked-layer structure formed of the same material, a stacked-layer structure formed of different materials may be employed.

The oxide 535 including a region functioning as the channel formation region includes the oxide 535a, the oxide 535b over the oxide 535a, and the oxide 535c over the oxide 535b. Including the oxide 535a under the oxide 535b makes it possible to inhibit diffusion of impurities into the oxide 535b from the components formed below the oxide 535a. Moreover, including the oxide 535c over the oxide 535b makes it possible to inhibit diffusion of impurities into the oxide 535b from the components formed above the oxide 535c. As the oxide 535, the oxide semiconductor described in the above embodiment, which is one kind of metal oxide, can be used.

Note that the oxide 535c is preferably provided in the opening provided in the insulating layer 580 with the insulating layer 574 positioned therebetween. When the insulating layer 574 has a barrier property, diffusion of impurities from the insulating layer 580 into the oxide 535 can be inhibited.

One of conductive layers 542 functions as a source electrode and the other functions as a drain electrode.

For the conductive layer 542a and the conductive layer 542b, a metal such as aluminum, titanium, chromium, nickel, copper, yttrium, zirconium, molybdenum, silver, tantalum, or tungsten or an alloy containing any of the metals as its main component can be used. In particular, a metal nitride film of tantalum nitride or the like is preferable because it has a barrier property against hydrogen or oxygen and its oxidation resistance is high.

Although a single-layer structure is shown in FIG. 14, a stacked-layer structure of two or more layers may be employed. For example, a tantalum nitride film and a tungsten film may be stacked. Alternatively, a titanium film and an aluminum film may be stacked. Further alternatively, a two-layer structure in which an aluminum film is stacked over a tungsten film, a two-layer structure in which a copper film is stacked over a copper-magnesium-aluminum alloy film, a two-layer structure in which a copper film is stacked over a titanium film, or a two-layer structure in which a copper film is stacked over a tungsten film may be employed.

A three-layer structure consisting of a titanium film or a titanium nitride film, an aluminum film or a copper film stacked over the titanium film or the titanium nitride film, and a titanium film or a titanium nitride film formed thereover; a three-layer structure consisting of a molybdenum film or a molybdenum nitride film, an aluminum film or a copper film stacked over the molybdenum film or the molybdenum nitride film, and a molybdenum film or a molybdenum nitride film formed thereover; or the like may be employed. Note that a transparent conductive material containing indium oxide, tin oxide, or zinc oxide may be used.

A barrier layer may be provided over the conductive layer 542. For the barrier layer, a material having a barrier property against oxygen or hydrogen is preferably used. This structure can inhibit oxidation of the conductive layer 542 at the time of depositing the insulating layer 574.

A metal oxide can be used for the barrier layer, for example. In particular, an insulating film of aluminum oxide, hafnium oxide, gallium oxide, or the like, which has a barrier property against oxygen and hydrogen, is preferably used. Alternatively, silicon nitride formed by a CVD method may be used.

With the barrier layer, the range of choices for the material of the conductive layer 542 can be expanded. For example, a material having a low oxidation resistance and high conductivity, such as tungsten or aluminum, can be used for the conductive layer 542. Moreover, for example, a conductor that can be easily deposited or processed can be used.

The insulating layer 550 functions as a first gate insulating layer. The insulating layer 550 is preferably provided in the opening provided in the insulating layer 580 with the oxide 535c and the insulating layer 574 positioned therebetween.

As miniaturization and high integration of transistors progress, a problem such as leakage current may arise because of a thinner gate insulating layer. In that case, the insulating layer 550 may have a stacked-layer structure like the second gate insulating layer. When the insulating layer functioning as the gate insulating layer has a stacked-layer structure of a high-k material and a thermally stable material, a gate potential during operation of the transistor can be reduced while the physical thickness is maintained. Furthermore, the stacked-layer structure can be thermally stable and have a high dielectric constant.

The conductive layer 560 functioning as a first gate electrode includes the conductive layer 560a and the conductive layer 560b over the conductive layer 560a. Like the conductive layer 505a, for the conductive layer 560a, it is preferable to use a conductive material having a function of inhibiting diffusion of impurities such as a hydrogen atom, a hydrogen molecule, a water molecule, and a copper atom. Alternatively, it is preferable to use a conductive material having a function of inhibiting diffusion of oxygen (e.g., at least one of an oxygen atom, an oxygen molecule, and the like).

When the conductive layer 560a has a function of inhibiting oxygen diffusion, the range of choices for the material of the conductive layer 560b can be expanded. That is, the conductive layer 560a inhibits oxidation of the conductive layer 560b, thereby preventing the decrease in conductivity of the conductive layer 560b.

As a conductive material having a function of inhibiting diffusion of oxygen, for example, tantalum, tantalum nitride, ruthenium, or ruthenium oxide is preferably used. For the conductive layer 560a, the oxide semiconductor that can be used as the oxide 535 can be used. In that case, when the conductive layer 560b is deposited by a sputtering method, the electric resistance of the conductive layer 560a is lowered so that the conductive layer 560a can become a conductor. This can be referred to as an OC (Oxide Conductor) electrode.

For the conductive layer 560b, it is preferable to use a conductive material containing tungsten, copper, or aluminum as its main component. The conductive layer 560 functions as a wiring and thus a conductor having high conductivity is preferably used. The conductive layer 560b may have a stacked-layer structure, for example, a stack of any of the above conductive materials and titanium or titanium nitride.

The insulating layer 574 is positioned between the insulating layer 580 and the transistor 710A. For the insulating layer 574, an insulating material having a function of inhibiting diffusion of oxygen and impurities such as water and hydrogen is preferably used. For example, aluminum oxide or hafnium oxide is preferably used. Moreover, it is possible to use, for example, a metal oxide such as magnesium oxide, gallium oxide, germanium oxide, yttrium oxide, zirconium oxide, lanthanum oxide, neodymium oxide, or tantalum oxide; silicon nitride oxide; silicon nitride; or the like.

The insulating layer 574 can inhibit diffusion of impurities such as water and hydrogen contained in the insulating layer 580 into the oxide 535b through the oxide 535c and the insulating layer 550. In addition, oxidation of the conductive layer 560 due to excess oxygen contained in the insulating layer 580 can be inhibited.

The insulating layer 580, the insulating layer 582, and the insulating layer 584 function as interlayer films.

Like the insulating layer 514, the insulating layer 582 preferably functions as a barrier insulating film that inhibits entry of impurities such as water and hydrogen into the transistor 710A from the outside.

The use of an insulating material having a resistivity higher than or equal to 1×10¹⁰ Ωcm and lower than or equal to 1×10¹⁵ Ωcm for the insulating layer 582 can reduce plasma damage caused in deposition, etching, or the like. For example, silicon nitride having a resistivity lower than or equal to 1×10¹⁴ Ωcm, preferably lower than or equal to 1×10¹³ Ωcm is used for the insulating layer 582. Note that an insulating material having a resistivity higher than or equal to 1×10¹⁰ Ωcm and lower than or equal to 1×10¹⁵ Ωcm may be used not only for the insulating layer 582 but also for the other insulating layers. For example, silicon nitride having a resistivity lower than or equal to 1×10¹⁴ Ωcm, preferably lower than or equal to 1×10¹³ Ωcm may be used for the insulating layer 584, the insulating layer 580, the insulating layer 524, and/or the insulating layer 516.

Like the insulating layer 516, the insulating layer 580 and the insulating layer 584 preferably have a lower dielectric constant than the insulating layer 582. When a material with a low dielectric constant is used for the interlayer films, the parasitic capacitance generated between wirings can be reduced.

The transistor 710A may be electrically connected to another component through a plug or a wiring such as the conductive layer 546 embedded in the insulating layer 580, the insulating layer 582, and the insulating layer 584.

As a material for the conductive layer 546, a conductive material such as a metal material, an alloy material, a metal nitride material, or a metal oxide material can be used as a single layer or stacked layers, as in the conductive layer 505. For example, it is preferable to use a high-melting-point material that has both heat resistance and conductivity, such as tungsten or molybdenum. Alternatively, it is preferable to use a low-resistance conductive material such as aluminum or copper. The use of a low-resistance conductive material can reduce wiring resistance.

For example, when the conductive layer 546 has a stacked-layer structure of tantalum nitride or the like, which is a conductor having a barrier property against hydrogen and oxygen, and tungsten, which has high conductivity, diffusion of impurities from the outside can be inhibited while the conductivity of a wiring is maintained.

With the above structure, a semiconductor device including a transistor that contains an oxide semiconductor and has a high on-state current can be provided. Alternatively, a semiconductor device including a transistor that contains an oxide semiconductor and has a low off-state current can be provided. Alternatively, a semiconductor device that has small variations in electrical characteristics, stable electrical characteristics, and high reliability can be provided.

### <Transistor Structure Example 2>

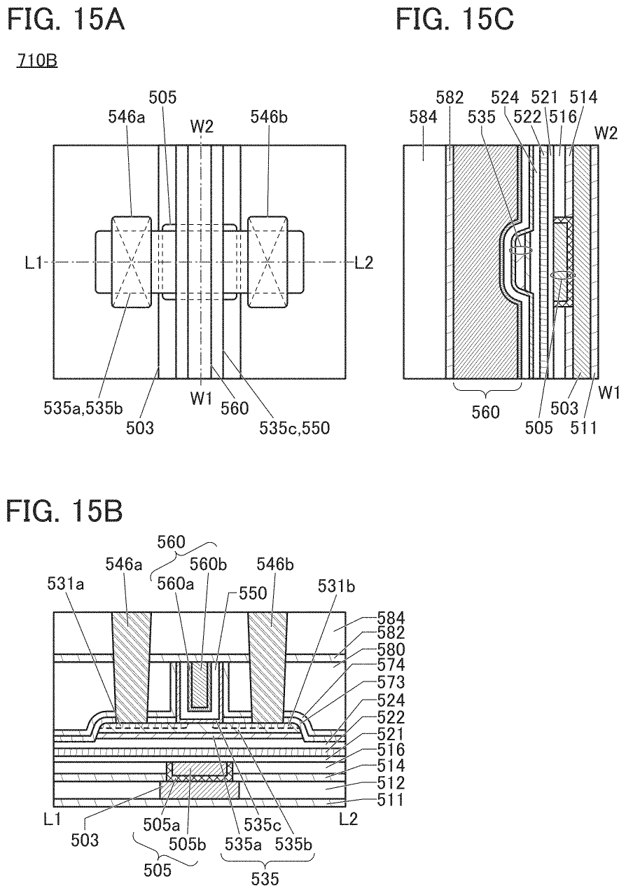

A structure example of a transistor 710B is described with reference to FIG. 15(A), FIG. 15(B), and FIG. 15(C). FIG. 15(A) is a top view of the transistor 710B. FIG. 15(B) is a cross-sectional view of a portion indicated by dashed-dotted line L1-L2 in FIG. 15(A). FIG. 15(C) is a cross-sectional view of a portion indicated by dashed-dotted line W1-W2 in FIG. 15(A). For clarity of the diagram, some components are not illustrated in the top view of FIG. 15(A).

The transistor 710B is a modification example of the above transistor. Therefore, the point different from the above transistor will be mainly described to avoid repeated description.

In FIG. 15(A) to FIG. 15(C), the conductive layer 542 (the conductive layer 542a and the conductive layer 542b) is not provided, and part of the exposed surface of the oxide 535b includes a region 531a and a region 531b. One of the region 531a and the region 531b functions as a source region, and the other functions as a drain region. Moreover, an insulating layer 573 is included between the oxide 535b and the insulating layer 574.

The region 531 (the region 531a and the region 531b), which is shown in FIG. 15, is the region of the oxide 535b to which an element that reduces the resistance of the oxide 535b is added. The region 531 can be formed with the use of a dummy gate, for example.

Specifically, a dummy gate is provided over the oxide 535b, and the above element that reduces the resistance of the oxide 535b is added using the dummy gate as a mask. That is, the element is added to regions of the oxide 535 that do not overlap with the dummy gate, whereby the region 531 is formed. As a method of adding the element, an ion implantation method by which an ionized source gas is subjected to mass separation and then added, an ion doping method by which an ionized source gas is added without mass separation, a plasma immersion ion implantation method, or the like can be used.

Typical examples of the element that reduces the resistance of the oxide 535 are boron and phosphorus. Moreover, hydrogen, carbon, nitrogen, fluorine, sulfur, chlorine, titanium, a rare gas element, or the like may be used. Typical examples of the rare gas element include helium, neon, argon, krypton, and xenon. The concentration of the element is measured by secondary ion mass spectrometry (SIMS) or the like.

In particular, boron and phosphorus are preferable because an apparatus used in a manufacturing line for amorphous silicon or low-temperature polysilicon can be used. Since the existing facility can be used, capital investment can be reduced.

Next, an insulating film to be the insulating layer 573 and an insulating film to be the insulating layer 574 may be deposited over the oxide 535b and the dummy gate. Stacking the insulating film to be the insulating layer 573 and the insulating film to be the insulating layer 574 can provide a region where the region 531, the oxide 535c, and the insulating layer 550 overlap with each other.

Specifically, after an insulating film to be the insulating layer 580 is provided over the insulating film to be the insulating layer 574, the insulating film to be the insulating layer 580 is subjected to CMP (Chemical Mechanical Polishing) treatment, whereby part of the insulating film to be the insulating layer 580 is removed and the dummy gate is exposed. Then, when the dummy gate is removed, part of the insulating layer 573 in contact with the dummy gate is preferably also removed. Thus, the insulating layer 574 and the insulating layer 573 are exposed at the side surface of the opening provided in the insulating layer 580, and the region 531 provided in the oxide 535b is partly exposed at the bottom surface of the opening. Next, an oxide film to be the oxide 535c, an insulating film to be the insulating layer 550, and a conductive film to be the conductive layer 560 are deposited in this order in the opening, and then, the oxide film to be the oxide 535c, the insulating film to be the insulating layer 550, and the conductive film to be the conductive layer 560 are partly removed by CMP treatment or the like until the insulating layer 580 is exposed; thus, the transistor illustrated in FIG. 15 can be formed.

Note that the insulating layer 573 and the insulating layer 574 are not essential components. Design is appropriately set in consideration of required transistor characteristics.

The cost of the transistor illustrated in FIG. 15 can be reduced because an existing apparatus can be used and the conductive layer 542 is not provided.

### <Transistor Structure Example 3>

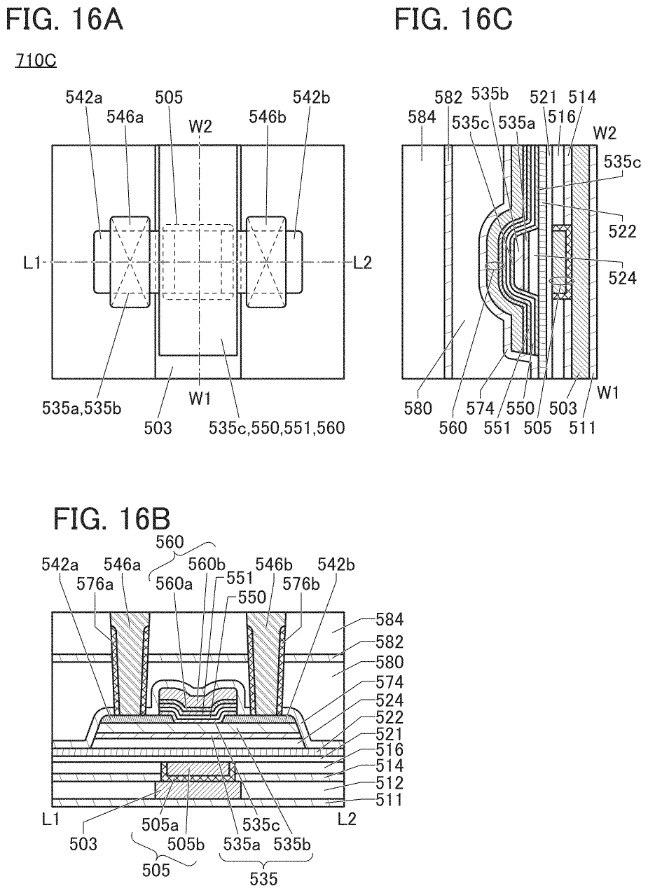

A structure example of a transistor 710C is described with reference to FIG. 16(A), FIG. 16(B), and FIG. 16(C). FIG. 16(A) is a top view of the transistor 710C. FIG. 16(B) is a cross-sectional view of a portion indicated by dashed-dotted line L1-L2 in FIG. 16(A). FIG. 16(C) is a cross-sectional view of a portion indicated by dashed-dotted line W1-W2 in FIG. 16(A). For clarity of the diagram, some components are not illustrated in the top view of FIG. 16(A).

The transistor 710C is a modification example of the above transistor. Therefore, the point different from the transistor 710A will be mainly described to avoid repeated description.

The transistor 710C includes a region where the conductive layer 542 (the conductive layer 542a and the conductive layer 542b), the oxide 535c, the insulating layer 550, the oxide 551, and the conductive layer 560 overlap with each other. With this structure, a transistor having a high on-state current can be provided. Moreover, a transistor having high controllability can be provided.

The conductive layer 560 functioning as a first gate electrode includes the conductive layer 560a and the conductive layer 560b over the conductive layer 560a. Like the conductive layer 505a, for the conductive layer 560a, it is preferable to use a conductive material having a function of inhibiting diffusion of impurities such as a hydrogen atom, a hydrogen molecule, a water molecule, and a copper atom. Alternatively, it is preferable to use a conductive material having a function of inhibiting diffusion of oxygen (e.g., at least one of an oxygen atom, an oxygen molecule, and the like).

When the conductive layer 560a has a function of inhibiting oxygen diffusion, the range of choices for the material of the conductive layer 560b can be expanded. That is, the conductive layer 560a inhibits oxidation of the conductive layer 560b, thereby preventing the decrease in conductivity of the conductive layer 560b.

In addition, to adjust Vth of the transistor, a material used for the conductive layer 560a may be determined in consideration of a work function. For example, the conductive layer 560a may be formed using titanium nitride, and the conductive layer 560b may be formed using tungsten. The conductive layer 560a and the conductive layer 560b are formed by a known deposition method such as a sputtering method, a CVD method, or an AFM method. Note that the deposition temperature in the case where titanium nitride is deposited by a CVD method is preferably higher than or equal to 380° C. and lower than or equal to 500° C., further preferably higher than or equal to 400° C. and lower than or equal to 450° C.

The oxide 551 may be formed using a material similar to those of the other insulating layers. As the oxide 551, a metal oxide such as an In-M-Zn oxide containing excess oxygen (the element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) may be used. For example, as the oxide 551, an In—Ga—Zn oxide is deposited by a sputtering method. Specifically, for example, deposition is performed using a target with an atomic ratio of In:Ga:Zn=1:3:4 and a sputtering gas containing oxygen. In the case where the oxide 551 is deposited by a sputtering method, the flow rate ratio of oxygen contained in the sputtering gas is preferably higher than or equal to 70%, further preferably higher than or equal to 80%, still further preferably 100%.

When a gas containing oxygen is used as a sputtering gas, oxygen can be supplied not only to the oxide 551 but also to the insulating layer 550 that is a formation surface of the oxide 551. Furthermore, when the flow rate ratio of oxygen contained in the sputtering gas is increased, the amount of oxygen supplied to the insulating layer 550 can be increased.

Moreover, when the oxide 551 is provided over the insulating layer 550, excess oxygen contained in the insulating layer 550 is unlikely to be diffused into the conductive layer 560. Thus, the reliability of the transistor can be increased. Note that the oxide 551 may be omitted depending on purposes or the like.

The insulating layer 574 is preferably provided to cover the top surface and the side surface of the conductive layer 560, the side surface of the insulating layer 550, and the side surface of the oxide 535c. For the insulating layer 574, an insulating material having a function of inhibiting diffusion of oxygen and impurities such as water and hydrogen is preferably used. For example, aluminum oxide or hafnium oxide is preferably used. Moreover, it is possible to use, for example, a metal oxide such as magnesium oxide, gallium oxide, germanium oxide, yttrium oxide, zirconium oxide, lanthanum oxide, neodymium oxide, or tantalum oxide; silicon nitride oxide; silicon nitride; or the like.

The insulating layer 574 can inhibit oxidation of the conductive layer 560. Moreover, the insulating layer 574 can inhibit diffusion of impurities such as water and hydrogen contained in the insulating layer 580 into the transistor 710C.

The insulating layer 576 (the insulating layer 576a and the insulating layer 576b) having a barrier property may be provided between the conductive layer 546 and the insulating layer 580. Providing the insulating layer 576 can prevent oxygen in the insulating layer 580 from reacting with the conductive layer 546 and oxidizing the conductive layer 546.

Furthermore, with the insulating layer 576 having a barrier property, the range of choices for the material of the conductor used as the plug or the wiring can be expanded. A metal material having an oxygen absorbing property and high conductivity can be used for the conductive layer 546, for example.

### <Transistor Structure Example 4>

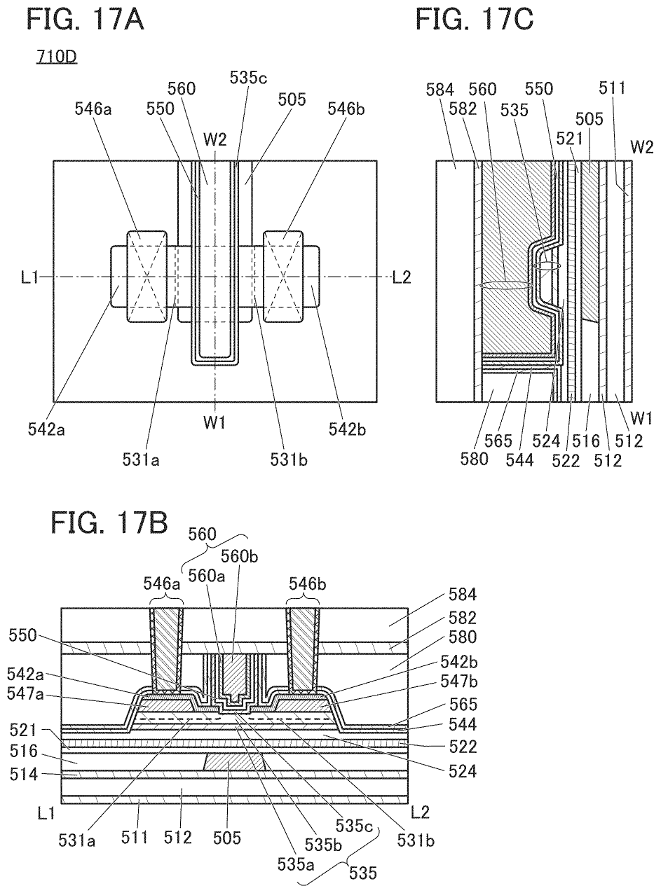

A structure example of a transistor 710D is described with reference to FIG. 17(A), FIG. 17(B), and FIG. 17(C). FIG. 17(A) is a top view of the transistor 710D. FIG. 17(B) is a cross-sectional view of a portion indicated by dashed-dotted line L1-L2 in FIG. 17(A). FIG. 17(C) is a cross-sectional view of a portion indicated by dashed-dotted line W1-W2 in FIG. 17(A). For clarity of the diagram, some components are not illustrated in the top view of FIG. 17(A).

The transistor 710D is a modification example of the above transistor. Therefore, the point different from the transistor 710A will be mainly described to avoid repeated description.

In the transistor 710D illustrated in FIG. 17, a conductive layer 547a is placed between the conductive layer 542a and the oxide 535b, and a conductive layer 547b is placed between the conductive layer 542b and the oxide 535b. Here, the conductive layer 542a (the conductive layer 542b) extends beyond the top surface and the side surface on the conductive layer 560 side of the conductive layer 547a (the conductive layer 547b), and includes a region in contact with the top surface of the oxide 535b. Here, for the conductive layer 547 (the conductive layer 547a and the conductive layer 547b), a conductor that can be used for the conductive layer 542 is used. It is preferred that the thickness of the conductive layer 547 be at least greater than that of the conductive layer 542.

In the transistor 710D in FIG. 17 having such a structure, the conductive layer 542 can be closer to the conductive layer 560 than that in the transistor 710A is. Alternatively, an end portion of the conductive layer 542a and an end portion of the conductive layer 542b can overlap with the conductive layer 560. Accordingly, an effective channel length of the transistor 710D can be shortened; thus, the transistor 710D can have a high on-state current and improved frequency characteristics.

The conductive layer 547a (the conductive layer 547b) is preferably provided to overlap with the conductive layer 542a (the conductive layer 542b). With such a structure, the conductive layer 547a (the conductive layer 547b) functioning as a stopper can prevent over-etching of the oxide 535b by etching for forming the opening where the conductive layer 546a (the conductive layer 546b) is to be embedded.

The transistor 710D illustrated in FIG. 17 includes an insulating layer 544 that extends beyond the conductive layer 542a and the conductive layer 542b. An insulating layer 565 may be provided over and in contact with the insulating layer 544. The insulating layer 544 preferably functions as a barrier insulating film that inhibits entry of impurities such as water and hydrogen and excess oxygen into the transistor 710D from the insulating layer 580 side. As the insulating layer 565, an insulating layer that can be used as the insulating layer 544 can be used. In addition, the insulating layer 544 may be formed using a nitride insulating material such as aluminum nitride, aluminum titanium nitride, titanium nitride, silicon nitride, or silicon nitride oxide, for example.

Unlike in the transistor 710A illustrated in FIG. 14, in the transistor 710D illustrated in FIG. 17, the conductive layer 505 may be provided to have a single-layer structure. In this case, an insulating film to be the insulating layer 516 is deposited over the patterned conductive layer 505, and an upper portion of the insulating film is removed by a CMP method or the like until the top surface of the conductive layer 505 is exposed. Preferably, the planarity of the top surface of the conductive layer 505 is made favorable. For example, the average surface roughness (Ra) of the top surface of the conductive layer 505 is less than or equal to 1 nm, preferably less than or equal to 0.5 nm, further preferably less than or equal to 0.3 nm. This allows the improvement in planarity of the insulating layer formed over the conductive layer 505 and the increase in crystallinity of the oxide 535b and the oxide 535c.

### <Transistor Structure Example 5>

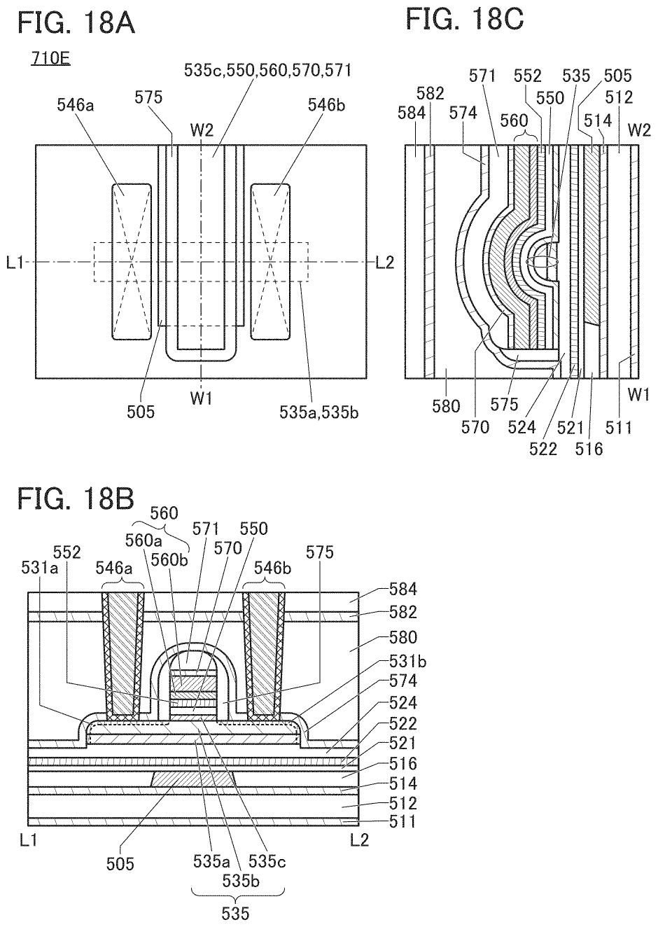

A structure example of a transistor 710E is described with reference to FIG. 18(A), FIG. 18(B), and FIG. 18(C). FIG. 18(A) is a top view of the transistor 710E. FIG. 18(B) is a cross-sectional view of a portion indicated by dashed-dotted line L1-L2 in FIG. 18(A). FIG. 18(C) is a cross-sectional view of a portion indicated by dashed-dotted line W1-W2 in FIG. 18(A). For clarity of the diagram, some components are not illustrated in the top view of FIG. 18(A).

The transistor 710E is a modification example of the above transistor. Therefore, the point different from the above transistor will be mainly described to avoid repeated description.

In FIG. 18(A) to FIG. 18(C), the conductive layer 503 is not provided and the conductive layer 505 functioning as the second gate also functions as a wiring. The insulating layer 550 is provided over the oxide 535c, and a metal oxide 552 is provided over the insulating layer 550. The conductive layer 560 is provided over the metal oxide 552, and an insulating layer 570 is provided over the conductive layer 560. An insulating layer 571 is provided over the insulating layer 570.

The metal oxide 552 preferably has a function of inhibiting diffusion of oxygen. When the metal oxide 552 that inhibits diffusion of oxygen is provided between the insulating layer 550 and the conductive layer 560, diffusion of the oxygen to the conductive layer 560 is inhibited. That is, a reduction in the amount of oxygen supplied to the oxide 535 can be inhibited. Moreover, oxidization of the conductive layer 560 due to oxygen can be inhibited.

Note that the metal oxide 552 may function as part of the first gate. For the metal oxide 552, the oxide semiconductor that can be used as the oxide 535 can be used, for example. In that case, when the conductive layer 560 is deposited by a sputtering method, the electric resistance of the metal oxide 552 is lowered so that the metal oxide 552 can become a conductive layer. This can be referred to as an OC (Oxide Conductor) electrode.

In addition, the metal oxide 552 functions as part of a gate insulating layer in some cases. Thus, when silicon oxide, silicon oxynitride, or the like is used for the insulating layer 550, a metal oxide that is a high-k material with a high dielectric constant is preferably used for the metal oxide 552. Such a stacked-layer structure can be thermally stable and can have a high dielectric constant. Thus, a gate potential that is applied during operation of the transistor can be reduced while the physical thickness is maintained. In addition, the equivalent oxide thickness (EOT) of the insulating layer functioning as the gate insulating layer can be reduced.

Although the metal oxide 552 in the transistor 710E is shown as a single layer, the metal oxide 552 may have a stacked-layer structure of two or more layers. For example, a metal oxide functioning as part of a gate electrode and a metal oxide functioning as part of the gate insulating layer may be stacked.

With the metal oxide 552 functioning as a gate electrode, the on-state current of the transistor 710E can be increased without a reduction in the influence of the electric field from the conductive layer 560. With the metal oxide 552 functioning as a gate insulating layer, the distance between the conductive layer 560 and the oxide 535 is kept by the physical thicknesses of the insulating layer 550 and the metal oxide 552, so that leakage current between the conductive layer 560 and the oxide 535 can be reduced. Thus, with the stacked-layer structure of the insulating layer 550 and the metal oxide 552, the physical distance between the conductive layer 560 and the oxide 535 and the intensity of electric field applied from the conductive layer 560 to the oxide 535 can be easily adjusted as appropriate.

Specifically, the oxide semiconductor that can be used for the oxide 535 can also be used for the metal oxide 552 when the resistance thereof is reduced. Alternatively, a metal oxide containing one kind or two or more kinds selected from hafnium, aluminum, gallium, yttrium, zirconium, tungsten, titanium, tantalum, nickel, germanium, magnesium, and the like can be used.

It is particularly preferable to use an insulating layer containing an oxide of one or both of aluminum and hafnium, for example, aluminum oxide, hafnium oxide, or an oxide containing aluminum and hafnium (hafnium aluminate). In particular, hafnium aluminate has higher heat resistance than a hafnium oxide film. Therefore, hafnium aluminate is preferable since it is less likely to be crystallized by heat treatment in a later step. Note that the metal oxide 552 is not an essential structure. Design is appropriately set in consideration of required transistor characteristics.

For the insulating layer 570, an insulating material having a function of inhibiting the passage of oxygen and impurities such as water and hydrogen is preferably used. For example, aluminum oxide or hafnium oxide is preferably used. Thus, oxidization of the conductive layer 560 due to oxygen from above the insulating layer 570 can be inhibited. Moreover, entry of impurities such as water and hydrogen from above the insulating layer 570 into an oxide 530 through the conductive layer 560 and the insulating layer 550 can be inhibited.

The insulating layer 571 functions as a hard mask. By providing the insulating layer 571, the conductive layer 560 can be processed to have a side surface that is substantially vertical; specifically, an angle formed by the side surface of the conductive layer 560 and a surface of the substrate can be greater than or equal to 75° and less than or equal to 100°, preferably greater than or equal to 80° and less than or equal to 95°.

An insulating material having a function of inhibiting the passage of oxygen and impurities such as water and hydrogen may be used for the insulating layer 571 so that the insulating layer 571 also functions as a barrier layer. In that case, the insulating layer 570 does not have to be provided.

Parts of the insulating layer 570, the conductive layer 560, the metal oxide 552, the insulating layer 550, and the oxide 535c are selected and removed using the insulating layer 571 as a hard mask, whereby their side surfaces can be substantially aligned with each other and a surface of the oxide 535b can be partly exposed.

The transistor 710E includes the region 531a and the region 531b on part of the exposed surface of the oxide 535b. One of the region 531a and the region 531b functions as a source region, and the other functions as a drain region.

The region 531a and the region 531b can be formed by addition of an impurity element such as phosphorus or boron to the exposed surface of the oxide 535b by an ion implantation method, an ion doping method, a plasma immersion ion implantation method, or plasma treatment, for example. In this embodiment and the like, an “impurity element” refers to an element other than main constituent elements.

Alternatively, the region 531a and the region 531b can be formed in such manner that, after part of the surface of the oxide 535b is exposed, a metal film is formed and then heat treatment is performed so that the element contained in the metal film is diffused into the oxide 535b.

The electrical resistivity of regions of the oxide 535b to which the impurity element is added decreases. For that reason, the region 531a and the region 531b are sometimes referred to “impurity regions” or “low-resistance regions”.

The region 531a and the region 531b can be formed in a self-aligned manner by using the insulating layer 571 and/or the conductive layer 560 as a mask. Accordingly, the conductive layer 560 does not overlap with the region 531a and/or the region 531b, so that the parasitic capacitance can be reduced. Moreover, an offset region is not formed between a channel formation region and the source/drain region (the region 531a or the region 531b). The formation of the region 531a and the region 531b in a self-aligned manner achieves an increase in on-state current, a reduction in threshold voltage, and an improvement in operating frequency, for example.

Note that an offset region may be provided between the channel formation region and the source/drain region in order to further reduce the off-state current. The offset region is a region where the electrical resistivity is high and a region where the above-described addition of the impurity element is not performed. The offset region can be formed by the above-described addition of the impurity element after the formation of an insulating layer 575. In this case, the insulating layer 575 serves as a mask like the insulating layer 571 or the like. Thus, the impurity element is not added to a region of the oxide 535b that overlaps with the insulating layer 575, so that the electrical resistivity of the region can be kept high.

The transistor 710E includes the insulating layer 575 on the side surfaces of the insulating layer 570, the conductive layer 560, the metal oxide 552, the insulating layer 550, and the oxide 535c. The insulating layer 575 is preferably an insulating layer having a low dielectric constant. For example, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like is preferably used. In particular, silicon oxide, silicon oxynitride, silicon nitride oxide, or porous silicon oxide is preferably used for the insulating layer 575, in which case an excess-oxygen region can be easily formed in the insulating layer 575 in a later step. Silicon oxide and silicon oxynitride are preferable because of their thermal stability. The insulating layer 575 preferably has a function of diffusing oxygen.

The transistor 710E also includes the insulating layer 574 over the insulating layer 575 and the oxide 535. The insulating layer 574 is preferably deposited by a sputtering method. When a sputtering method is used, an insulating layer containing few impurities such as water and hydrogen can be deposited. For example, aluminum oxide is preferably used for the insulating layer 574.

Note that, in some cases, an oxide film formed by a sputtering method extracts hydrogen from the structure body over which the oxide film is deposited. Thus, the hydrogen concentration in the oxide 230 and the insulating layer 575 can be reduced when the insulating layer 574 absorbs hydrogen and water from the oxide 530 and the insulating layer 575.

This embodiment can be implemented in combination with the other embodiments and examples as appropriate.

### Embodiment 7

In this embodiment, an image of a product in which the semiconductor device described in the above embodiment can be used, and electronic components and electronic devices in which the semiconductor device described in the above embodiment can be used will be described.

### <Product Image>

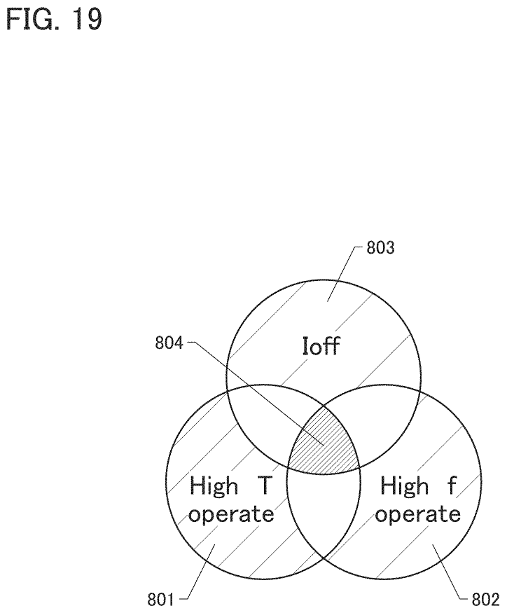

First, FIG. 19 illustrates an image of a product in which the semiconductor device of one embodiment of the present invention can be used. A region 801 illustrated in FIG. 19 represents high temperature characteristics (High T operate), a region 802 represents high frequency characteristics (High f operate), a region 803 represents low off-state characteristics (Ioff), and a region 804 represents a region where the region 801, the region 802, and the region 803 overlap with one another.

Note that the region 801 can be roughly satisfied by using a carbide or a nitride such as silicon carbide or gallium nitride for a channel formation region of a transistor. The region 802 can be roughly satisfied by using a silicide such as single crystal silicon or crystalline silicon for a channel formation region of a transistor. The region 803 can be roughly satisfied by using an OS, which is one kind of metal oxide, for a channel formation region of a transistor.

The semiconductor device of one embodiment of the present invention can be favorably used for a product in the range represented by the region 804, for example.

A conventional product has difficulty in satisfying all of the region 801, the region 802, and the region 803. However, in the case where an OS is used for a channel formation region of a transistor included in the semiconductor device of one embodiment of the present invention, particularly in the case of using a crystalline OS, a semiconductor device which achieves high temperature characteristics, high frequency characteristics, and low off-state characteristics can be provided.

Note that examples of a product including the semiconductor device of one embodiment of the present invention in the range represented by the region 804 are an electronic device including a low-power consumption and high-performance CPU, an in-car electronic component and an in-car electronic device required to have high reliability in a high-temperature environment. Next, examples of electronic components and electronic devices in which the semiconductor device of one embodiment of the present invention is incorporated are described.

The semiconductor device of one embodiment of the present invention can be mounted on a variety of electronic devices. In particular, the semiconductor device of one embodiment of the present invention can be used as a memory incorporated in an electronic device. Examples of electronic devices include a digital camera, a digital video camera, a digital photo frame, a mobile phone, a portable game machine, a portable information terminal, and an audio reproducing device in addition to electronic devices provided with a relatively large screen, such as a television device, a desktop or laptop personal computer, a monitor for a computer or the like, digital signage, and a large game machine like a pachinko machine.

The electronic device of one embodiment of the present invention may include an antenna. When a signal is received by the antenna, the electronic device can display a video, data, or the like on the display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radioactive rays, flow rate, humidity, gradient, oscillation, a smell, or infrared rays).

The electronic device of one embodiment of the present invention can have a variety of functions. For example, the electronic device in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### <Electronic Components>

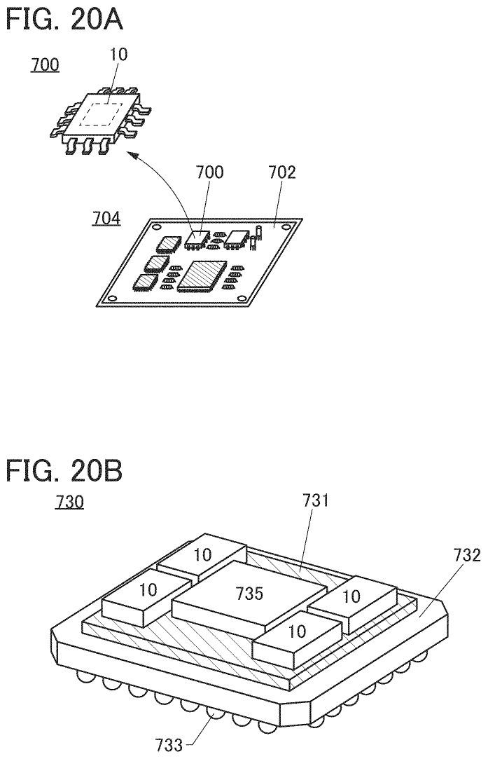

Examples of an electronic component including the semiconductor device 10 are illustrated in FIG. 20(A) and FIG. 20(B).

FIG. 20(A) is a perspective view of an electronic component 700 and a substrate (mounting board 704) on which the electronic component 700 is mounted. The electronic component 700 illustrated in FIG. 20(A) is an IC semiconductor device and includes a lead and a circuit portion. The electronic component 700 is mounted on a printed circuit board 702, for example. A plurality of such IC semiconductor devices are combined and electrically connected to each other on the printed circuit board 702, whereby the mounting board 704 is completed.

The semiconductor device 10 described in the above embodiment is provided as the circuit portion of the electronic component 700. Although a QFP (Quad Flat Package) is used as the package of the electronic component 700 in FIG. 20(A), the mode of the package is not limited thereto.

FIG. 20(B) is a perspective view of an electronic component 730. The electronic component 730 is an example of a SiP (System in package) or an MCM (Multi-Chip Module). In the electronic component 730, an interposer 731 is provided on a package substrate 732 (a printed circuit board), and a semiconductor device 735 and a plurality of semiconductor devices 10 are provided on the interposer 731.

The electronic component 730 using the semiconductor devices 10 as high bandwidth memory (HBM) is shown as an example. An integrated circuit such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings are provided in a single layer or multiple layers. Moreover, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. A through electrode may be provided in the interposer 731 and used for electrically connecting an integrated circuit and the package substrate 732. For a silicon interposer, a TSV (Through Silicon Via) can also be used as the through electrode.

A silicon interposer is preferably used as the interposer 731. A silicon interposer can be manufactured at lower cost than an integrated circuit because it is not necessary to provide an active element. Meanwhile, since wirings of a silicon interposer can be formed through a semiconductor process, formation of minute wirings, which is difficult for a resin interposer, is easy.

In order to achieve a wide memory bandwidth, many wirings need to be used for HBM. Therefore, formation of minute and high-density wirings is required for an interposer on which HBM is mounted. For this reason, a silicon interposer is preferably used as the interposer on which HBM is mounted.

In a SiP, an MCM, or the like using a silicon interposer, the decrease in reliability due to a difference in expansion coefficient between an integrated circuit and the interposer does not easily occur. Furthermore, the surface of a silicon interposer has high planarity, so that a poor connection between the silicon interposer and an integrated circuit provided on the silicon interposer does not easily occur. It is particularly preferable to use a silicon interposer for a 2.5D package (2.5D mounting) in which a plurality of integrated circuits are arranged on an interposer.

A heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 10 and the semiconductor device 735 are preferably equal to each other.

To mount the electronic component 730 on another substrate, an electrode 733 may be provided on the bottom portion of the package substrate 732. FIG. 20(B) illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

### <Electronic Devices>

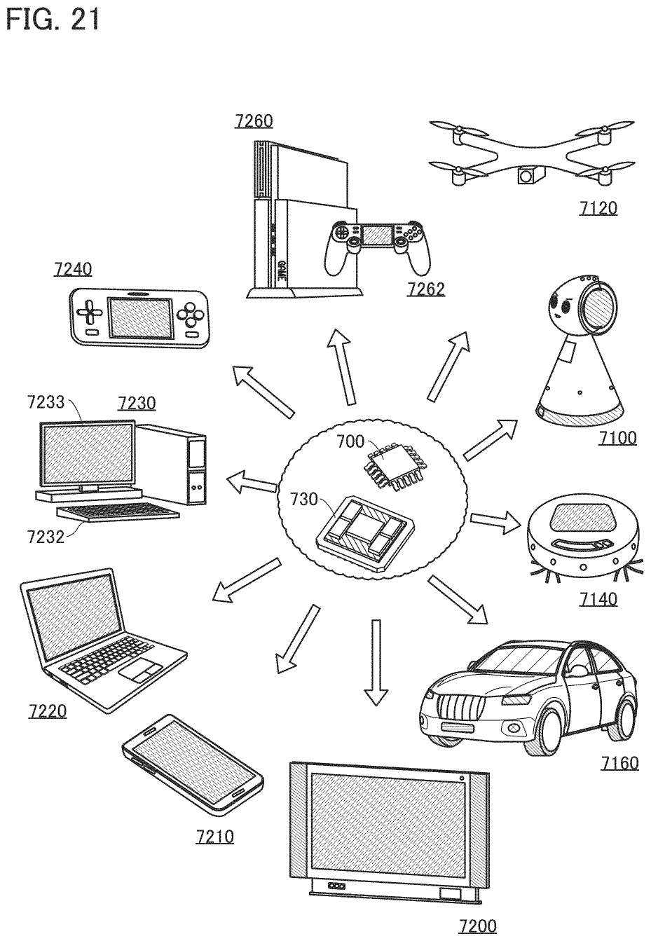

Next, examples of an electronic device including the above electronic component will be described with reference to FIG. 21 to FIG. 23.

A robot 7100 includes an illuminance sensor, a microphone, a camera, a speaker, a display, various kinds of sensors (e.g., an infrared ray sensor, an ultrasonic wave sensor, an acceleration sensor, a piezoelectric sensor, an optical sensor, and a gyro sensor), a moving mechanism, and the like. The electronic component 730 includes a processor or the like and has a function of controlling these peripheral devices. For example, the electronic component 700 has a function of storing data obtained by the sensors.

The microphone has a function of detecting acoustic signals of a speaking voice of a user, an environmental sound, and the like. The speaker has a function of outputting audio signals such as a voice and a warning beep. The robot 7100 can analyze an audio signal input via the microphone and can output a necessary audio signal from the speaker. The robot 7100 can communicate with the user with the use of the microphone and the speaker.

The camera has a function of taking images of the surroundings of the robot 7100. Furthermore, the robot 7100 has a function of moving with the use of the moving mechanism. The robot 7100 can take images of the surroundings with the use of the camera, and can analyze the images to sense whether there is an obstacle in the way of the movement.

A flying object 7120 includes propellers, a camera, a battery, and the like and has a function of flying autonomously. The electronic component 730 has a function of controlling these peripheral devices.

For example, image data taken by the camera is stored in the electronic component 700. The electronic component 730 can analyze the image data to sense whether there is an obstacle in the way of the movement. Moreover, the electronic component 730 can estimate the remaining battery level from a change in the power storage capacity of the battery.

A cleaning robot 7140 includes a display provided on the top surface, a plurality of cameras provided on the side surface, a brush, an operation button, various kinds of sensors, and the like. Although not illustrated, the cleaning robot 7140 is provided with a tire, an inlet, and the like. The cleaning robot 7140 can run autonomously, detect dust, and vacuum the dust through the inlet provided on the bottom surface.

For example, the electronic component 730 can judge whether there is an obstacle such as a wall, furniture, or a step by analyzing an image taken by the cameras. In the case where an object that is likely to be caught in the brush, such as a wire, is detected by image analysis, the rotation of the brush can be stopped.

An automobile 7160 is shown as an example of a moving object. The automobile 7160 includes an engine, tires, a brake, a steering gear, a camera, and the like. For example, the electronic component 730 performs control for optimizing the running state of the automobile 7160 on the basis of navigation information, the speed, the state of the engine, the gearshift state, the use frequency of the brake, and other data. For example, image data taken by the camera is stored in the electronic component 700.

Although an automobile is described above as an example of a moving object, moving objects are not limited to an automobile. Examples of moving objects also include a train, a monorail train, a ship, and a flying object (a helicopter, an unmanned aircraft (a drone), an airplane, and a rocket), and these moving objects can include a system utilizing artificial intelligence when equipped with the computer of one embodiment of the present invention.

The electronic component 700 and/or the electronic component 730 can be incorporated in a TV device 7200 (a television receiver), a smartphone 7210, a PC 7220 (a personal computer), a PC 7230, a game machine 7240, a game machine 7260, and the like.

For example, the electronic component 730 incorporated in the TV device 7200 can function as an image processing engine. The electronic component 730 performs, for example, image processing such as noise removal and resolution up-conversion.

The smartphone 7210 is an example of a portable information terminal. The smartphone 7210 includes a microphone, a camera, a speaker, various kinds of sensors, and a display portion. These peripheral devices are controlled by the electronic component 730.

The PC 7220 and the PC 7230 are examples of a notebook PC and a desktop PC. To the PC 7230, a keyboard 7232 and a monitor device 7233 can be connected with or without a wire.

The game machine 7240 is an example of a portable game machine. The game machine 7260 is an example of a home-use stationary game machine. To the game machine 7260, a controller 7262 is connected with or without a wire. The electronic component 700 and/or the electronic component 730 can be incorporated in the controller 7262.

A game machine in which the semiconductor device of one embodiment of the present invention is used is not limited to these. Examples of game machines using the semiconductor device of one embodiment of the present invention include an arcade game machine installed in entertainment facilities (a game center, an amusement park, and the like), and a throwing machine for batting practice installed in sports facilities.

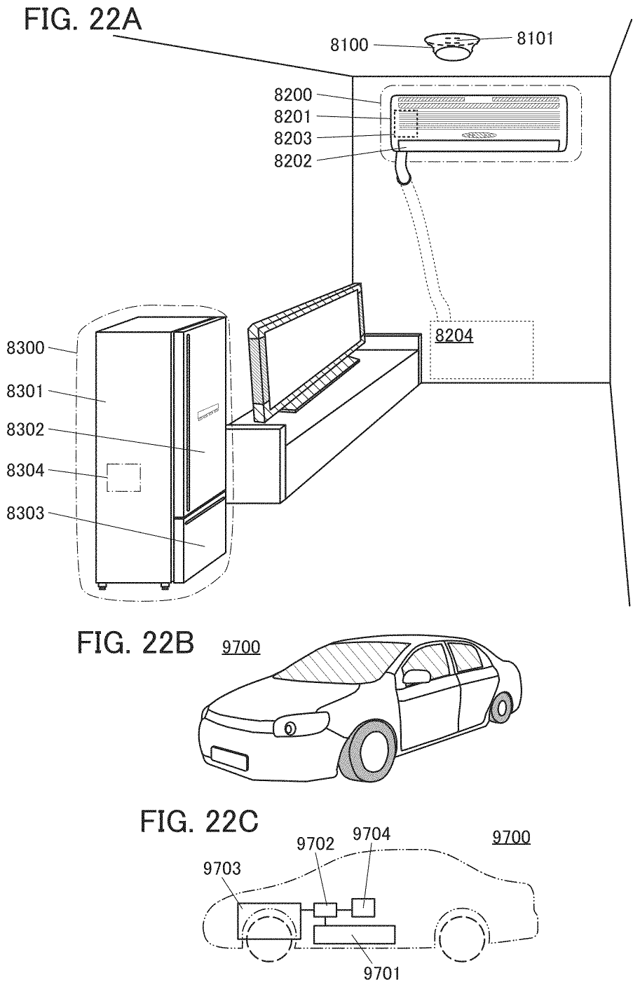

An alarm device 8100 illustrated in FIG. 22(A) is a residential fire alarm, which includes a sensor portion and a semiconductor device 8101. When the electronic component 700 and/or the electronic component 730 are/is used in the semiconductor device 8101, the power consumption of the alarm device 8100 can be reduced. In addition, stable operation can be performed even in a high-temperature environment. Thus, the reliability of the alarm device 8100 can be increased.

An air conditioner illustrated in FIG. 22(A) includes an indoor unit 8200 and an outdoor unit 8204. The indoor unit 8200 includes a housing 8201, an air outlet 8202, a semiconductor device 8203, and the like. Although FIG. 22(A) illustrates the case where the semiconductor device 8203 is provided in the indoor unit 8200, the semiconductor device 8203 may be provided in the outdoor unit 8204. Alternatively, the semiconductor devices 8203 may be provided in both the indoor unit 8200 and the outdoor unit 8204. When the electronic component 700 and/or the electronic component 730 are/is used in the semiconductor device 8203, the power consumption of the air conditioner can be reduced. In addition, stable operation can be performed even in a high-temperature environment. Thus, the reliability of the air conditioner can be increased.

An electric refrigerator-freezer 8300 illustrated in FIG. 22(A) includes a housing 8301, a refrigerator door 8302, a freezer door 8303, a semiconductor device 8304, and the like. The semiconductor device 8304 is provided in the housing 8301 in FIG. 22(A). When the electronic component 700 and/or the electronic component 730 are/is used in the semiconductor device 8304, the power consumption of the electric refrigerator-freezer 8300 can be reduced. In addition, stable operation can be performed even in a high-temperature environment. Thus, the reliability of the electric refrigerator-freezer 8300 can be increased.

Note that in this embodiment, the electric refrigerator-freezer and the air conditioner are described as examples of household appliances. The semiconductor device of one embodiment of the present invention can also be used for another household appliance. Other examples of household appliances include a vacuum cleaner, a microwave oven, an electric oven, a rice cooker, a water heater, an IH cooker, a water server, a heating-cooling combination appliance (including an air conditioner), a washing machine, a drying machine, and an audio visual appliance.

FIG. 22(B) and FIG. 22(C) illustrate an example of an electric vehicle. An electric vehicle 9700 is equipped with a secondary battery 9701. The output of the electric power of the secondary battery 9701 is adjusted by a control circuit 9702, and the electric power is supplied to a driving device 9703. The control circuit 9702 is controlled by a processing device 9704 including a semiconductor device or the like which is not illustrated. When the electronic component 700 and/or the electronic component 730 are/is used in the control circuit 9702 or the processing device 9704, the power consumption of the electric vehicle 9700 can be reduced. In addition, stable operation can be performed even in a high-temperature environment. Thus, the reliability of the electric vehicle 9700 can be increased.

The driving device 9703 includes a DC motor or an AC motor either alone, or a combination of a motor and an internal-combustion engine. The processing device 9704 outputs a control signal to the control circuit 9702 on the basis of input data such as data of operation (e.g., acceleration, deceleration, or stop) by a driver or data during driving (e.g., data on an upgrade or a downgrade, or data on a load on a driving wheel) of the electric vehicle 9700. The control circuit 9702 adjusts the electric energy supplied from the secondary battery 9701 in accordance with the control signal of the processing device 9704 to control the output of the driving device 9703. In the case where the AC motor is mounted, although not illustrated, an inverter which converts a direct current into an alternate current is also incorporated.

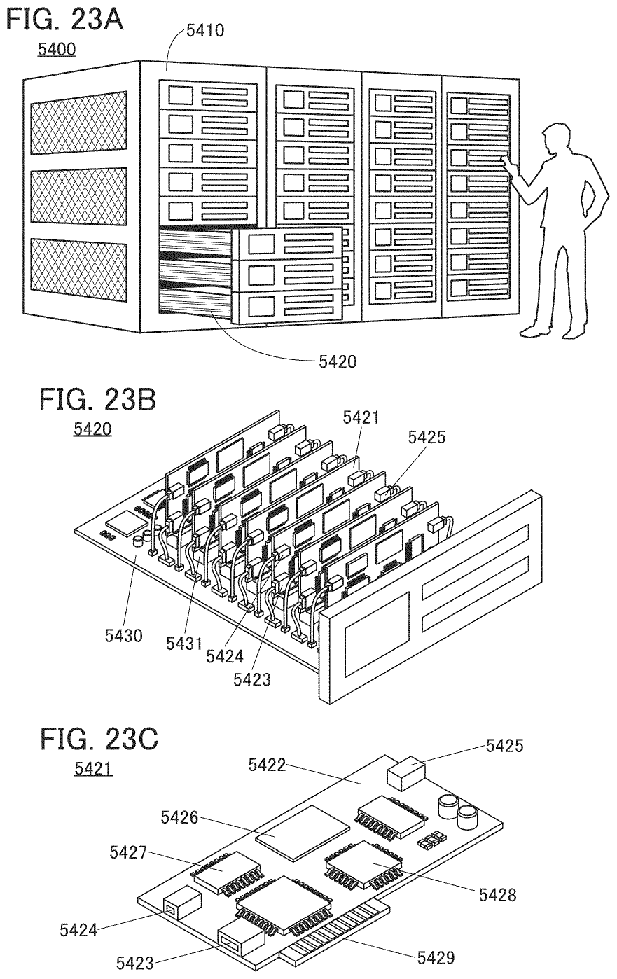

A computer 5400 illustrated in FIG. 23(A) is an example of a large computer. In the computer 5400, a plurality of rack mount computers 5420 are stored in a rack 5410.

The computer 5420 can have a structure in a perspective view illustrated in FIG. 23(B), for example. In FIG. 23(B), the computer 5420 includes a motherboard 5430, and the motherboard includes a plurality of slots 5431, a plurality of connection terminals, and the like. A PC card 5421 is inserted in the slot 5431. In addition, the PC card 5421 includes a connection terminal 5423, a connection terminal 5424, and a connection terminal 5425, each of which is connected to the motherboard 5430.

The PC card 5421 illustrated in FIG. 23(C) is an example of a processing board provided with a CPU, a GPU, a memory device, and the like. The PC card 5421 includes a board 5422. The board 5422 includes the connection terminal 5423, the connection terminal 5424, the connection terminal 5425, a semiconductor device 5426, a semiconductor device 5427, a semiconductor device 5428, and a connection terminal 5429. FIG. 23(C) also illustrates semiconductor devices other than the semiconductor device 5426, the semiconductor device 5427, and the semiconductor device 5428; the following description of the semiconductor device 5426, the semiconductor device 5427, and the semiconductor device 5428 can be referred to for these semiconductor devices.

The connection terminal 5429 has a shape with which the connection terminal 5429 can be inserted in the slot 5431 of the motherboard 5430, and the connection terminal 5429 functions as an interface for connecting the PC card 5421 and the motherboard 5430. An example of the standard for the connection terminal 5429 is PCIe.

The connection terminal 5423, the connection terminal 5424, and the connection terminal 5425 can serve as interfaces for supplying electric power and inputting a signal to the PC card 5421, for example. As another example, they can serve as an interface for outputting a signal calculated by the PC card 5421. Examples of the standard for each of the connection terminal 5423, the connection terminal 5424, and the connection terminal 5425 include USB

(Universal Serial Bus), SATA (Serial ATA), and SCSI (Small Computer System Interface). In the case where video signals are output from the connection terminal 5423, the connection terminal 5424, and the connection terminal 5425, an example of the standard therefor is HDMI (registered trademark).

The semiconductor device 5426 includes a terminal (not illustrated) for inputting and outputting signals, and when the terminal is inserted in a socket (not illustrated) of the board 5422, the semiconductor device 5426 and the board 5422 can be electrically connected to each other.

The semiconductor device 5427 includes a plurality of terminals, and when the terminals are reflow-soldered, for example, to wirings of the board 5422, the semiconductor device 5427 and the board 5422 can be electrically connected to each other. As the semiconductor device 5427, an FPGA, a GPU, a CPU, or the like can be given, for example. As the semiconductor device 5427, the electronic component 730 can be used.

The semiconductor device 5428 includes a plurality of terminals, and when the terminals are reflow-soldered, for example, to wirings of the board 5422, the semiconductor device 5428 and the board 5422 can be electrically connected to each other. As the semiconductor device 5428, a memory device can be given, for example. As the semiconductor device 5428, the electronic component 700 can be used.

The computer 5400 can also function as a parallel computer. When the computer 5400 is used as a parallel computer, large-scale computation necessary for artificial intelligence learning and inference can be performed, for example.

The semiconductor device of one embodiment of the present invention is used in a variety of electronic devices described above, whereby a reduction in size, an increase in speed, or a reduction in power consumption of the electronic devices can be achieved. Moreover, heat generation from a circuit can be reduced owing to low power consumption; thus, the influence of heat generation on the circuit, the peripheral circuit, and the module can be reduced. In addition, stable operation can be performed even in a high-temperature environment. Thus, the reliability of the electronic devices can be increased.

This embodiment can be implemented in combination with the other embodiments and examples as appropriate.

### Example 1

In this example, effects of a structure where the cell array CA is stacked above the sense amplifier array SAA and the like will be described. Here, specifically, the evaluation results of effects of the stacked-layer structure on the operation speed, the circuit area, and the like will be described. Note that in this example, a DRAM using an OS transistor as illustrated in FIG. 2(B-1) to FIG. 2(B-3) is also referred to as a DOSRAM (Dynamic Oxide Semiconductor Random Access Memory).

For the evaluation, four kinds of memory circuits (memory circuits A to D) were used. The memory circuit A is a DRAM using a Si transistor in a memory cell, and the memory circuits B, C, and D are DOSRAMs. The memory circuit B is a memory circuit having a structure where the cell array CA and the sense amplifier array SAA are not stacked and are provided in the same layer. The memory circuit C is a memory circuit having a structure where the cell array CA is stacked above the sense amplifier array SAA as illustrated in FIG. 3(A) (a stack A). The memory circuit D is a memory circuit having a structure where the cell array CA is stacked above the driver circuit RD, the sense amplifier array SAA, and the global sense amplifier GSA as illustrated in FIG. 3(B) (a stack B).

First, comparison of the operation speed between the memory circuits A to D was performed. The operation speed of the memory circuits A to D was calculated on the assumption of the case where the technology node was 25 nm. Table 1 shows, of each of the memory circuits A to D, the field-effect mobility (mobility) of the employed transistor, the ratio of the effective channel width W to the effective channel length L (effective W/L ratio), the mobility normalized by the effective W/L ratio, the channel resistance of the employed transistor, the contact resistance between a semiconductor layer and a source electrode and a drain electrode of the employed transistor, the resistance of the memory cell MC (cell resistance), the capacitance value CBL of the wiring BL, the capacitance value Cs of the capacitor provided in the memory cell MC, and the estimation result of the operation speed of the memory cell MC (cell operation speed). The operation speed of the memory cell MC was calculated on the assumption that the speed of the memory circuit A (DRAM) was 1.

TABLE 1

| Memory | A | | B | | C | | D | |
|---|---|---|---|---|---|---|---|---|
| circuit | (DRAM) | | (DOSRAM) | | (DOSRAM) | | (DOSRAM) | |
| Stacked-layer structure | N/A | | N/A | | Stack A | | Stack B | |
| Transistor | Si transistor | | OS transistor | | OS transistor | | OS transistor | |
| Mobility | 200 | cm²/Vs | 10.7 | cm²/Vs | 10.7 | cm²/Vs | 10.7 | cm²/Vs |
| Effective W/L ratio | 6 | | 1 | | 1 | | 1 | |
| Mobility normalized | 33 | cm²/Vs | 10.7 | cm²/Vs | 10.7 | cm²/Vs | 10.7 | cm²/Vs |
| effective by W/L ratio | | | | | | | | |
| Channel resistance | 115 | kΩ | 340 | kΩ | 340 | kΩ | 340 | kΩ |
| Contact reistance | 115 | kΩ | 120 | kΩ | 120 | kΩ | 120 | kΩ |
| Cell resistance | 230 | kΩ | 460 | kΩ | 460 | kΩ | 460 | kΩ |

| | | | | | | | |
|---|---|---|---|---|---|---|---|
| C_{BL} | Approx. 50 fF | 40 | fF | 10 | fF | 20 | fF |
| C_{S} | Approx. 15 fF | 12 | fF | 1.5 | fF | 3 | fF |

| | | | | |
|---|---|---|---|---|
| Cell operation speed | 1 | Approx. ×1 | Approx. ×5 | Approx. ×2.5 |

As shown in Table 1, it is found that the use of the stacked-layer structure can reduce the capacitance of the wiring BL and the size of the capacitor in the memory cell MC. Furthermore, this allows high-speed operation of the memory circuits with the stacked-layer structure (the memory circuits C and D). As shown in Table 1, the DOSRAM with the stacked-layer structure can achieve cell operation speed five times higher than that of the DRAM.

Table 2 shows the data retention time of the memory cell MC, the number of memory cells MC connected to one wiring BL, and the estimation result of the area reduction rate of each of the memory circuits A to D. Note that the area reduction rate was calculated using the memory circuit A (DRAM) as a reference.

TABLE 2

| Memory | A | B | C | D |
|---|---|---|---|---|
| circuit | (DRAM) | (DOSRAM) | (DOSRAM) | (DOSRAM) |
| Stacked-layer | N/A | N/A | Stack A | Stack B |
| structure | | | | |
| Retention | 64 ms | 10 s or | 10 s or | 10 s or |
| time | | longer | longer | longer |
| Cell number | 512 | 512 | 128 | 256 |
| per BL | | | | |
| Area reduction | — | 0% | Approx. | Approx. |
| rate | | | 13% | 19% |

As shown in Table 2, it is found that the stacked-layer structure is effective for an area reduction (the memory circuits C and D). It is also found that the use of the structure of the stack B allows a further area reduction compared with the structure of the stack A.

The above indicates that the structure where the memory cell MC is formed using an OS transistor and the cell array CA is stacked above the sense amplifier array SAA and the like is effective in increasing the speed of a memory circuit and reducing the area thereof.

This example can be implemented in combination with the other embodiments and examples as appropriate.

### Example 2

An OS transistor corresponding to the transistor 400a illustrated in FIG. 12 was fabricated and the temperature dependence of the Id-Vg characteristics of the transistor was evaluated. Specifically, the temperature of the OS transistor to be measured was changed to room temperature (higher than or equal to 20° C. and lower than or equal to 30° C., 27° C. in this example), a set temperature of 85° C. (actual temperature of 83° C.), a set temperature of 125° C. (actual temperature of 121° C.), a set temperature of 150° C. (actual temperature of 144° C.), and a set temperature of 200° C. (actual temperature of 192° C.), and the Id-Vg characteristics were measured at the respective temperatures.

The measurement was performed on two kinds of transistor: an OSFET-A and an OSFET-B. The OSFET-A and the OSFET-B have different channel lengths L and channel widths W. The L/W of the OSFET-A is 370 nm/240 nm, while the L/W of the OSFET-B is 82 nm/55 nm.

The Id-Vg characteristics were measured with a drain voltage (Vd) of 3.3 V and a front gate voltage (Vg) changed from ˜1 V to 3.3 V. In addition, the back gate voltage of the OSFET-A was −7.1 V and the back gate voltage of the OSFET-B was −11 V during the measurement.

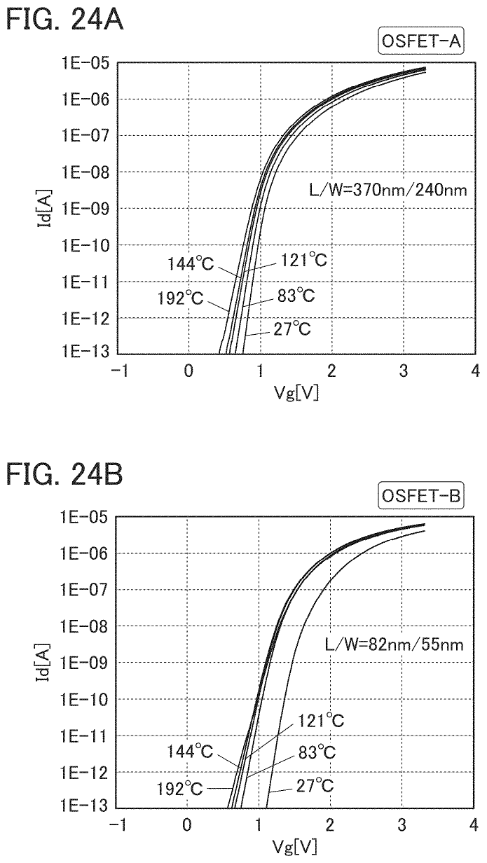

FIG. 24(A) shows the measurement results of the Id-Vg characteristics of the OSFET-A. FIG. 24(B) shows the measurement results of the Id-Vg characteristics of the OSFET-B. In each of FIG. 24(A) and FIG. 24(B), the horizontal axis represents Vg and the vertical axis represents drain current (Id). Each of FIG. 24(A) and FIG. 24(B) is a semi-log graph with a logarithmic vertical axis.

It is found from FIG. 24(A) and FIG. 24(B) that the threshold voltage of the OSFET-A and the OSFET-B decreases with the rise in measurement temperature. Meanwhile, Id at Vg of 0 V (also referred to as “Icut”) of the OSFET-A and the OSFET-B is lower than or equal to the measurement limit at every measurement temperature. It is found that Id of the OSFET-A and the OSFET-B does not easily increase even when the temperature rises and the OSFET-A and the OSFET-B have favorable off-state characteristics.

Next, calculated was the temperature dependence of the retention time when the OSFET-A or the OSFET-B was used as the transistor Tr1 in the memory cell MC illustrated in FIG. 2(B-1).

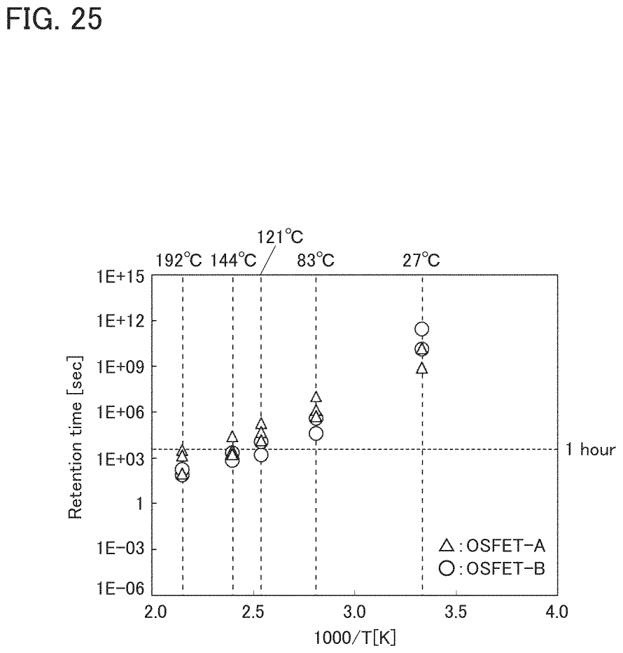

FIG. 25 is a graph showing the temperature dependence of the retention time. In FIG. 25, the horizontal axis represents temperature and the vertical axis represents retention time. Note that a value that is 1000 times the inverse of the absolute temperature is shown as the temperature represented by the horizontal axis of FIG. 25. Note that a retention time of one hour is indicated by a dashed line in FIG. 25. The capacitance value of the capacitor C1 was 3.5 fF and the allowable voltage change was 0.2 V in the calculation of the retention time. Icut of each of the OSFET-A and the OSFET-B was obtained by extrapolation of the Id-Vg characteristics.

FIG. 25 shows the retention time obtained from the Id-Vg characteristics of a plurality of OSFETs-A and the retention time obtained from the Id-Vg characteristics of a plurality of OSFETs-B. It is found from FIG. 25 that the OSFET-A and the OSFET-B have similar retention times. The retention time becomes shorter with a temperature rise. This shows that the retention time is more influenced by the temperature than by the magnitude of the L/W of the OS transistor.

It is also found from FIG. 25 that the retention time is 7.8×10⁸ seconds or longer at room temperature (27° C.), 3.8×10⁴ seconds or longer at a set temperature of 85° C. (actual temperature of 83° C.), 1.6×10³ seconds or longer at a set temperature of 125° C. (actual temperature of 121° C.), 6.9×10² seconds or longer at a set temperature of 150° C. (actual temperature of 144° C.), and 80 seconds or longer at a set temperature of 200° C. (actual temperature of 192° C.).

It is found that a retention time of several hours or longer at 85° C. can be achieved with the use of the OS transistor as the transistor Tr1 in the memory cell MC. Accordingly, even in an environment where the operation temperature is 85° C., a time from the end of refresh operation to the start of next refresh operation (refresh interval) can be 10 minutes or longer, one hour or longer, or 10 hours or longer.

This example can be implemented in combination with the other embodiments and examples as appropriate.

### Example 3

An OS transistor corresponding to the transistor 400a and being different from the OS transistor described in Example 2 was fabricated, and the temperature dependence of the Id-Vg characteristics of the transistor was evaluated. Specifically, the Id-Vg characteristics were measured when the temperature of the OS transistor to be measured was set to room temperature (higher than or equal to 20° C. and lower than or equal to 30° C., 27° C. in this example), a set temperature of 85° C. (actual temperature of 83° C.), a set temperature of 150° C. (actual temperature of 144° C.), and a set temperature of 200° C. (actual temperature of 192° C.). Calculated were the retention time and the operation frequency at each operation temperature when the OS transistor is used as the transistor Tr1 in the memory cell MC illustrated in FIG. 2(B-1).

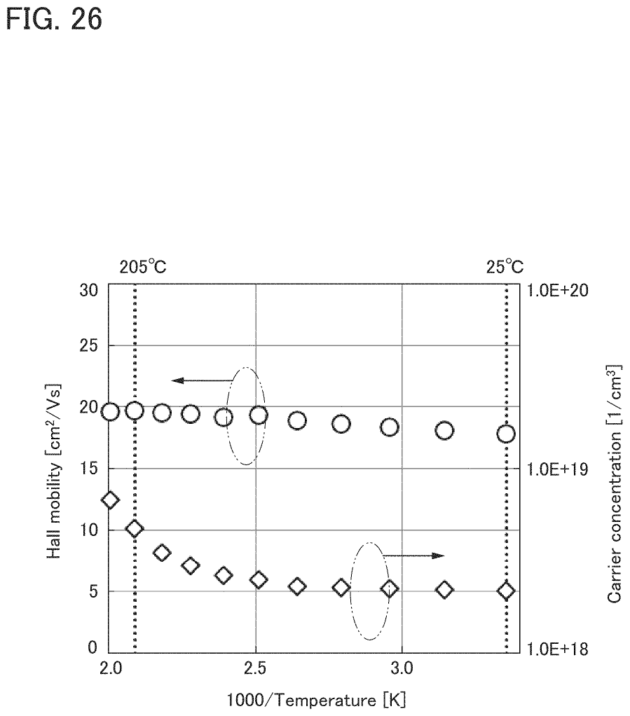

CAAC-OS including In, Ga, and Zn (also referred to as “CAAC-IGZO”) was used for a semiconductor layer of the OS transistor. A CAAC-IGZO film equivalent to the semiconductor layer used for the OS transistor was separately formed, and the Hall mobility of the CAAC-IGZO film was measured with the temperature changed from 25° C. to 205° C. FIG. 26 shows the measurement results.

In FIG. 26, the horizontal axis represents temperature and the vertical axis represents Hall mobility and carrier concentration. Note that the horizontal axis of FIG. 26 represents a value that is 1000 times the inverse of the absolute temperature. It is found from FIG. 26 that the Hall mobility of the CAAC-IGZO film increases with a temperature rise. That is, the carrier concentration of the CAAC-IGZO film increases with a temperature rise. The on-state current of the OS transistor is expected to increase with a temperature rise.

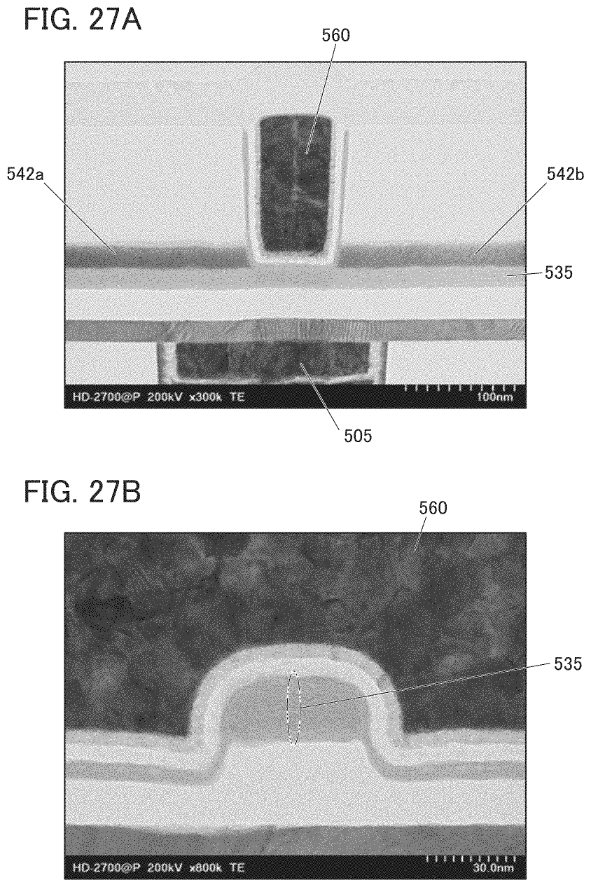

FIG. 27(A) and FIG. 27(B) are cross-sectional TEM images of the fabricated OS transistor. The OS transistor is a transistor with the S-channel structure. FIG. 27(A) shows part of the cross section in the channel length direction of the OS transistor (see FIG. 14(B)), and FIG. 27(B) shows part of the cross section in the channel width direction of the OS transistor (see FIG. 14(C)).

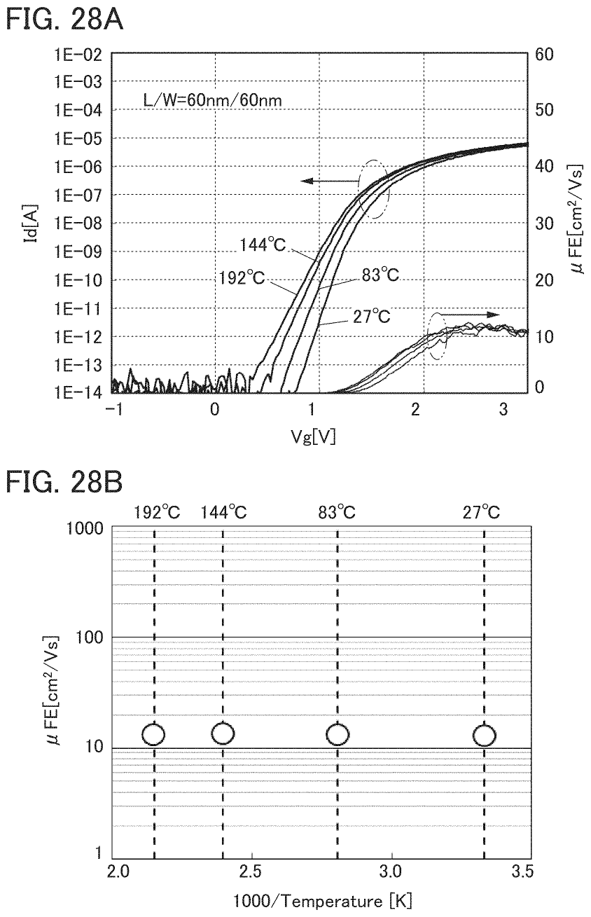

FIG. 28(A) shows the measurement results of the Id-Vg characteristics and the field-effect mobility (saturation mobility, also referred to as “μFE”) of the OS transistor. In FIG. 28(A), the horizontal axis represents Vg, one of vertical axes represents drain current (Id), and the other of the vertical axes represents μFE. Note that the vertical axis representing Id was set from 1×10⁻² A to 1×10⁻¹⁴ A in FIG. 28(A). Because the measurement limit of the measurement apparatus is 1×10⁻¹³ A, in an area with less than 1×10⁻¹³ A, a noise component is dominant and the actual Id is not measurable.

The Id-Vg characteristics were measured with a drain voltage (Vd) of 3.3 V and a front gate voltage (Vg) changed from ˜1 V to 3.3 V. The back gate voltage was −10.6 V during the measurement.

It is found from FIG. 28(A) that the threshold voltage of the OS transistor decreases with the rise in temperature of the OS transistor. Furthermore, Id at Vg of 0 V (Icut) is lower than or equal to the measurement limit at every measurement temperature. It is found that Id of the OS transistor does not easily increase even when the temperature rises and the OS transistor has favorable off-state characteristics.

FIG. 28(B) shows the maximum value of μFE at each measurement temperature. In general, as the temperature of a Si transistor rises, μFE decreases. In contrast, it is found from FIG. 28(B) that μFE of the OS transistor does not easily decrease. Moreover, μFE is higher at a measurement temperature of 192° C. than at 27° C.

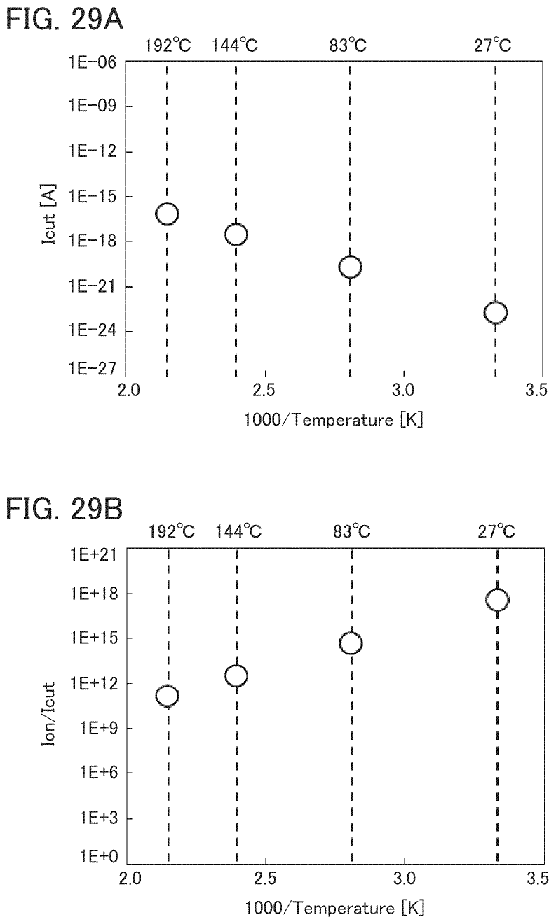

FIG. 29(A) shows Icut at each measurement temperature. Values obtained by extrapolation of the Id-Vg characteristics shown in FIG. 28(A) are shown as Icut. Although Icut increases with the rise in measurement temperature, extremely low off-state current is achieved even at high temperatures.

FIG. 29(B) shows a ratio of Id at Vg=3.3 V (also referred to as “Ion”) to Icut (also referred to as “on/off ratio”). FIG. 29(B) shows on/off ratio at each measurement temperature. It is found that the OS transistor has an extremely high on/off ratio and has an on/off ratio of 1×10¹¹ or more even at 192° C.

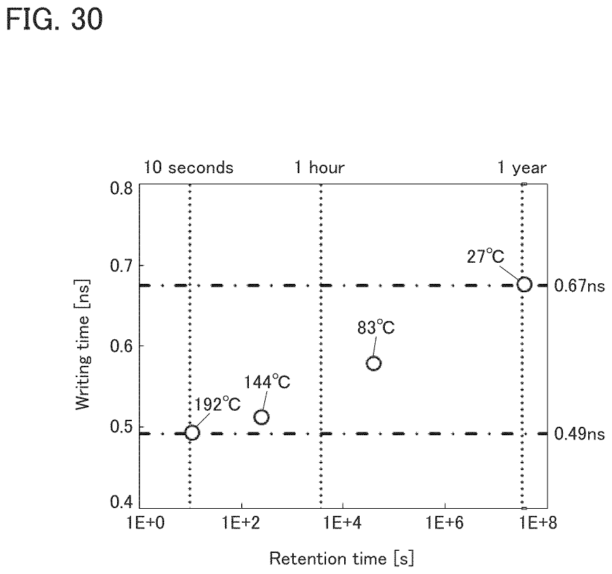

Next, calculated were the retention time and the writing time at each measurement temperature when the fabricated OS transistor was used as the transistor Tr1 in the memory cell MC illustrated in FIG. 2(B-1). FIG. 30 shows the calculation results of the retention time and the writing time. In FIG. 30, the horizontal axis represents retention time and the vertical axis represents writing time.

The retention time and the writing time were calculated on the assumption that the capacitance value of the capacitor C1 was 3.5 fF, the write judgment voltage was 0.52 V, the drain voltage (Vd) was 1.2 V, and Vg for bringing the OS transistor into an on state was 3.3 V.

The writing time is a time taken for a voltage of a node (node N) where the transistor Tr1 (OS transistor) and the capacitor C1 are connected to change from 0 V to 0.52 V. The retention time is a time taken for the voltage of the node N to change from 0.52 V to 0.32 V when the OS transistor is in an off state (Vg=0 V).

It is found from the calculation results that a writing time of 0.49 ns (nanoseconds) and a retention time of 10 seconds are achievable at a temperature of 192° C. Moreover, it is found that a writing time of 0.67 ns (nanoseconds) and a retention time of one year or longer are achievable at room temperature. With the use of the OS transistor, a memory device that operates stably even in a high-temperature environment can be provided.

This example can be implemented in combination with the other embodiments and examples as appropriate.

### REFERENCE NUMERALS

10: semiconductor device, 11: block, 50: computer, 51: processing unit, 52: memory unit, 53: memory unit, 54: input unit, 55: output unit, 56: transmission path, 400a: transistor, 400b: transistor.

1. A memory device comprising:
a first memory cell comprising a first transistor,
wherein the first transistor comprises a metal oxide in a semiconductor layer,
wherein a refresh interval of the first memory cell is longer than or equal to 10 minutes, and
wherein an operation speed of the first memory cell is higher than or equal to an operation speed of a second memory cell comprising a transistor comprising silicon in a semiconductor layer.

2. (canceled)

3. The memory device according to claim 1,
wherein the first memory cell operates at a higher operation speed than the second memory cell at an operation temperature of higher than or equal to 20° C. and lower than or equal to 200° C.

4. The memory device according to claim 1,
wherein the first memory cell operates at an operation speed five or more times higher than that of the second memory cell at an operation temperature of higher than or equal to 20° C. and lower than equal to 200° C.

5. The memory device according to claim 1,
wherein a channel length of the first transistor is greater than or equal to 5 nm and less than or equal to 100 nm.

6. The memory device according to claim 1,
wherein a channel length of the first transistor is greater than or equal to 5 nm and less than or equal to 30 nm.

7. The memory device according to claim 1,
wherein the metal oxide comprises at least one of In and Zn.

8. An electronic device comprising:
the memory device according to claim 1; and
at least one of an antenna, a sensor, a speaker, and a microphone.

9. A memory device comprising:
a cell array comprising a memory cell; and
a peripheral circuit configured to control the cell array,
wherein the peripheral circuit comprises a region overlapping with the cell array,
wherein the memory cell comprises a transistor and a capacitor,
wherein the transistor comprises a metal oxide in a semiconductor layer, and
wherein the memory device has a function of operating at a refresh interval of longer than or equal to 10 minutes and shorter than or equal to one hour in an environment of higher than or equal to 20° C. and lower than or equal to 85° C.

10. The memory device according to claim 9,
wherein the memory device has a function of operating at a refresh interval of longer than or equal to 10 minutes and shorter than or equal to 10 hours.

11. The memory device according to claim 9,
wherein the peripheral circuit has a function of writing data to the memory cell when the transistor is in an on state,
wherein the memory cell has a function of retaining the data when the transistor is in an off state, and
wherein the peripheral circuit has a function of reading out the data retained in the memory cell when the transistor is in an on state.

12. The memory device according to claim 9,
wherein the metal oxide comprises at least one of In and Zn.
